(19) United States
(12) Patent Application Publication
(10) Pub. No.: US 2023/0292610 A1
(43) Pub. Date: Sep. 14, 2023

(54) ORGANIC ELECTROLUMINESCENT COMPOUND, A PLURALITY OF HOST MATERIALS AND ORGANIC ELECTROLUMINESCENT DEVICE COMPRISING THE SAME

(71) Applicant: ROHM AND HAAS ELECTRONIC MATERIALS KOREA LTD., Chungcheongnam-do (KR)

(72) Inventors: Sang-Hee CHO, Gyeonggi-do (KR); Young-Jae KIM, Gyeonggi-do (KR); Hyo-Nim SHIN, Gyeonggi-do (KR); So-Young JUNG, Gyeonggi-do (KR); Mi-Ja LEE, Gyeonggi-do (KR); Su-Hyun LEE, Gyeonggi-do (KR); Hae-Yeon KIM, Gyeonggi-do (KR)

(21) Appl. No.: 18/178,712

(22) Filed: Mar. 6, 2023

(30) Foreign Application Priority Data
Mar. 8, 2022 (KR) 10-2022-0029217
Feb. 8, 2023 (KR) 10-2023-0016598

(51) Int. Cl. H10K 85/60; H10K 50/11

(52) U.S. Cl. CPC H10K 85/6574; H10K 85/636; H10K 85/657; H10K 85/631; H10K 85/6576; H10K 85/654; H10K 50/11; H10K 2102/302

(57) ABSTRACT

The present disclosure relates to an organic electroluminescent compound, a plurality of host materials comprising at least one first host compound and at least one second host compound, and an organic electroluminescent device comprising the same. An organic electroluminescent device with improved driving voltage, luminous efficiency and/or lifespan properties can be provided by comprising the organic electroluminescent compound or the specific combination of compounds according to the present disclosure as a host material.

### TECHNICAL FIELD

The present disclosure relates to an organic electroluminescent compound, a plurality of host materials and an organic electroluminescent device comprising the same.

### BACKGROUND ART

In 1987, Tang et al. of Eastman Kodak first developed a small molecular green organic electroluminescent device (OLED) by using TPD/Alq₃ bilayer consisting of a light-emitting layer and a charge transport layer. Thereafter, the development of OLEDs was rapidly effected and OLEDs have been commercialized. Currently, OLEDs mainly use phosphorescent materials having excellent luminous efficiency in panel implementation.

However, in many applications such as TVs and lightings, the lifespan of OLEDs is insufficient, and higher efficiency of OLEDs is still required. In general, the lifespan of an OLED becomes shorter as the luminance of the OLED becomes higher. Thus, OLEDs having high luminous efficiency and/or long lifespan are required for long-term use and high resolution of a display.

In order to improve luminous efficiency, driving voltage, and/or lifespan, various materials or concepts for an organic layer of an organic electroluminescent device have been proposed, but they were not satisfactory in practical use. Accordingly, there has been a continuous need to develop an organic electroluminescent device having improved performances, for example, improved driving voltage, luminous efficiency, and/or lifespan properties, compared to organic electroluminescent devices previously disclosed.

On the other hand, Korean Patent Application Laid-Open No. 10-2020-0026079 discloses an organic electroluminescent device comprising a compound containing a phenanthrooxazole as a host material, and Korean Patent Application Laid-Open No. 10-2021-0006283 discloses an organic electroluminescent device comprising a compound respectively containing a phenanthrooxazole and a naphthobenzo structure as a basic backbone, as a plurality of host materials. However, the aforementioned references fail to specifically disclose organic electroluminescent devices using a specific compound or a specific combination of a plurality of host materials claimed in the present disclosure, and there is still a need to develop a host material for improving the performance of an organic electroluminescent device.

### DISCLOSURE OF INVENTION

### Technical Problems

An objective of the present disclosure is to provide an organic electroluminescent compound with a novel structure suitable for application to an organic electroluminescent device. Another objective of the present disclosure is to provide a plurality of host materials capable of producing an organic electroluminescent device having low driving voltage, high luminous efficiency and/or long lifespan properties. Still another objective of the present disclosure is to provide an organic electroluminescent device having low driving voltage, high luminous efficiency and/or long lifespan properties by comprising a compound according to the present disclosure as a single host material or comprising a plurality of host materials including a specific combination of compounds according to the present disclosure.

### Solution to Problem

The present inventors noted that a compound having a core such as phenanthrooxazole has a low HOMO(highest occupied molecular orbital) energy level in an energy level relationship with a hole transport layer as a hole-type host, and studied a hole-type host capable of forming an appropriate energy gap with the compound used in the hole transport layer. On the other hand, the compound used for the hole transport layer and the compound having a phenanthrooxazole backbone have a dihedral angle as a molecular form with an appropriate rigidity, but when they have completely planar structures depending on the formation of a substituent, they can cause crystallization by aggregation. The present inventors found that a compound containing a terphenyl group at the terminal as shown in the following formula 1 can provide an organic electroluminescent device having a fast current property and a long lifespan because proper intermolecular stacking is well established. Specifically, when the compound represented by formula 1 is used as a hole-type host, it was confirmed that the energy barrier is lowered in relation to a hole transport layer compared to the hole-type host of the conventional phenanthrooxazole backbone, and found that when it is used in a light-emitting layer in combination with a compound represented by the following formula 2, hole and electron properties are balanced by appropriate HOMO and LUMO energy levels, and it is possible to provide an organic electroluminescent device having lower driving voltage, higher luminous efficiency and/or longer lifespan compared to the conventional organic electroluminescent device, and at the same time, capable of implementing colors of high purity.

Specifically, the present inventors found that the above objective can be achieved by a plurality of host materials comprising at least one first host compound and at least one second host compound, wherein the first host compound is represented by the following formula 1, and wherein the second host compound is represented by the following formula 2.

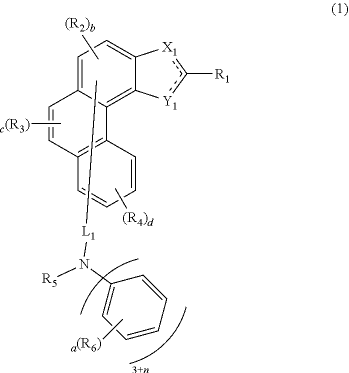

In formula 1,

X₁, and Y₁, each independently represent —N═, —NR₁₁, —O— or —S—, with a proviso that any one of X₁, and Y₁, represents —N═, and the other of X₁, and Y₁, represents —NR₁₁—, —O— or —S—;

R₁, represents a substituted or unsubstituted (C6-C30)aryl, or a substituted or unsubstituted (3- to 30-membered)heteroaryl;

R₂ to R₄ and R₁₁ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring group of a (C3-C30) aliphatic ring(s) and a (C6-C30) aromatic ring(s), or -L₂-N(Ar₁)(Ar₂); or may be linked to an adjacent substituent(s) to form a ring(s);

R₅ represents a substituted or unsubstituted (C6-C30)aryl, or a substituted or unsubstituted (3- to 30-membered)heteroaryl;

R₆ each independently represents hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring group of a (C3-C30) aliphatic ring(s) and a (C6-C30) aromatic ring(s), or -L₂-N(Ar₁)(Ar₂);

L₁ and L₂ each independently represent a single bond, a substituted or unsubstituted (C6-C30)arylene, or a substituted or unsubstituted (3- to 30-membered)heteroarylene;

Ar₁ and Ar₂ each independently represent hydrogen, a substituted or unsubstituted (C1-C30)alkyl, a substituted or unsubstituted (C2-C30)alkenyl, a substituted or unsubstituted fused ring group of a (C3-C30) aliphatic ring(s) and a (C6-C30) aromatic ring(s), a substituted or unsubstituted (C6-C30)aryl, or a substituted or unsubstituted (3- to 30-membered)heteroaryl; and

n represents an integer of 0 to 3, a represents an integer of 1 to 5, d represents an integer of 1 to 4, and b and c each independently represent an integer of 1 or 2, where if a to d are an integer of 2 or more, each of R₂ to each of R₄, and each of R₆ may be the same as or different from each other;

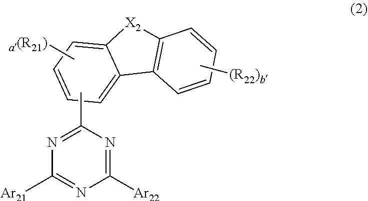

In formula 2,

X₂ represents —O— or —S—;

R₂₁ and R₂₂ each independently represent hydrogen, deuterium, or a substituted or unsubstituted (C6-C30)aryl;

Ar₂₁ represents a substituted or unsubstituted naphthyl, a substituted or unsubstituted dibenzofuranyl, a substituted or unsubstituted dibenzothiophenyl, or a substituted or unsubstituted terphenyl;

Ar₂₂ represents a substituted or unsubstituted phenyl, a substituted or unsubstituted biphenyl, a substituted or unsubstituted naphthyl, or a substituted or unsubstituted terphenyl; and

a′ represents an integer of 1 to 3, and b′ represents an integer of 1 to 4, where if a′ and b′ represent an integer of 2 or more, each of R₂₁ and each of R₂₂ may be the same as or different from each other,

the substituent(s) of the substituted aryl, the substituted phenyl, the substituted biphenyl, the substituted terphenyl, the substituted naphthyl, the substituted dibenzofuranyl, and the substituted dibenzothiophenyl in formula 2 are each independently at least one of deuterium and a (C6-C30) aryl.

In addition, the present inventors found that the above objective can be achieved by an organic electroluminescent compound represented by the following formula 21.

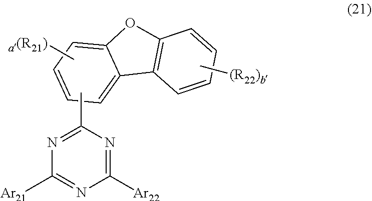

In formula 21,

Ar₂₁ represents a naphthyl unsubstituted or substituted with deuterium, a phenylnaphthyl unsubstituted or substituted with deuterium, a naphthylphenyl unsubstituted or substituted with deuterium, or a terphenyl unsubstituted or substituted with deuterium;

Ar₂₂ represents a binaphthyl unsubstituted or substituted with deuterium;

R₂₁ and R₂₂ each independently represent hydrogen or deuterium; and

a′ represents an integer of 1 to 3, and b′ represents an integer of 1 to 4, where if a′ and b′ represent an integer of 2 or more, each of R₂₁ and each of R₂₂ may be the same as or different from each other.

In addition, the present inventors found that the above objective can be achieved by the following organic electroluminescent compounds.

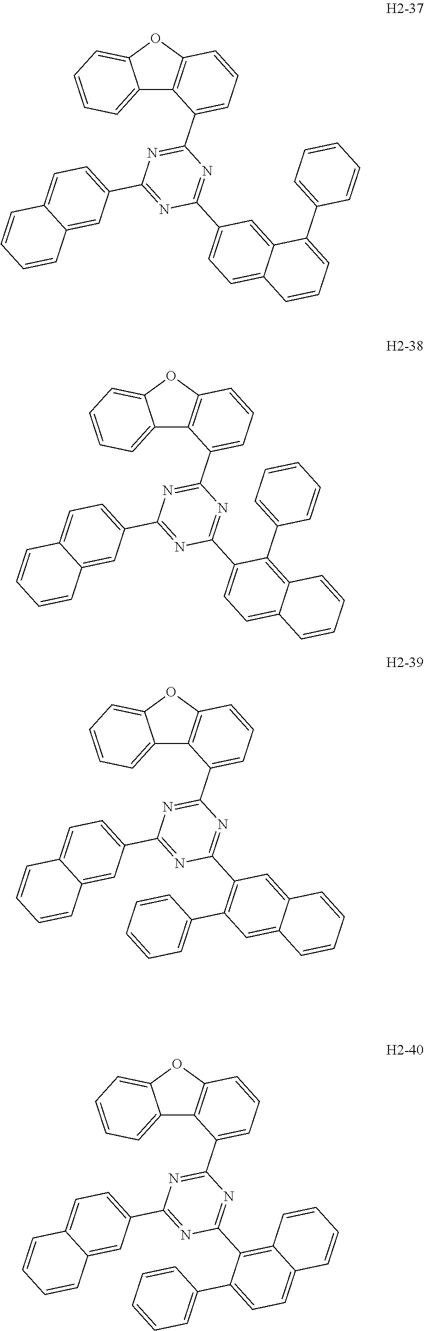 [SMILES: c1ccc(-c2cccc3ccc(-c4nc(-c5ccc6ccccc6c5)nc(-c5cccc6oc7ccccc7c56)n4)cc23)cc1 ; c1ccc(-c2c(-c3nc(-c4ccc5ccccc5c4)nc(-c4cccc5oc6ccccc6c45)n3)ccc3ccccc23)cc1 ; c1ccc(-c2cc3ccccc3cc2-c2nc(-c3ccc4ccccc4c3)nc(-c3cccc4oc5ccccc5c34)n2)cc1 ; c1ccc(-c2ccc3ccccc3c2-c2nc(-c3ccc4ccccc4c3)nc(-c3cccc4oc5ccccc5c34)n2)cc1]

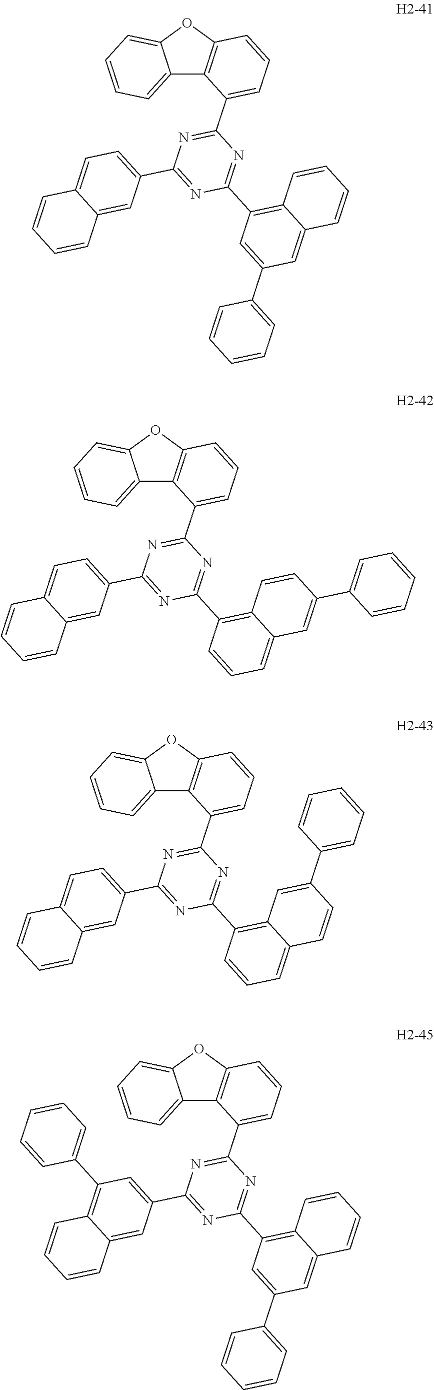 [SMILES: c1ccc(-c2cc(-c3nc(-c4ccc5ccccc5c4)nc(-c4cccc5oc6ccccc6c45)n3)c3ccccc3c2)cc1 ; c1ccc(-c2ccc3c(-c4nc(-c5ccc6ccccc6c5)nc(-c5cccc6oc7ccccc7c56)n4)cccc3c2)cc1 ; c1ccc(-c2ccc3cccc(-c4nc(-c5ccc6ccccc6c5)nc(-c5cccc6oc7ccccc7c56)n4)c3c2)cc1 ; c1ccc(-c2cc(-c3nc(-c4cc(-c5ccccc5)c5ccccc5c4)nc(-c4cccc5oc6ccccc6c45)n3)c3ccccc3c2)cc1]

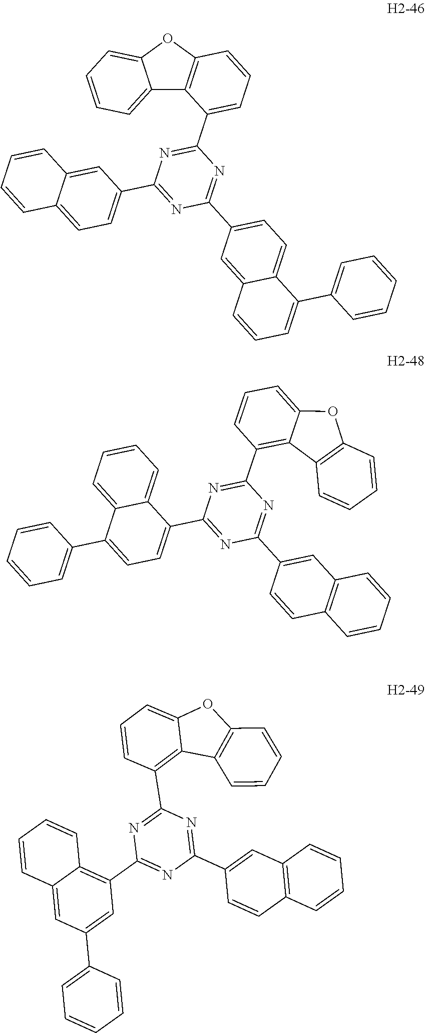 [SMILES: c1ccc(-c2cccc3cc(-c4nc(-c5ccc6ccccc6c5)nc(-c5cccc6oc7ccccc7c56)n4)ccc23)cc1 ; c1ccc(-c2ccc(-c3nc(-c4ccc5ccccc5c4)nc(-c4cccc5oc6ccccc6c45)n3)c3ccccc23)cc1 ; c1ccc(-c2cc(-c3nc(-c4ccc5ccccc5c4)nc(-c4cccc5oc6ccccc6c45)n3)c3ccccc3c2)cc1]

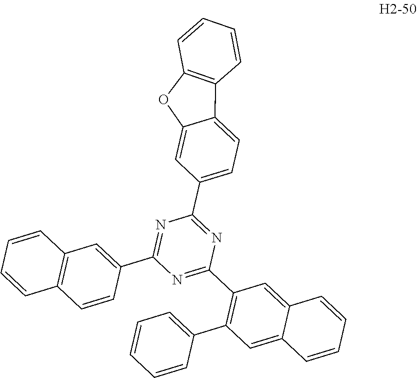 [SMILES: c1ccc(-c2cc3ccccc3cc2-c2nc(-c3ccc4ccccc4c3)nc(-c3ccc4c(c3)oc3ccccc34)n2)cc1]

### Advantageous Effects of Invention

The organic electroluminescent compound according to the present disclosure exhibits performances suitable for using in an organic electroluminescent device. In addition, an organic electroluminescent device having lower driving voltage, higher luminous efficiency and/or longer lifespan properties compared to the conventional organic electroluminescent device may be manufactured by comprising the compound according to the present disclosure as a single host material or as a plurality of host materials, and it is possible to manufacture a display system or a lighting system using the same.

### MODE FOR THE INVENTION

Hereinafter, the present disclosure will be described in detail. However, the following description is intended to explain the present disclosure, and is not meant to restrict the scope of the present disclosure.

The term “organic electroluminescent compound” in the present disclosure means a compound that may be used in an organic electroluminescent device, and may be comprised in any layer constituting an organic electroluminescent device, as necessary.

The term “organic electroluminescent material” in the present disclosure means a material that may be used in an organic electroluminescent device, and may comprise at least one compound. The organic electroluminescent material may be comprised in any layer constituting an organic electroluminescent device, as necessary. For example, the organic electroluminescent material may be a hole injection material, a hole transport material, a hole auxiliary material, a light-emitting auxiliary material, an electron blocking material, a light-emitting material (including a host material and a dopant material), an electron buffer material, a hole blocking material, an electron transport material, an electron injection material, etc.

The term “a plurality of organic electroluminescent materials” in the present disclosure means an organic electroluminescent material(s) comprising a combination of two or more compounds, which may be comprised in any layer constituting an organic electroluminescent device. It may mean both a material before being comprised in an organic electroluminescent device (for example, before vapor deposition) and a material after being comprised in an organic electroluminescent device (for example, after vapor deposition). For example, a plurality of organic electroluminescent materials may be a combination of two or more compounds that may be comprised in at least one layer of a hole injection layer, a hole transport layer, a hole auxiliary layer, a light-emitting auxiliary layer, an electron blocking layer, a light-emitting layer, an electron buffer layer, a hole blocking layer, an electron transport layer, and an electron injection layer. The two or more compounds may be comprised in the same layer or different layers, and may be mixture-evaporated or co-evaporated, or may be individually evaporated.

The term “a plurality of host materials” in the present disclosure means an organic electroluminescent material(s) comprising a combination of two or more host materials. It may mean both a material before being comprised in an organic electroluminescent device (for example, before vapor deposition) and a material after being comprised in an organic electroluminescent device (for example, after vapor deposition). The plurality of host materials of the present disclosure may be comprised in any light-emitting layer constituting an organic electroluminescent device, wherein the two or more compounds comprised in the plurality of host materials may be comprised together in one light-emitting layer or may be respectively comprised in different light-emitting layers. When two or more host materials are comprised in one layer, for example, they may be mixture-evaporated to form a layer or separately and simultaneously co-evaporated to form a layer.

Herein, the term “(C1-C30)alkyl” is meant to be a linear or branched alkyl having 1 to 30 carbon atoms constituting the chain, in which the number of carbon atoms is preferably 1 to 20, and more preferably 1 to 10. The above alkyl may include methyl, ethyl, n-propyl, isopropyl, n-butyl, isobutyl, tert-butyl, sec-butyl, etc. The term “(C2-C30)alkenyl” in the present disclosure is meant to be a linear or branched alkenyl having 2 to 30 carbon atoms constituting the chain, in which the number of carbon atoms is preferably 2 to 20, and more preferably 2 to 10. The above alkenyl may include vinyl, 1-propenyl, 2-propenyl, 1-butenyl, 2-butenyl, 3-butenyl, 2-methylbut-2-enyl, etc. The term “(C2-C30)alkynyl” in the present disclosure is meant to be a linear or branched alkynyl having 2 to 30 carbon atoms constituting the chain, in which the number of carbon atoms is preferably 2 to 20, and more preferably 2 to 10. The above alkynyl may include ethynyl, 1-propynyl, 2-propynyl, 1-butynyl, 2-butynyl, 3-butynyl, 1-methylpent-2-ynyl, etc. The term “(C3-C30)cycloalkyl” is meant to be a monocyclic or polycyclic hydrocarbon having 3 to 30 ring backbone carbon atoms, preferably 3 to 20 ring backbone carbon atoms, and more preferably 3 to 7 ring backbone carbon atoms. Examples of the cycloalkyl may include cyclopropyl, cyclobutyl, cyclopentyl, cyclohexyl, cyclopentylmethyl, cyclohexylmethyl, etc. The term “(3- to 7-membered)heterocycloalkyl” in the present disclosure is meant to be a cycloalkyl having 3 to 7 ring backbone atoms, preferably 5 to 7 ring backbone atoms and containing at least one heteroatom(s) selected from the group consisting of B, N, O, S, Si, and P, preferably the group consisting of O, S, and N. The above heterocycloalkyl includes tetrahydrofuran, pyrrolidine, thiolane, tetrahydropyran, etc. The term “(C6-C30)aryl(ene)” in the present disclosure is meant to be a monocyclic or fused ring radical derived from an aromatic hydrocarbon having 6 to 30 ring backbone carbon atoms. The number of ring backbone carbon atoms is preferably 6 to 25, and more preferably 6 to 18. The above aryl may be partially saturated, and may comprise a spiro structure. The above aryl may include phenyl, biphenyl, terphenyl, naphthyl, binaphthyl, phenylnaphthyl, naphthylphenyl, phenylterphenyl, fluorenyl, phenylfluorenyl, benzofluorenyl, dibenzofluorenyl, phenanthrenyl, phenylphenanthrenyl, anthracenyl, indenyl, triphenylenyl, pyrenyl, tetracenyl, perylenyl, chrysenyl, naphthacenyl, fluoranthenyl, spirobifluorenyl, azulenyl, tetramethyldihydrophenanthrenyl, etc. More specifically, the aryl may include phenyl, 1-naphthyl, 2-naphthyl, 1-anthryl, 2-anthryl, 9-anthryl, benzanthryl, 1-phenanthryl, 2-phenanthryl, 3-phenanthryl, 4-phenanthryl, 9-phenanthryl, naphthacenyl, pyrenyl, 1-chrysenyl, 2-chrysenyl, 3-chrysenyl, 4-chrysenyl, 5-chrysenyl, 6-chrysenyl, benzo[c]phenanthryl, benzo[g]chrysenyl, 1-triphenylenyl, 2-triphenylenyl, 3-triphenylenyl, 4-triphenylenyl, 1-fluorenyl, 2-fluorenyl, 3-fluorenyl, 4-fluorenyl, 9-fluorenyl, benzo[a]fluorenyl, benzo[b]fluorenyl, benzo[c]fluorenyl, dibenzofluorenyl, 2-biphenylyl, 3-biphenylyl, 4-biphenylyl, o-terphenyl, m-terphenyl-4-yl, m-terphenyl-3-yl, m-terphenyl-2-yl, p-terphenyl-4-yl, p-terphenyl-3-yl, p-terphenyl-2-yl, m-quaterphenyl, 3-fluoranthenyl, 4-fluoranthenyl, 8-fluoranthenyl, 9-fluoranthenyl, benzofluoranthenyl, o-tolyl, m-tolyl, p-tolyl, 2,3-xylyl, 3,4-xylyl, 2,5-xylyl, mesityl, o-cumenyl, m-cumenyl, p-cumenyl, p-t-butylphenyl, p-(2-phenylpropyl)phenyl, 4′-methylbiphenylyl, 4″-t-butyl-p-terphenyl-4-yl, 9,9-dimethyl-1-fluorenyl, 9,9-dimethyl-2-fluorenyl, 9,9-dimethyl-3-fluorenyl, 9,9-dimethyl-4-fluorenyl, 9,9-diphenyl-1-fluorenyl, 9,9-diphenyl-2-fluorenyl, 9,9-diphenyl-3-fluorenyl, 9,9-diphenyl-4-fluorenyl, 11,11-dimethyl-1-benzo[a]fluorenyl, 11,11-dimethyl-2-benzo[a]fluorenyl, 11,11-dimethyl-3-benzo[a]fluorenyl, 11,11-dimethyl-4-benzo[a]fluorenyl, 11,11-dimethyl-5-benzo[a]fluorenyl, 11,11-dimethyl-6-benzo[a]fluorenyl, 11,11-dimethyl-7-benzo[a]fluorenyl, 11,11-dimethyl-8-benzo[a]fluorenyl, 11,11-dimethyl-9-benzo[a]fluorenyl, 11,11-dimethyl-10-benzo[a]fluorenyl, 11,11-dimethyl-1-benzo[b]fluorenyl, 11,11-dimethyl-2-benzo[b]fluorenyl, 11,11-dimethyl-3-benzo[b]fluorenyl, 11,11-dimethyl-4-benzo[b]fluorenyl, 11,11-dimethyl-5-benzo[b]fluorenyl, 11,11-dimethyl-6-benzo[b]fluorenyl, 11,11-dimethyl-7-benzo[b]fluorenyl, 11,11-dimethyl-8-benzo[b]fluorenyl, 11,11-dimethyl-9-benzo[b]fluorenyl, 11,11-dimethyl-10-benzo[b]fluorenyl, 11,11-dimethyl-1-benzo[c]fluorenyl, 11,11-dimethyl-2-benzo[c]fluorenyl, 11,11-dimethyl-3-benzo[c]fluorenyl, 11,11-dimethyl-4-benzo[c]fluorenyl, 11,11-dimethyl-5-benzo[c]fluorenyl, 11,11-dimethyl-6-benzo[c]fluorenyl, 11,11-dimethyl-7-benzo[c]fluorenyl, 11,11-dimethyl-8-benzo[c]fluorenyl, 11,11-dimethyl-9-benzo[c]fluorenyl, 11,11-dimethyl-10-benzo[c]fluorenyl, 11,11-diphenyl-1-benzo[a]fluorenyl, 11,11-diphenyl-2-benzo[a]fluorenyl, 11,11-diphenyl-3-benzo[a]fluorenyl, 11,11-diphenyl-4-benzo[a]fluorenyl, 11,11-diphenyl-5-benzo[a]fluorenyl, 11,11-diphenyl-6-benzo[a]fluorenyl, 11,11-diphenyl-7-benzo[a]fluorenyl, 11,11-diphenyl-8-benzo[a]fluorenyl, 11,11-diphenyl-9-benzo[a]fluorenyl, 11,11-diphenyl-10-benzo[a]fluorenyl, 11,11-diphenyl-1-benzo[b]fluorenyl, 11,11-diphenyl-2-benzo[b]fluorenyl, 11,11-diphenyl-3-benzo[b]fluorenyl, 11,11-diphenyl-4-benzo[b]fluorenyl, 11,11-diphenyl-5-benzo[b]fluorenyl, 11,11-diphenyl-6-benzo[b]fluorenyl, 11,11-diphenyl-7-benzo[b]fluorenyl, 11,11-diphenyl-8-benzo[b]fluorenyl, 11,11-diphenyl-9-benzo[b]fluorenyl, 11,11-diphenyl-10-benzo[b]fluorenyl, 11,11-diphenyl-1-benzo[c]fluorenyl, 11,11-diphenyl-2-benzo[c]fluorenyl, 11,11-diphenyl-3-benzo[c]fluorenyl, 11,11-diphenyl-4-benzo[c]fluorenyl, 11,11-diphenyl-5-benzo[c]fluorenyl, 11,11-diphenyl-6-benzo[c]fluorenyl, 11,11-diphenyl-7-benzo[c]fluorenyl, 11,11-diphenyl-8-benzo[c]fluorenyl, 11,11-diphenyl-9-benzo[c]fluorenyl, 11,11-diphenyl-10-benzo[c]fluorenyl, 9,9,10,10-tetramethyl-9,10-dihydro-1-phenanthrenyl, 9,9,10,10-tetramethyl-9,10-dihydro-2-phenanthrenyl, 9,9,10,10-tetramethyl-9,10-dihydro-3-phenanthrenyl, 9,9,10,10-tetramethyl-9,10-dihydro-4-phenanthrenyl, etc.

The term “(3- to 30-membered)heteroaryl(ene)” in the present disclosure is meant to be an aryl having 3 to 30 ring backbone atoms and including at least one, preferably 1 to 4 heteroatom(s) selected from the group consisting of B, N, O, S, Si, and P. It may be a monocyclic ring or a fused ring condensed with at least one benzene ring, and may be partially saturated. In addition, the above heteroaryl(ene) comprises one formed by linking at least one heteroaryl or aryl group to a heteroaryl group via a single bond(s), and may comprise a spiro structure. The above heteroaryl may include a monocyclic ring-type heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl such as benzofuranyl, benzothiophenyl, isobenzofuranyl, dibenzofuranyl, dibenzothiophenyl, dibenzoselenophenyl, naphthobenzofuranyl, naphthobenzothiophenyl, benzofuroquinolinyl, benzofuroquinazolinyl, benzofuronaphthyridinyl, benzofuropyrimidinyl, naphthofuropyrimidinyl, benzothienoquinolinyl, benzothienoquinazolinyl, benzothienonaphthyridinyl, benzothienopyrimidinyl, naphthothienopyrimidinyl, pyrimidoindolyl, benzopyrimidoindolyl, benzofuropyrazinyl, naphthofuropyrazinyl, benzothienopyrazinyl, naphthothienopyrazinyl, acenaphthopyrazinyl, pyrazinoindolyl, benzopyrazinoindolyl, benzimidazolyl, benzothiazolyl, benzoisothiazolyl, benzoisoxazolyl, benzoxazolyl, naphthoxazolyl, isoindolyl, indolyl, benzoindolyl, indazolyl, benzothiadiazolyl, quinolyl, isoquinolyl, cinnolinyl, quinazolinyl, benzoquinazolinyl, quinoxalinyl, benzoquinoxalinyl, dibenzoquinoxalinyl, naphthyridinyl, carbazolyl, benzocarbazolyl, dibenzocarbazolyl, phenoxazinyl, phenothiazinyl, phenanthridinyl, phenantroimidazolyl, benzodioxolyl, dihydroacridinyl, benzotriazolephenazinyl, imidazopyridinyl, chromenoquinazolinyl, thiochromenoquinazolinyl, dimethylbenzoperimidinyl, indolocarbazolyl, indenocarbazolyl, etc. More specifically, the heteroaryl may include 1-pyrrolyl, 2-pyrrolyl, 3-pyrrolyl, pyrazinyl, 2-pyridyl, 2-pyrimidinyl, 4-pyrimidinyl, 5-pyrimidinyl, 6-pyrimidinyl, 1,2,3-triazin-4-yl, 1,2,4-triazin-3-yl, 1,3,5-triazin-2-yl, 1-imidazolyl, 2-imidazolyl, 1-pyrazolyl, 1-indolidinyl, 2-indolidinyl, 3-indolidinyl, 5-indolidinyl, 6-indolidinyl, 7-indolidinyl, 8-indolidinyl, 2-imidazopyridyl, 3-imidazopyridyl, 5-imidazopyridyl, 6-imidazopyridyl, 7-imidazopyridyl, 8-imidazopyridyl, 3-pyridyl, 4-pyridyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 2-quinolyl, 3-quinolyl, 4-quinolyl, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyl, 2-carbazolyl, 3-carbazolyl, 4-carbazolyl, 9-carbazolyl, azacarbazolyl-1-yl, azacarbazolyl-2-yl, azacarbazolyl-3-yl, azacarbazolyl-4-yl, azacarbazolyl-5-yl, azacarbazolyl-6-yl, azacarbazolyl-7-yl, azacarbazolyl-8-yl, azacarbazolyl-9-yl, 1-phenanthridinyl, 2-phenanthridinyl, 3-phenanthridinyl, 4-phenanthridinyl, 6-phenanthridinyl, 7-phenanthridinyl, 8-phenanthridinyl, 9-phenanthridinyl, 10-phenanthridinyl, 1-acridinyl, 2-acridinyl, 3-acridinyl, 4-acridinyl, 9-acridinyl, 2-oxazolyl, 4-oxazolyl, 5-oxazolyl, 2-oxadiazolyl, 5-oxadiazolyl, 3-furazanyl, 2-thienyl, 3-thienyl, 2-methylpyrrol-1-yl, 2-methylpyrrol-3-yl, 2-methylpyrrol-4-yl, 2-methylpyrrol-5-yl, 3-methylpyrrol-1-yl, 3-methylpyrrol-2-yl, 3-methylpyrrol-4-yl, 3-methylpyrrol-5-yl, 2-tert-butylpyrrol-4-yl, 3-(2-phenylpropyl)pyrrol-1-yl, 2-methyl-1-indolyl, 4-methyl-1-indolyl, 2-methyl-3-indolyl, 4-methyl-3-indolyl, 2-tert-butyl-1-indolyl, 4-tert-butyl-1-indolyl, 2-tert-butyl-3-indolyl, 4-tert-butyl-3-indolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-naphtho-[1,2-b]-benzofuranyl, 2-naphtho-[1,2-b]-benzofuranyl, 3-naphtho-[1,2-b]-benzofuranyl, 4-naphtho-[1,2-b]-benzofuranyl, 5-naphtho-[1,2-b]-benzofuranyl, 6-naphtho-[1,2-b]-benzofuranyl, 7-naphtho-[1,2-b]-benzofuranyl, 8-naphtho-[1,2-b]-benzofuranyl, 9-naphtho-[1,2-b]-benzofuranyl, 10-naphtho-[1,2-b]-benzofuranyl, 1-naphtho-[2,3-b]-benzofuranyl, 2-naphtho-[2,3-b]-benzofuranyl, 3-naphtho-[2,3-b]-benzofuranyl, 4-naphtho-[2,3-b]-benzofuranyl, 5-naphtho-[2,3-b]-benzofuranyl, 6-naphtho-[2,3-b]-benzofuranyl, 7-naphtho-[2,3-b]-benzofuranyl, 8-naphtho-[2,3-b]-benzofuranyl, 9-naphtho-[2,3-b]-benzofuranyl, 10-naphtho-[2,3-b]-benzofuranyl, 1-naphtho-[2,1-b]-benzofuranyl, 2-naphtho-[2,1-b]-benzofuranyl, 3-naphtho-[2,1-b]-benzofuranyl, 4-naphtho-[2,1-b]-benzofuranyl, 5-naphtho-[2,1-b]-benzofuranyl, 6-naphtho-[2,1-b]-benzofuranyl, 7-naphtho-[2,1-b]-benzofuranyl, 8-naphtho-[2,1-b]-benzofuranyl, 9-naphtho-[2,1-b]-benzofuranyl, 10-naphtho-[2,1-b]-benzofuranyl, 1-naphtho-[1,2-b]-benzothiophenyl, 2-naphtho-[1,2-b]-benzothiophenyl, 3-naphtho-[1,2-b]-benzothiophenyl, 4-naphtho-[1,2-b]-benzothiophenyl, 5-naphtho-[1,2-b]-benzothiophenyl, 6-naphtho-[1,2-b]-benzothiophenyl, 7-naphtho-[1,2-b]-benzothiophenyl, 8-naphtho-[1,2-b]-benzothiophenyl, 9-naphtho-[1,2-b]-benzothiophenyl, 10-naphtho-[1,2-b]-benzothiophenyl, 1-naphtho-[2,3-b]-benzothiophenyl, 2-naphtho-[2,3-b]-benzothiophenyl, 3-naphtho-[2,3-b]-benzothiophenyl, 4-naphtho-[2,3-b]-benzothiophenyl, 5-naphtho-[2,3-b]-benzothiophenyl, 1-naphtho-[2,1-b]-benzothiophenyl, 2-naphtho-[2,1-b]-benzothiophenyl, 3-naphtho-[2,1-b]-benzothiophenyl, 4-naphtho-[2,1-b]-benzothiophenyl, 5-naphtho-[2,1-b]-benzothiophenyl, 6-naphtho-[2,1-b]-benzothiophenyl, 7-naphtho-[2,1-b]-benzothiophenyl, 8-naphtho-[2,1-b]-benzothiophenyl, 9-naphtho-[2,1-b]-benzothiophenyl, 10-naphtho-[2,1-b]-benzothiophenyl, 2-benzofuro[3,2-d]pyrimidinyl, 6-benzofuro[3,2-d]pyrimidinyl, 7-benzofuro[3,2-d]pyrimidinyl, 8-benzofuro[3,2-d]pyrimidinyl, 9-benzofuro[3,2-d]pyrimidinyl, 2-benzothio[3,2-d]pyrimidinyl, 6-benzothio[3,2-d]pyrimidinyl, 7-benzothio[3,2-d]pyrimidinyl, 8-benzothio[3,2-d]pyrimidinyl, 9-benzothio[3,2-d]pyrimidinyl, 2-benzofuro[3,2-d]pyrazinyl, 6-benzofuro[3,2-d]pyrazinyl, 7-benzofuro[3,2-d]pyrazinyl, 8-benzofuro[3,2-d]pyrazinyl, 9-benzofuro[3,2-d]pyrazinyl, 2-benzothio[3,2-d]pyrazinyl, 6-benzothio[3,2-d]pyrazinyl, 7-benzothio[3,2-d]pyrazinyl, 8-benzothio[3,2-d]pyrazinyl, 9-benzothio[3,2-d]pyrazinyl, 1-silafluorenyl, 2-silafluorenyl, 3-silafluorenyl, 4-silafluorenyl, 1-germafluorenyl, 2-germafluorenyl, 3-germafluorenyl, 4-germafluorenyl, 1-dibenzoselenophenyl, 2-dibenzoselenophenyl, 3-dibenzoselenophenyl, 4-dibenzoselenophenyl, etc. The term “a fused ring group of a (C3-C30)aliphatic ring(s) and a (C6-C30) aromatic ring(s)” is meant to be a functional group in which at least one aliphatic ring(s) having 3 to 30 ring backbone carbon atoms, preferably 3 to 25 ring backbone carbon atoms, and more preferably 3 to 18 ring backbone carbon atoms and at least one aromatic ring(s) having 6 to 30 ring backbone carbon atoms, preferably 6 to 25 ring backbone carbon atoms, and more preferably 6 to 18 ring backbone carbon atoms are fused. For example, the fused ring group may include a fused ring group of at least one benzene and at least one cyclohexane, or a fused ring group of at least one naphthalene and at least one cyclopentane, etc. In the present disclosure, the carbon atom of the fused ring group of a (C3-C30) aliphatic ring(s) and a (C6-C30) aromatic ring(s) may be replaced with at least one heteroatom(s) selected from B, N, O, S, Si, and P, preferably at least one heteroatom(s) selected from N, O, and S. In the present disclosure, “halogen” includes F, Cl, Br, and I.

In addition, “ortho (o-),” “meta (m-),” and “para (p-)” are prefixes, which represent the relative positions of substituents, respectively. Ortho indicates that two substituents are adjacent to each other, and for example, when two substituents in a benzene derivative occupy positions 1 and 2, it is called an ortho position. Meta indicates that two substituents are at positions 1 and 3, and for example, when two substituents in a benzene derivative occupy positions 1 and 3, it is called a meta position. Para indicates that two substituents are at positions 1 and 4, and for example, when two substituents in a benzene derivative occupy positions 1 and 4, it is called a para position.

The term “a ring formed by a linkage of adjacent substituents” means that at least two adjacent substituents are linked to or fused with each other to form a substituted or unsubstituted mono- or polycyclic (3- to 30-membered) alicyclic or aromatic ring, or the combination thereof, preferably a substituted or unsubstituted mono- or polycyclic (5- to 25-membered) alicyclic or aromatic ring, or the combination thereof. In addition, the formed ring may contain at least one heteroatom selected from B, N, O, S, Si, and P, preferably at least one heteroatom selected from N, O, and S. According to one embodiment of the present disclosure, the number of ring backbone atoms is 5 to 20, and according to another embodiment of the present disclosure, the number of ring backbone atoms is 5 to 15.

In addition, “substituted” in the expression “substituted or unsubstituted” means that a hydrogen atom in a certain functional group is replaced with another atom or another functional group (i.e., a substituent), and also includes that the hydrogen atom is replaced with a group formed by a linkage of two or more substituents of the above substituents. For example, the “group formed by a linkage of two or more substituents” may be pyridine-triazine. That is, pyridine-triazine may be interpreted as a heteroaryl substituent, or as substituents in which two heteroaryls are linked. Herein, the substituent(s) of the substituted alkyl, the substituted alkenyl, the substituted aryl, the substituted arylene, the substituted heteroaryl, the substituted heteroarylene, the substituted cycloalkyl, the substituted alkoxy, the substituted trialkylsilyl, the substituted dialkylarylsilyl, the substituted alkyldiarylsilyl, the substituted triarylsilyl, and the substituted fused ring group of an aliphatic ring(s) and an aromatic ring(s) in the formulas of the present disclosure each independently are at least one selected from the group consisting of deuterium; a halogen; a cyano; a carboxyl; a nitro; a hydroxyl; a phosphine oxide; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (3- to 7-membered)heterocycloalkyl; a (C6-C30)aryloxy; a (C6-C30)arylthio; a (3- to 30-membered)heteroaryl; a (C6-C30)aryl unsubstituted or substituted with at least one of deuterium and a (C6-C30)aryl(s); a tri(C1-C30)alkylsilyl(s); a tri(C6-C30)arylsilyl(s); a di(C1-C30)alkyl(C6-C30)arylsilyl; a (C1-C30)alkyldi(C6-C30)arylsilyl; a fused ring group of a (C3-C30) aliphatic ring(s) and a (C6-C30) aromatic ring(s); an amino; a mono- or di- (C1-C30)alkylamino; a mono- or di- (C2-C30)alkenylamino; a (C1-C30)alkyl(C2-C30)alkenylamino; a mono- or di- (C6-C30)arylamino; a (C1-C30)alkyl(C6-C30)arylamino; a mono- or di- (3- to 30-membered)heteroarylamino; a (C1-C30)alkyl(3- to 30-membered)heteroarylamino; a (C2-C30)alkenyl(C6-C30)arylamino; a (C2-C30)alkenyl(3- to 30-membered)heteroarylamino; a (C6-C30)aryl(3- to 30-membered)heteroarylamino; a (C1-C30)alkylcarbonyl; a (C1-C30)alkoxycarbonyl; a (C6-C30)arylcarbonyl; a (C6-C30)arylphosphine; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl. According to one embodiment of the present disclosure, the substituent(s), each independently, are at least one selected from the group consisting of deuterium; a (C1-C20)alkyl; and a (C6-C18)aryl unsubstituted or substituted with deuterium or a (C6-C18)aryl(s). According to another embodiment of the present disclosure, the substituent(s), each independently, are at least one selected from the group consisting of deuterium; a (C1-C10)alkyl; and a (C6-C15)aryl unsubstituted or substituted with deuterium or a (C6-C30)aryl(s). For example, the substituent(s), each independently, may be deuterium, a methyl, a phenyl unsubstituted or substituted with a naphthyl(s), a biphenyl unsubstituted or substituted with deuterium, a naphthyl unsubstituted or substituted with a phenyl(s), etc.

The plurality of host materials according to the present disclosure comprises a first host material comprising the compound represented by formula 1 and a second host material comprising the compound represented by formula 2, and may be comprised in a light-emitting layer of the organic electroluminescent device according to the present disclosure.

Hereinafter, the compound represented by formula 1 will be described in more detail.

In formula 1, X₁, and Y₁, each independently represent —N═, —NR₁₁, —O— or —S—, with a proviso that any one of X₁, and Y₁, represents —N═, and the other of X₁, and Y₁, represents —NR₁₁—, —O— or —S—. For example, any one of X₁, and Y₁, may be —N═, and the other of X₁, and Y₁, may be —O—.

In formula 1, R₁, represents a substituted or unsubstituted (C6-C30)aryl, or a substituted or unsubstituted (3- to 30-membered)heteroaryl. According to one embodiment of the present disclosure, R₁, may be a substituted or unsubstituted (C6-C18)aryl. According to another embodiment of the present disclosure, R₁, may be an unsubstituted (C6-C12)aryl. For example, R₁, may be a phenyl, a naphthyl, etc.

In formula 1, R₂ to R₄ and R₁₁ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring group of a (C3-C30) aliphatic ring(s) and a (C6-C30) aromatic ring(s), or -L₂-N(Ar₁,)(Ar₂); or may be linked to an adjacent substituent(s) to form a ring(s). For example, R₂ to R₄ and R₁₁ may be hydrogen.

In formula 1, R₅ represents a substituted or unsubstituted (C6-C30)aryl, or a substituted or unsubstituted (3- to 30-membered)heteroaryl. According to one embodiment of the present disclosure, R₅ may be a substituted or unsubstituted (C6-C20)aryl, or a substituted or unsubstituted (3- to 20-membered)heteroaryl. According to another embodiment of the present disclosure, R₅ may be a (C6-C18)aryl unsubstituted or substituted with a (C1-C10)alkyl(s), or an unsubstituted (3- to 18-membered)heteroaryl. For example, R₅ may be a phenyl, a biphenyl, a naphthyl, a dimethylfluorenyl, a dibenzofuranyl, a dibenzothiophenyl, etc.

According to another embodiment of the present disclosure, R₅ may be a substituted or unsubstituted phenyl, a substituted or unsubstituted naphthyl, a substituted or unsubstituted biphenyl, a substituted or unsubstituted terphenyl, a substituted or unsubstituted phenanthrenyl, a substituted or unsubstituted anthracenyl, a substituted or unsubstituted fluorenyl, a substituted or unsubstituted benzofluorenyl, a substituted or unsubstituted triphenylenyl, a substituted or unsubstituted spirobifluorenyl, a substituted or unsubstituted carbazolyl, a substituted or unsubstituted dibenzothiophenyl, a substituted or unsubstituted benzothiophenyl, a substituted or unsubstituted dibenzofuranyl, or a substituted or unsubstituted benzofuranyl.

In formula 1, R₆ each independently represents hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring group of a (C3-C30) aliphatic ring(s) and a (C6-C30) aromatic ring(s), or -L₂-N(Ar₁)(Ar₂). For example, R₆ may be hydrogen.

In formula 1, L₁, and L₂ each independently represent a single bond, a substituted or unsubstituted (C6-C30)arylene, or a substituted or unsubstituted (3- to 30-membered)heteroarylene. According to one embodiment of the present disclosure, L₁, may be a single bond, or a substituted or unsubstituted (C6-C18)arylene. According to another embodiment of the present disclosure, L₁, may be a single bond, or an unsubstituted (C6-C12)arylene. For example, L₁, may be a single bond, phenylene, etc.

In formula 1, Arₙ and Ar₂ each independently represent hydrogen, a substituted or unsubstituted (C1-C30)alkyl, a substituted or unsubstituted (C2-C30)alkenyl, a substituted or unsubstituted fused ring group of a (C3-C30) aliphatic ring(s) and a (C6-C30) aromatic ring(s), a substituted or unsubstituted (C6-C30)aryl, or a substituted or unsubstituted (3- to 30-membered)heteroaryl.

In formula 1, n represents an integer of 0 to 3, a represents an integer of 1 to 5, d represents an integer of 1 to 4, and b and c each independently represent an integer of 1 or 2, where if a to d are an integer of 2 or more, each of R₂ to each of R₄, and each of R₆ may be the same as or different from each other. For example, n may be an integer of 0 or 1.

According to one embodiment of the present disclosure, formula 1 may be represented by the following formula 1-1.

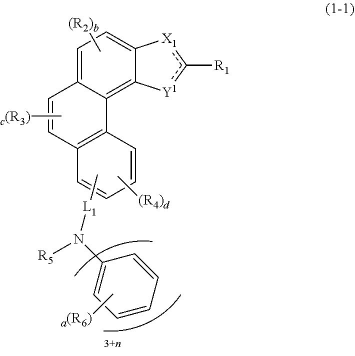

In formula 1-1, d represents an integer of 1 to 3, where if d is an integer of 2 or more, each of R₄ may be the same as or different from each other; and X₁, Y₁, R₁, to R₆, L₁, n, and a to c are as defined in formula 1.

According to one embodiment of the present disclosure, formula 1 may be represented by at least one of the following formulas 1-1-1 to 1-1-4.

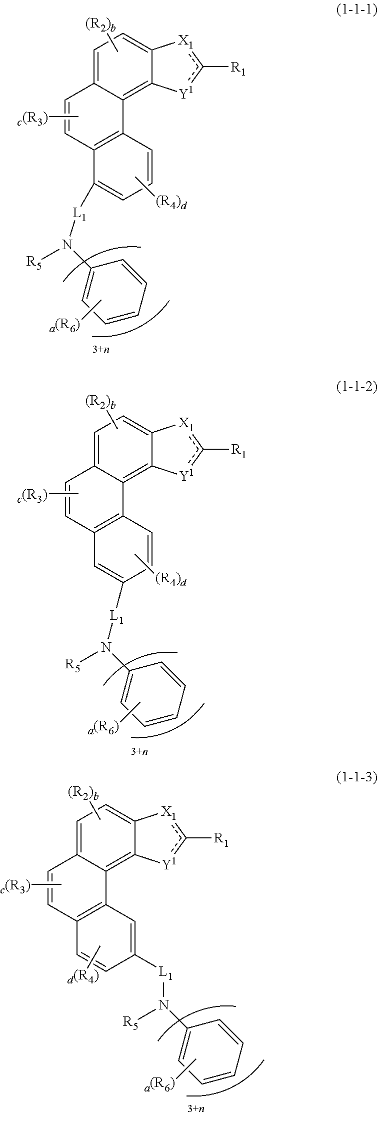

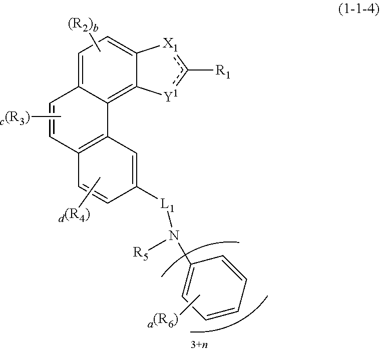

In formulas 1-1-1 to 1-1-4, d represents an integer of 1 to 3, where if d is an integer of 2 or more, each of R₄ may be the same as or different from each other; and X₁, Y₁, R₁, to R₆, L₁, n, and a to c are as defined in formula 1.

Hereinafter, the compound represented by formula 2 will be described in more detail.

In formula 2, X₂ represents —O— or —S—.

In formula 2, R₂₁ and R₂₂ each independently represent hydrogen, deuterium, or a substituted or unsubstituted (C6-C30)aryl. According to one embodiment of the present disclosure, R₂₁ and R₂₂ each independently may be hydrogen, deuterium, or a substituted or unsubstituted (C6-C20)aryl. According to another embodiment of the present disclosure, R₂₁ and R₂₂ each independently may be hydrogen, deuterium, or a (C6-C18)aryl unsubstituted or substituted with deuterium or a (C6-C18)aryl(s). For example, R₂₁ and R₂₂ each independently may be hydrogen, deuterium, a phenyl unsubstituted or substituted with a naphthyl(s), a biphenyl, a naphthyl unsubstituted or substituted with a phenyl(s), a phenanthrenyl, etc.

In formula 2, Ar₂₁ represents a substituted or unsubstituted naphthyl, a substituted or unsubstituted dibenzofuranyl, a substituted or unsubstituted dibenzothiophenyl, or a substituted or unsubstituted terphenyl. According to one embodiment of the present disclosure, Ar₂₁ may be a naphthyl unsubstituted or substituted with a (C6-C30)aryl(s); a dibenzofuranyl unsubstituted or substituted with at least one of deuterium and a (C6-C30)aryl(s); or an unsubstituted terphenyl. According to another embodiment of the present disclosure, Ar₂₁ may be a naphthyl unsubstituted or substituted with a (C6-C18)aryl(s); a dibenzofuranyl unsubstituted or substituted with at least one of deuterium and a (C6-C18)aryl(s); or an unsubstituted terphenyl. For example, Ar₂₁ may be a naphthyl unsubstituted or substituted with a phenyl(s), a naphthyl(s), or a biphenyl(s); a dibenzofuranyl unsubstituted or substituted with a phenyl(s), a naphthylphenyl(s), a biphenyl(s) unsubstituted or substituted with deuterium, a naphthyl(s), or a phenylnaphthyl(s); a terphenyl, etc.

In formula 2, Ar₂₂ represents a substituted or unsubstituted phenyl, a substituted or unsubstituted biphenyl, a substituted or unsubstituted naphthyl, or a substituted or unsubstituted terphenyl. According to one embodiment of the present disclosure, Ar₂₂ may be a phenyl unsubstituted or substituted with a (C6-C30)aryl(s), an unsubstituted biphenyl, a naphthyl unsubstituted or substituted with a (C6-C30)aryl(s), or an unsubstituted terphenyl. According to another embodiment of the present disclosure, Ar₂₂ may be a phenyl unsubstituted or substituted with a (C6-C18)aryl(s), an unsubstituted biphenyl, a naphthyl unsubstituted or substituted with a (C6-C12)aryl(s), or an unsubstituted terphenyl. For example, Ar₂₂ may be a phenyl unsubstituted or substituted with a naphthyl(s); a biphenyl; a naphthyl unsubstituted or substituted with a phenyl(s) or a naphthyl(s); a terphenyl, etc.

In formula 2, a′ represents an integer of 1 to 3, and b′ represents an integer of 1 to 4, where if a′ and b′ represent an integer of 2 or more, each of R₂₁ and each of R₂₂ may be the same as or different from each other.

In formula 2, the substituents of the substituted aryl, the substituted phenyl, the substituted biphenyl, the substituted terphenyl, the substituted naphthyl, the substituted dibenzofuranyl, and the substituted dibenzothiophenyl in formula 2 are each independently at least one of deuterium and a (C6-C30)aryl.

According to one embodiment of the present disclosure, formula 2 may be represented by at least one of the following formulas 2-1 to 2-4.

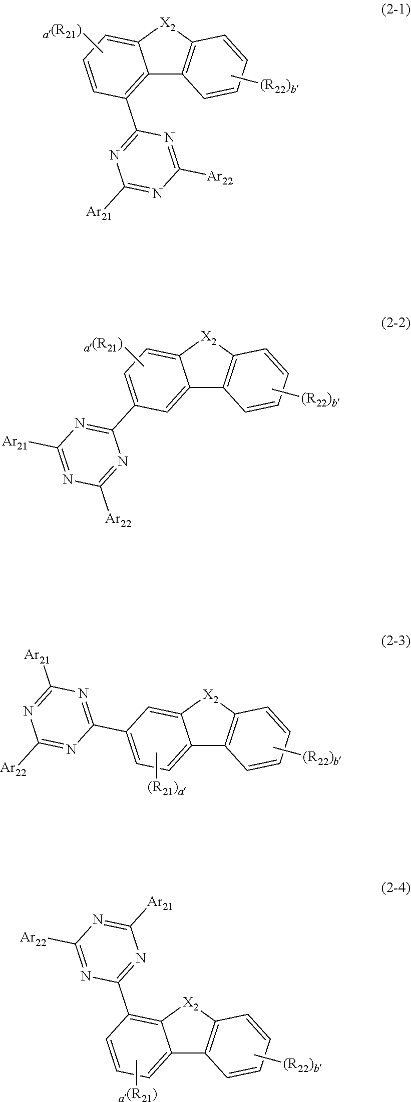

In formulas 2-1 to 2-4, X₂, Ar₂₁, Ar₂₂, R₂₁, R₂₂, a′, and b′ are as defined in formula 2.

The compound represented by formula 1 may be at least one selected from the following compounds, but is not limited thereto.

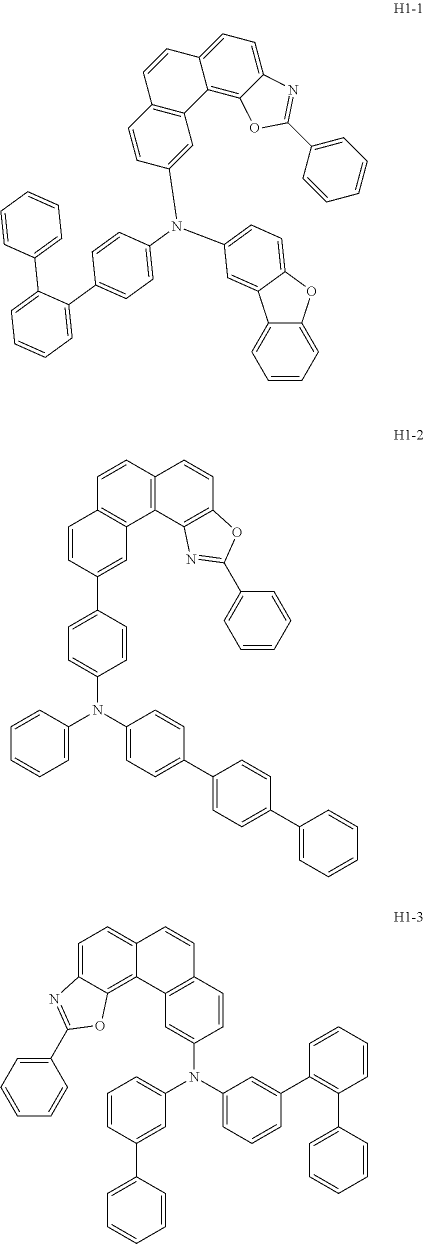 [SMILES: c1ccc(-c2nc3ccc4ccc5ccc(N(c6ccc(-c7ccccc7-c7ccccc7)cc6)c6ccc7oc8ccccc8c7c6)cc5c4c3o2)cc1 ; c1ccc(-c2ccc(-c3ccc(N(c4ccccc4)c4ccc(-c5ccc6ccc7ccc8oc(-c9ccccc9)nc8c7c6c5)cc4)cc3)cc2)cc1 ; c1ccc(-c2cccc(N(c3cccc(-c4ccccc4-c4ccccc4)c3)c3ccc4ccc5ccc6nc(-c7ccccc7)oc6c5c4c3)c2)cc1]

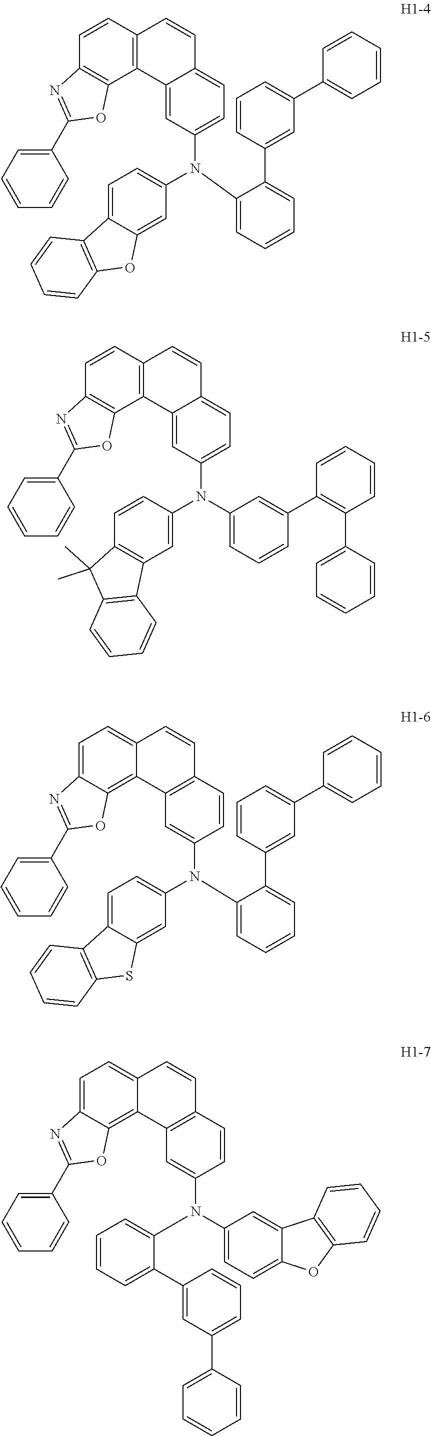 [SMILES: c1ccc(-c2cccc(-c3ccccc3N(c3ccc4c(c3)oc3ccccc34)c3ccc4ccc5ccc6nc(-c7ccccc7)oc6c5c4c3)c2)cc1 ; CC1(C)c2ccccc2-c2cc(N(c3cccc(-c4ccccc4-c4ccccc4)c3)c3ccc4ccc5ccc6nc(-c7ccccc7)oc6c5c4c3)ccc21 ; c1ccc(-c2cccc(-c3ccccc3N(c3ccc4c(c3)sc3ccccc34)c3ccc4ccc5ccc6nc(-c7ccccc7)oc6c5c4c3)c2)cc1 ; c1ccc(-c2cccc(-c3ccccc3N(c3ccc4oc5ccccc5c4c3)c3ccc4ccc5ccc6nc(-c7ccccc7)oc6c5c4c3)c2)cc1]

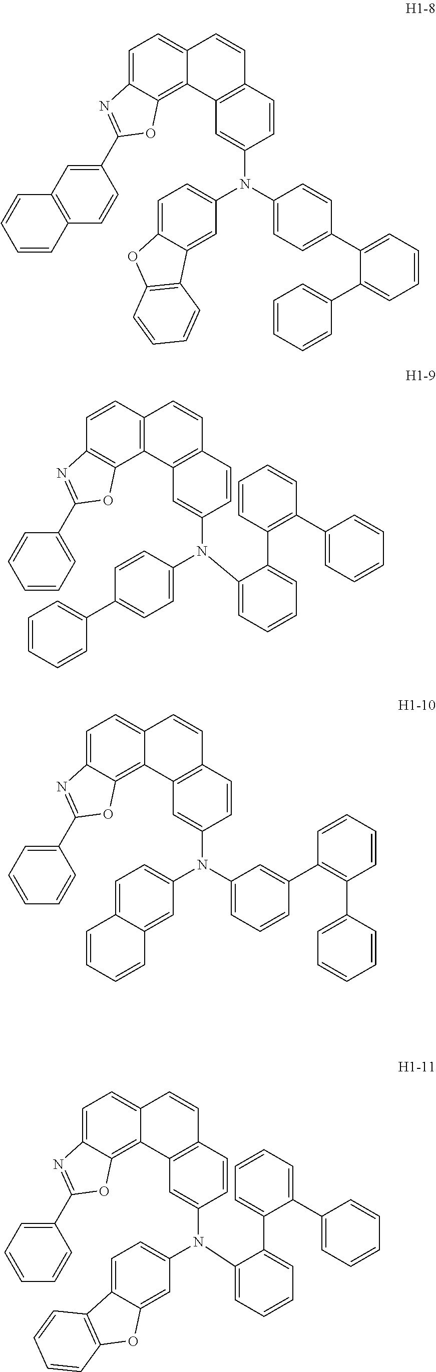 [SMILES: c1ccc(-c2ccccc2-c2ccc(N(c3ccc4oc5ccccc5c4c3)c3ccc4ccc5ccc6nc(-c7ccc8ccccc8c7)oc6c5c4c3)cc2)cc1 ; c1ccc(-c2ccc(N(c3ccc4ccc5ccc6nc(-c7ccccc7)oc6c5c4c3)c3ccccc3-c3ccccc3-c3ccccc3)cc2)cc1 ; c1ccc(-c2nc3ccc4ccc5ccc(N(c6cccc(-c7ccccc7-c7ccccc7)c6)c6ccc7ccccc7c6)cc5c4c3o2)cc1 ; c1ccc(-c2nc3ccc4ccc5ccc(N(c6ccc7c(c6)oc6ccccc67)c6ccccc6-c6ccccc6-c6ccccc6)cc5c4c3o2)cc1]

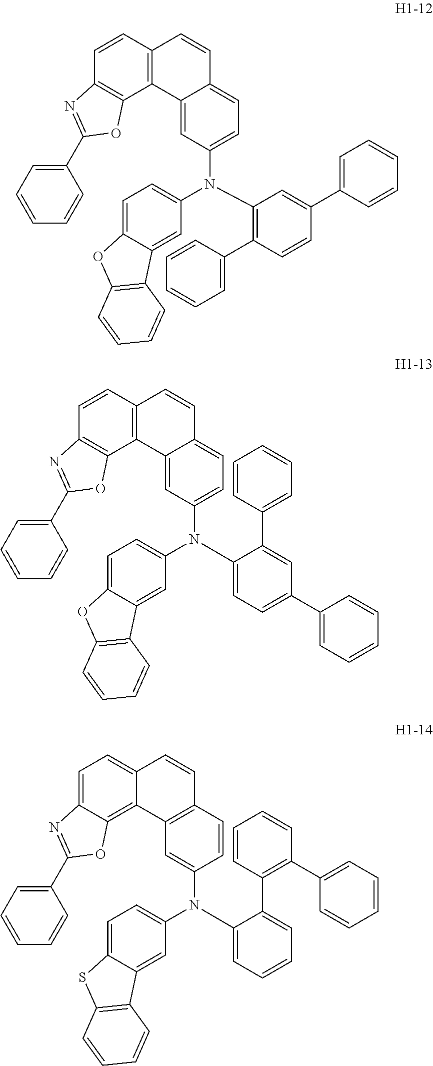

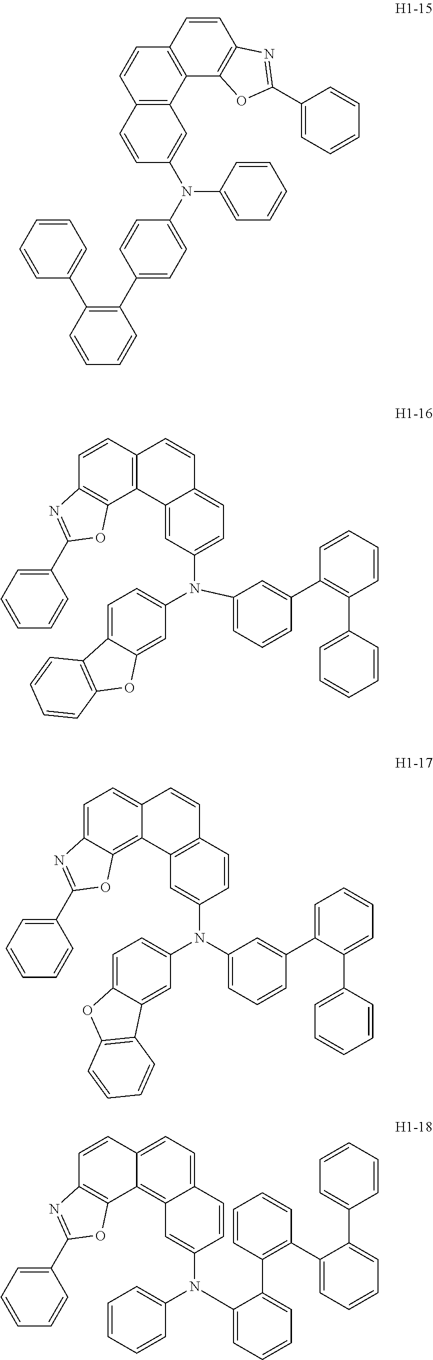

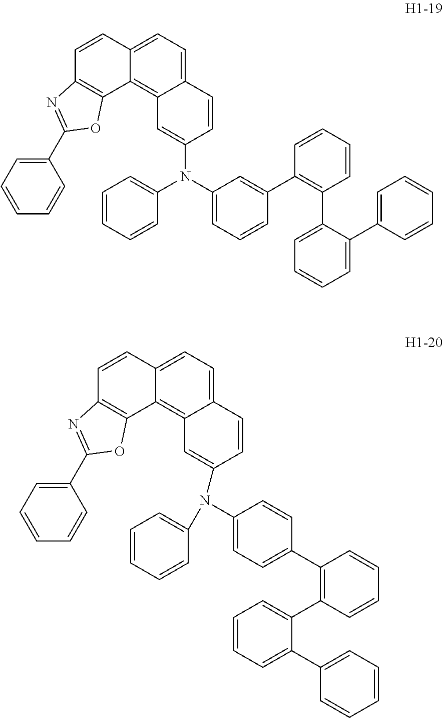 [SMILES: c1ccc(-c2nc3ccc4ccc5ccc(N(c6ccccc6)c6cccc(-c7ccccc7-c7ccccc7-c7ccccc7)c6)cc5c4c3o2)cc1 ; c1ccc(-c2nc3ccc4ccc5ccc(N(c6ccccc6)c6ccc(-c7ccccc7-c7ccccc7-c7ccccc7)cc6)cc5c4c3o2)cc1]

The compound represented by formula 2 may be at least one selected from the following compounds, but is not limited thereto.

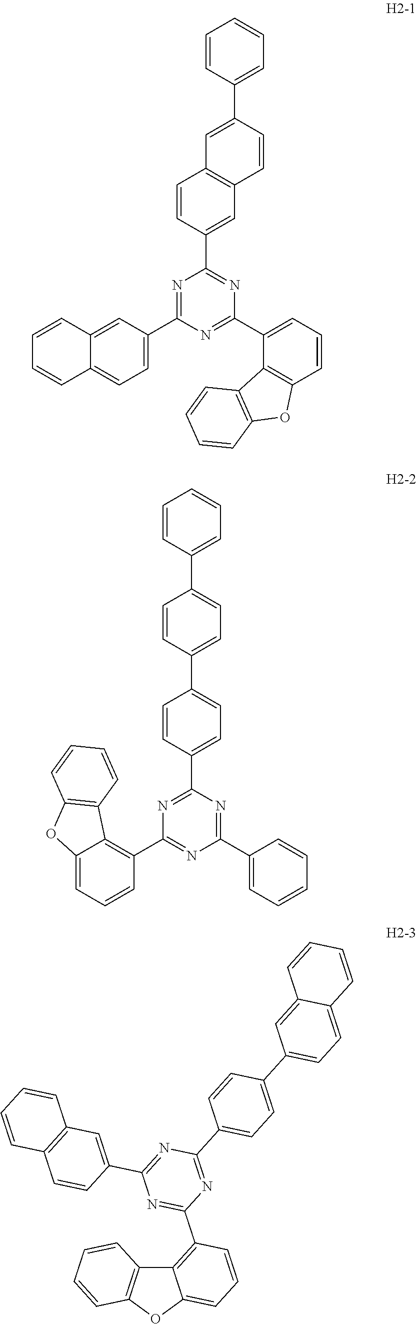

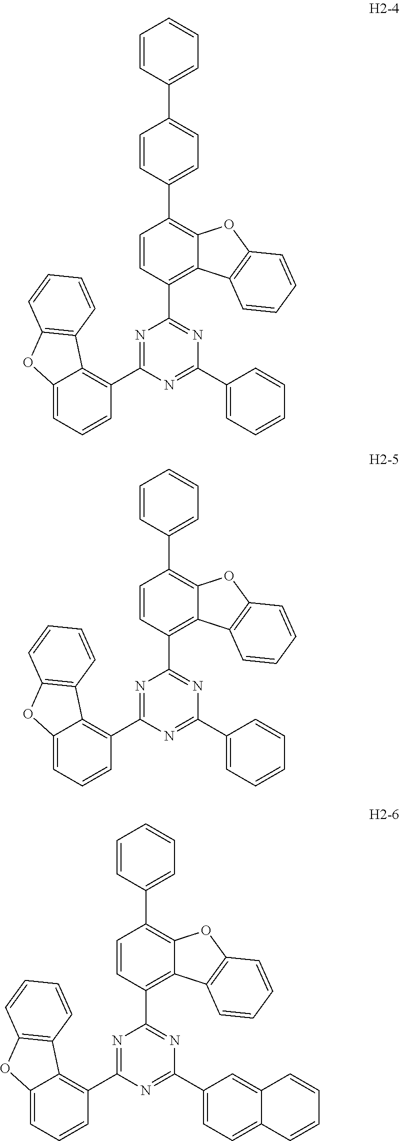 [SMILES: c1ccc(-c2ccc(-c3ccc(-c4nc(-c5ccccc5)nc(-c5cccc6oc7ccccc7c56)n4)c4c3oc3ccccc34)cc2)cc1 ; c1ccc(-c2nc(-c3cccc4oc5ccccc5c34)nc(-c3ccc(-c4ccccc4)c4oc5ccccc5c34)n2)cc1 ; c1ccc(-c2ccc(-c3nc(-c4ccc5ccccc5c4)nc(-c4cccc5oc6ccccc6c45)n3)c3c2oc2ccccc23)cc1]

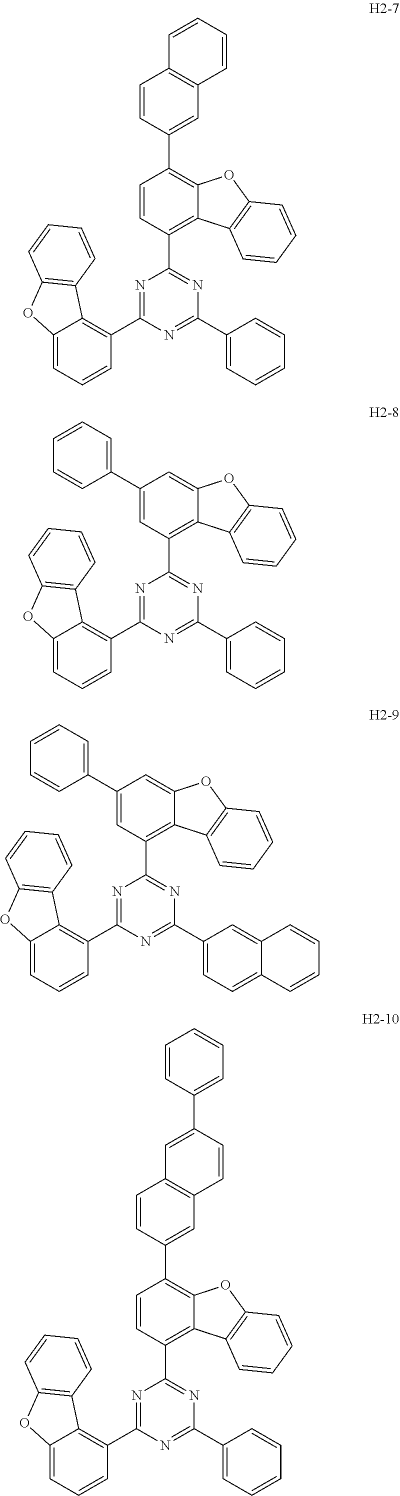

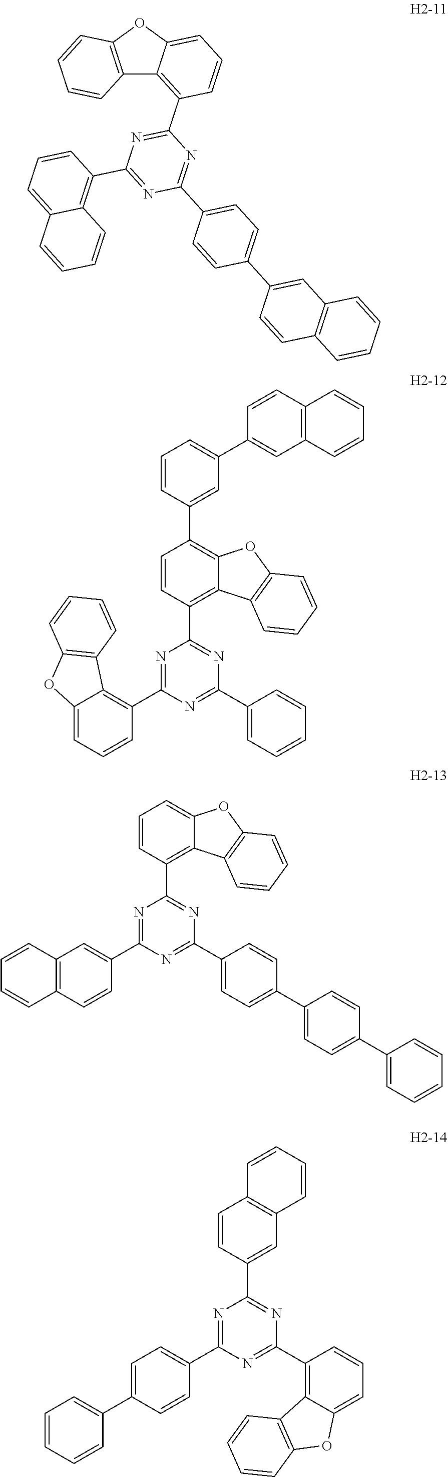

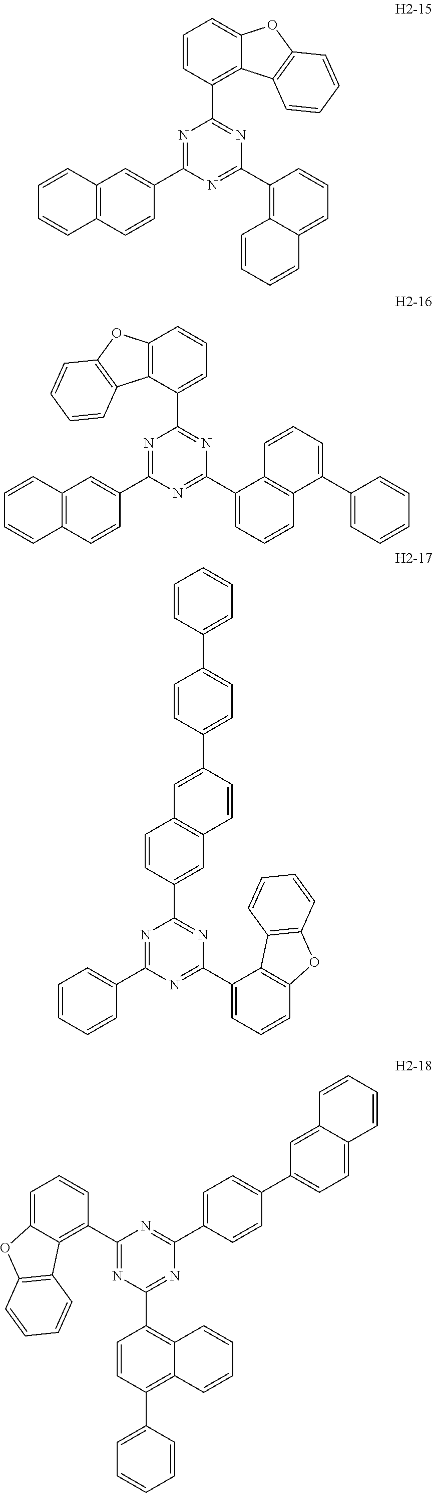 [SMILES: c1ccc2cc(-c3nc(-c4cccc5ccccc45)nc(-c4cccc5oc6ccccc6c45)n3)ccc2c1 ; c1ccc(-c2cccc3c(-c4nc(-c5ccc6ccccc6c5)nc(-c5cccc6oc7ccccc7c56)n4)cccc23)cc1 ; c1ccc(-c2ccc(-c3ccc4cc(-c5nc(-c6ccccc6)nc(-c6cccc7oc8ccccc8c67)n5)ccc4c3)cc2)cc1 ; c1ccc(-c2ccc(-c3nc(-c4ccc(-c5ccc6ccccc6c5)cc4)nc(-c4cccc5oc6ccccc6c45)n3)c3ccccc23)cc1]

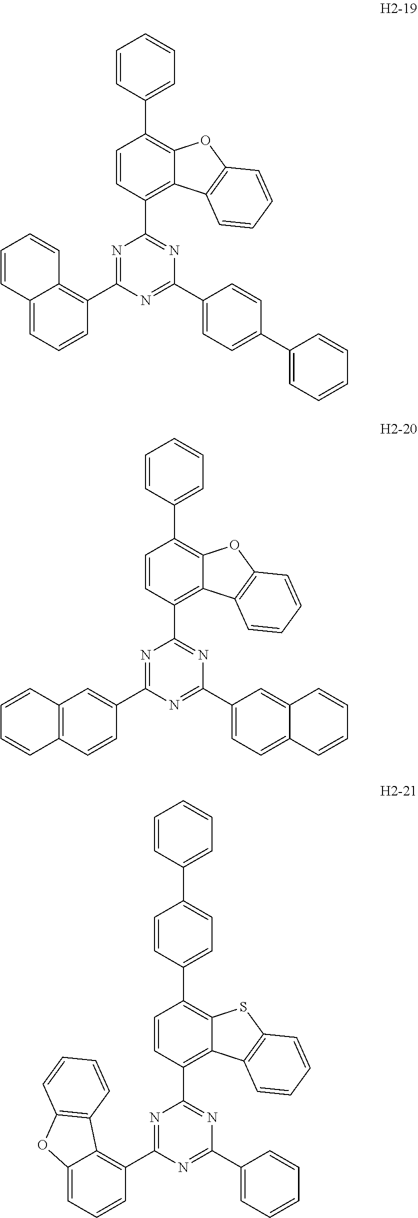 [SMILES: c1ccc(-c2ccc(-c3nc(-c4cccc5ccccc45)nc(-c4ccc(-c5ccccc5)c5oc6ccccc6c45)n3)cc2)cc1 ; c1ccc(-c2ccc(-c3nc(-c4ccc5ccccc5c4)nc(-c4ccc5ccccc5c4)n3)c3c2oc2ccccc23)cc1 ; c1ccc(-c2ccc(-c3ccc(-c4nc(-c5ccccc5)nc(-c5cccc6oc7ccccc7c56)n4)c4c3sc3ccccc34)cc2)cc1]

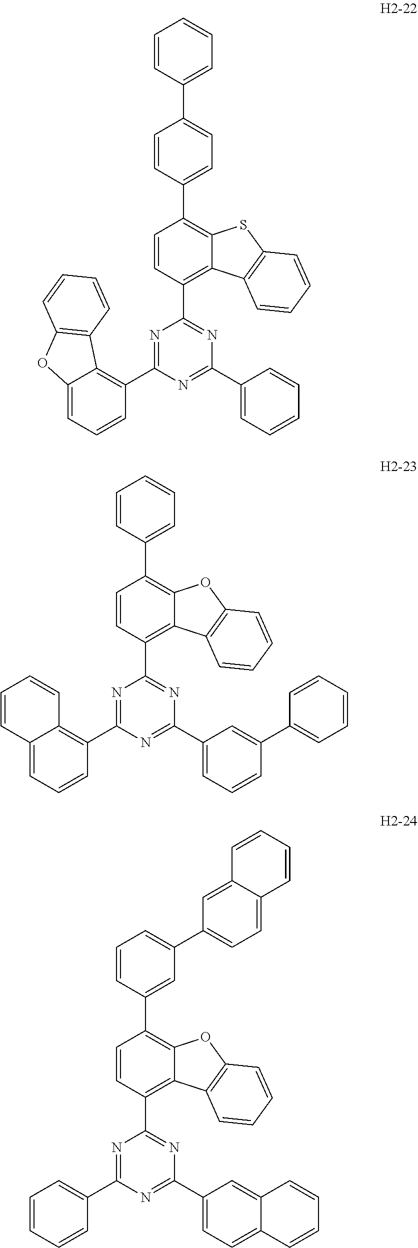 [SMILES: c1ccc(-c2ccc(-c3ccc(-c4nc(-c5ccccc5)nc(-c5cccc6oc7ccccc7c56)n4)c4c3sc3ccccc34)cc2)cc1 ; c1ccc(-c2cccc(-c3nc(-c4cccc5ccccc45)nc(-c4ccc(-c5ccccc5)c5oc6ccccc6c45)n3)c2)cc1 ; c1ccc(-c2nc(-c3ccc4ccccc4c3)nc(-c3ccc(-c4cccc(-c5ccc6ccccc6c5)c4)c4oc5ccccc5c34)n2)cc1]

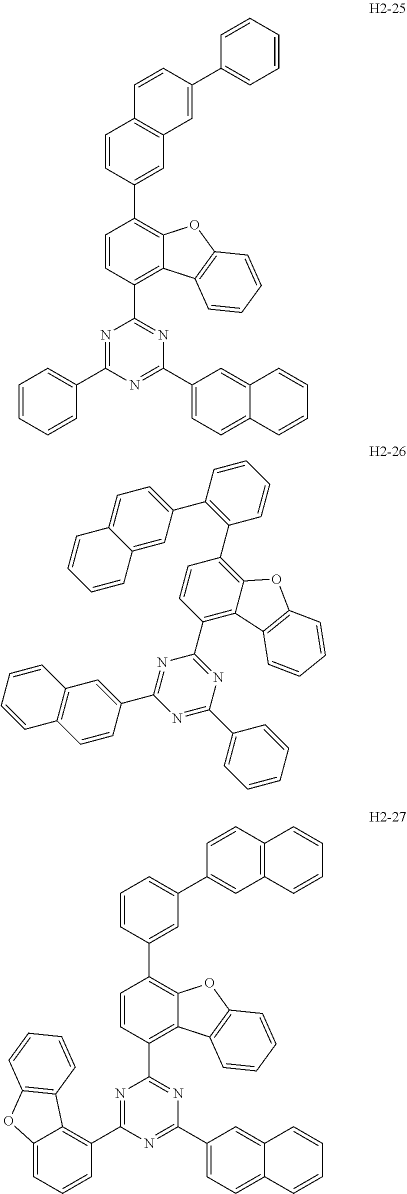

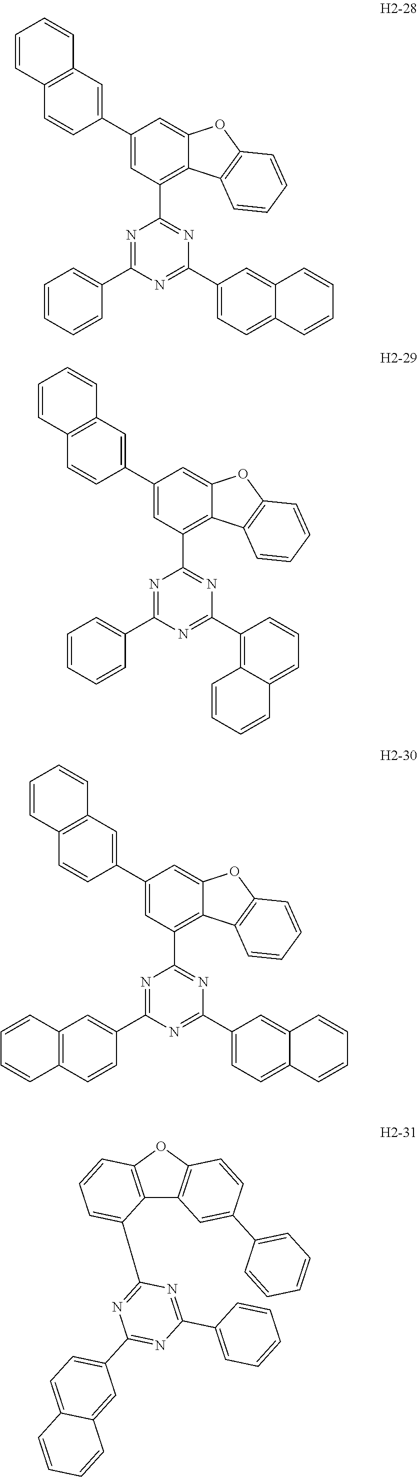

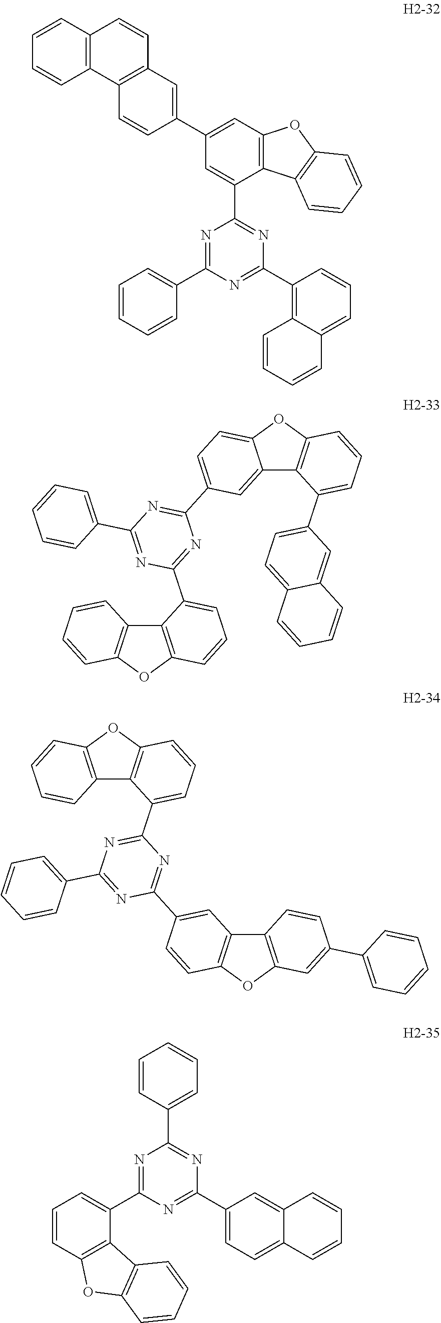

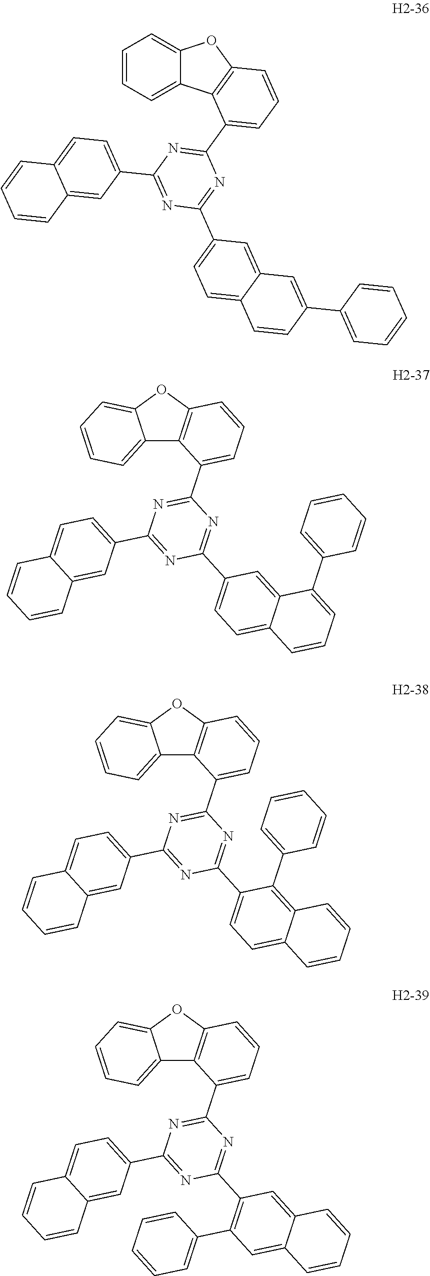 [SMILES: c1ccc(-c2ccc3ccc(-c4nc(-c5ccc6ccccc6c5)nc(-c5cccc6oc7ccccc7c56)n4)cc3c2)cc1 ; c1ccc(-c2cccc3ccc(-c4nc(-c5ccc6ccccc6c5)nc(-c5cccc6oc7ccccc7c56)n4)cc23)cc1 ; c1ccc(-c2c(-c3nc(-c4ccc5ccccc5c4)nc(-c4cccc5oc6ccccc6c45)n3)ccc3ccccc23)cc1 ; c1ccc(-c2cc3ccccc3cc2-c2nc(-c3ccc4ccccc4c3)nc(-c3cccc4oc5ccccc5c34)n2)cc1]

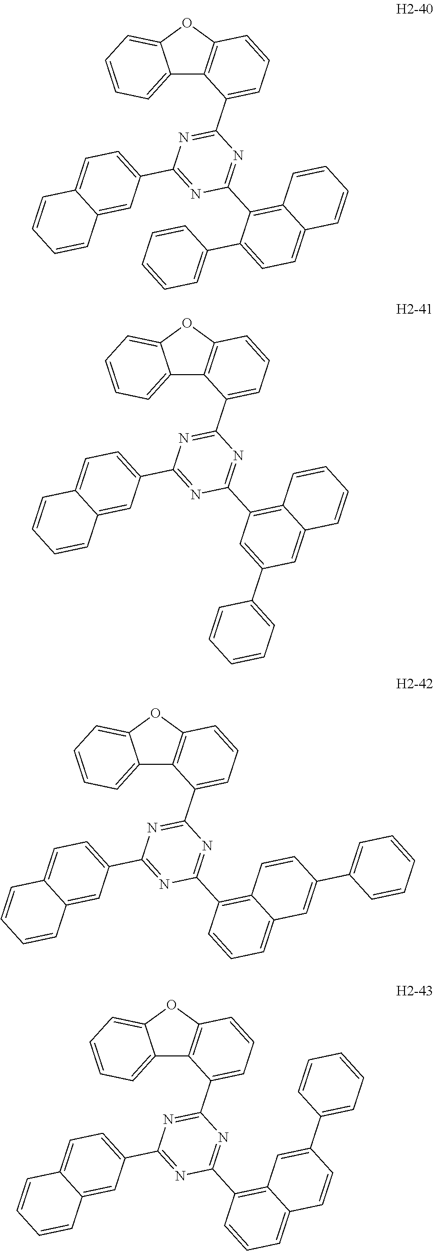

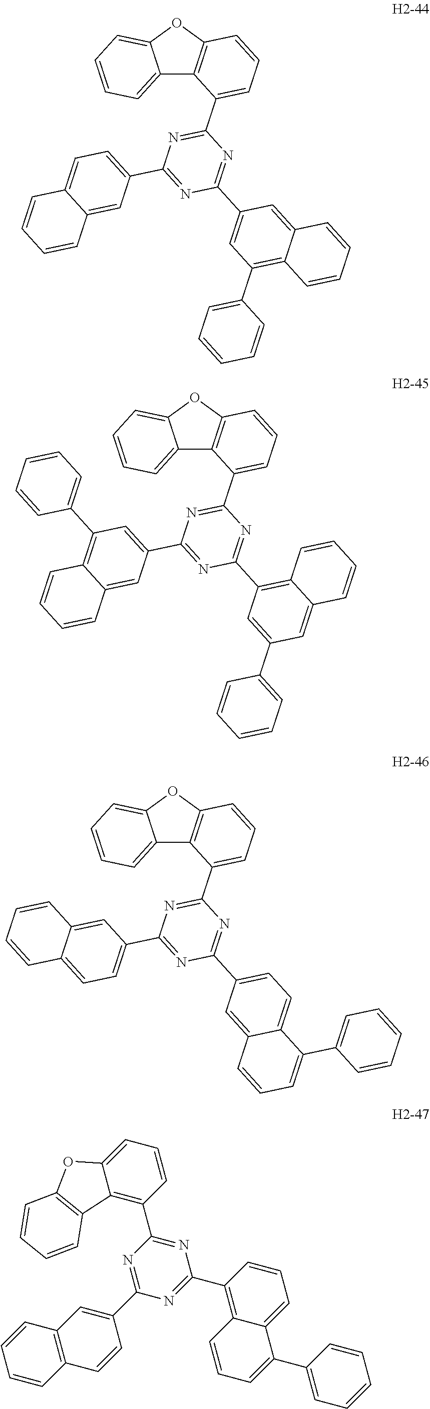

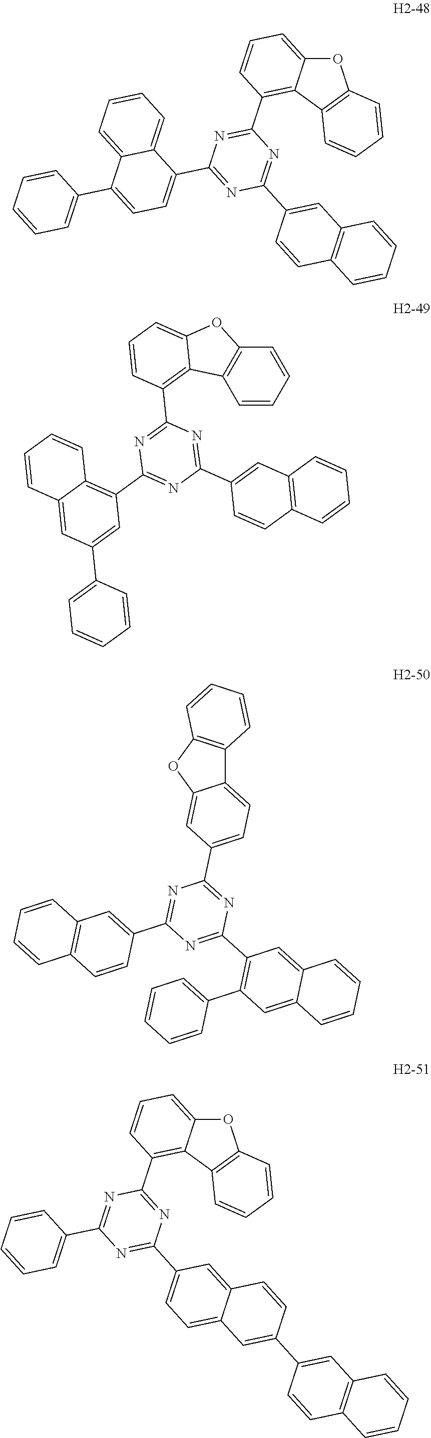 [SMILES: c1ccc(-c2ccc(-c3nc(-c4ccc5ccccc5c4)nc(-c4cccc5oc6ccccc6c45)n3)c3ccccc23)cc1 ; c1ccc(-c2cc(-c3nc(-c4ccc5ccccc5c4)nc(-c4cccc5oc6ccccc6c45)n3)c3ccccc3c2)cc1 ; c1ccc(-c2cc3ccccc3cc2-c2nc(-c3ccc4ccccc4c3)nc(-c3ccc4c(c3)oc3ccccc34)n2)cc1 ; c1ccc(-c2nc(-c3ccc4cc(-c5ccc6ccccc6c5)ccc4c3)nc(-c3cccc4oc5ccccc5c34)n2)cc1]

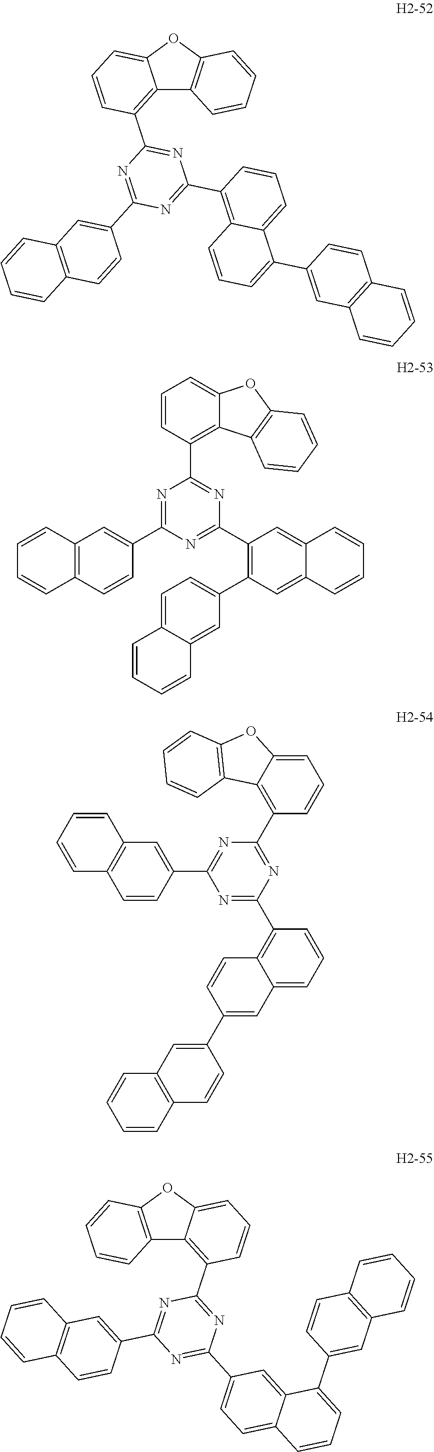 [SMILES: c1ccc2cc(-c3nc(-c4cccc5c(-c6ccc7ccccc7c6)cccc45)nc(-c4cccc5oc6ccccc6c45)n3)ccc2c1 ; c1ccc2cc(-c3nc(-c4cc5ccccc5cc4-c4ccc5ccccc5c4)nc(-c4cccc5oc6ccccc6c45)n3)ccc2c1 ; c1ccc2cc(-c3ccc4c(-c5nc(-c6ccc7ccccc7c6)nc(-c6cccc7oc8ccccc8c67)n5)cccc4c3)ccc2c1 ; c1ccc2cc(-c3nc(-c4ccc5cccc(-c6ccc7ccccc7c6)c5c4)nc(-c4cccc5oc6ccccc6c45)n3)ccc2c1]

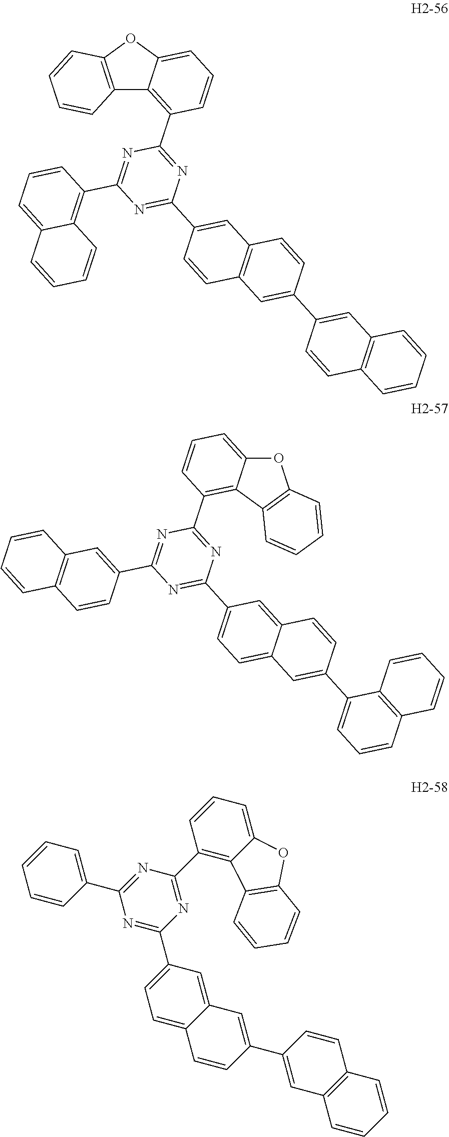 [SMILES: c1ccc2cc(-c3ccc4cc(-c5nc(-c6cccc7ccccc67)nc(-c6cccc7oc8ccccc8c67)n5)ccc4c3)ccc2c1 ; c1ccc2cc(-c3nc(-c4ccc5cc(-c6cccc7ccccc67)ccc5c4)nc(-c4cccc5oc6ccccc6c45)n3)ccc2c1 ; c1ccc(-c2nc(-c3ccc4ccc(-c5ccc6ccccc6c5)cc4c3)nc(-c3cccc4oc5ccccc5c34)n2)cc1]

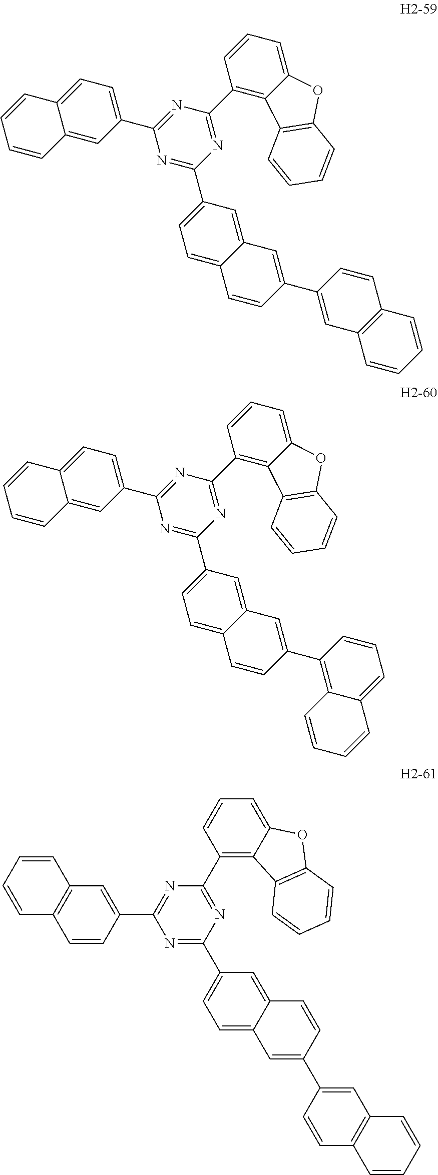 [SMILES: c1ccc2cc(-c3ccc4ccc(-c5nc(-c6ccc7ccccc7c6)nc(-c6cccc7oc8ccccc8c67)n5)cc4c3)ccc2c1 ; c1ccc2cc(-c3nc(-c4ccc5ccc(-c6cccc7ccccc67)cc5c4)nc(-c4cccc5oc6ccccc6c45)n3)ccc2c1 ; c1ccc2cc(-c3ccc4cc(-c5nc(-c6ccc7ccccc7c6)nc(-c6cccc7oc8ccccc8c67)n5)ccc4c3)ccc2c1]

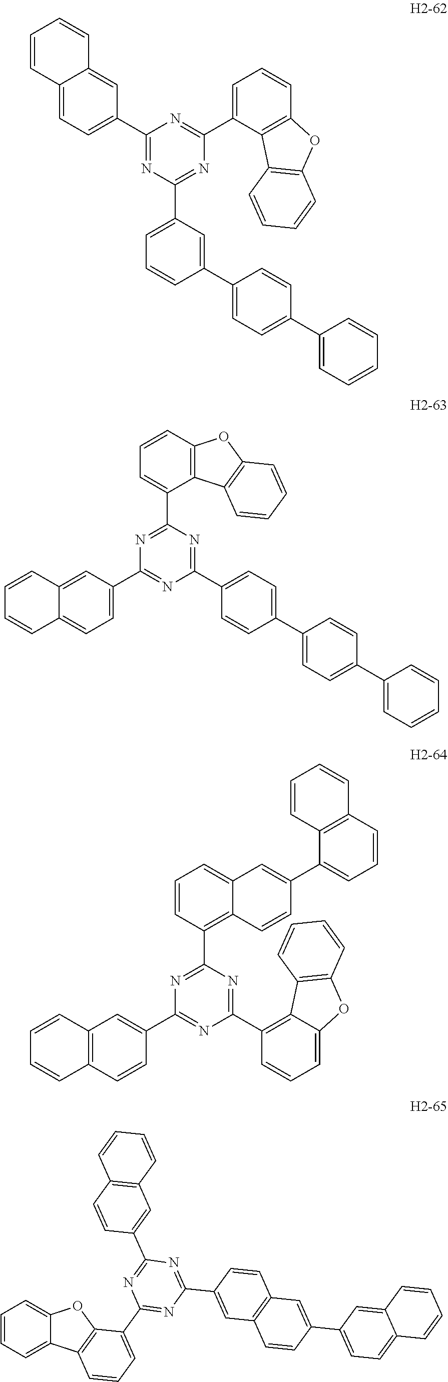 [SMILES: c1ccc(-c2ccc(-c3cccc(-c4nc(-c5ccc6ccccc6c5)nc(-c5cccc6oc7ccccc7c56)n4)c3)cc2)cc1 ; c1ccc(-c2ccc(-c3ccc(-c4nc(-c5ccc6ccccc6c5)nc(-c5cccc6oc7ccccc7c56)n4)cc3)cc2)cc1 ; c1ccc2cc(-c3nc(-c4cccc5cc(-c6cccc7ccccc67)ccc45)nc(-c4cccc5oc6ccccc6c45)n3)ccc2c1 ; c1ccc2cc(-c3ccc4cc(-c5nc(-c6ccc7ccccc7c6)nc(-c6cccc7c6oc6ccccc67)n5)ccc4c3)ccc2c1]

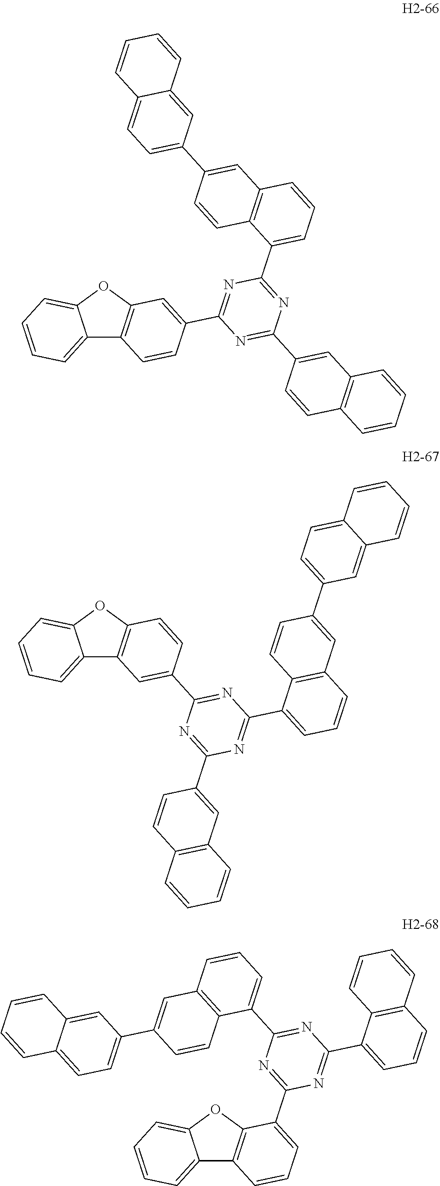 [SMILES: c1ccc2cc(-c3ccc4c(-c5nc(-c6ccc7ccccc7c6)nc(-c6ccc7c(c6)oc6ccccc67)n5)cccc4c3)ccc2c1 ; c1ccc2cc(-c3ccc4c(-c5nc(-c6ccc7ccccc7c6)nc(-c6ccc7oc8ccccc8c7c6)n5)cccc4c3)ccc2c1 ; c1ccc2cc(-c3ccc4c(-c5nc(-c6cccc7ccccc67)nc(-c6cccc7c6oc6ccccc67)n5)cccc4c3)ccc2c1]

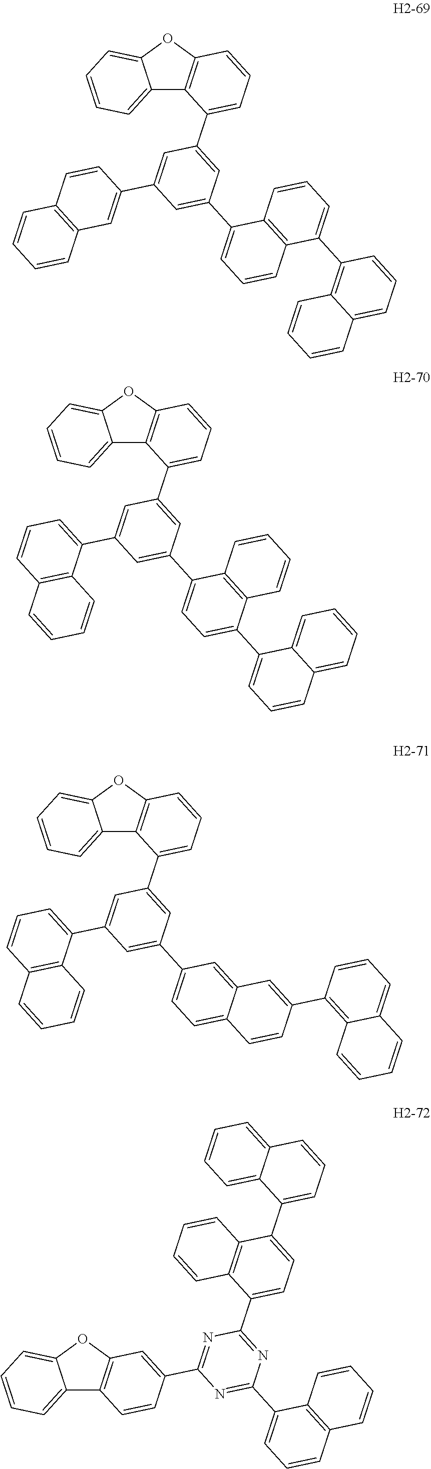 [SMILES: c1ccc2cc(-c3cc(-c4cccc5c(-c6cccc7ccccc67)cccc45)cc(-c4cccc5oc6ccccc6c45)c3)ccc2c1 ; c1ccc2c(-c3cc(-c4ccc(-c5cccc6ccccc56)c5ccccc45)cc(-c4cccc5oc6ccccc6c45)c3)cccc2c1 ; c1ccc2c(-c3cc(-c4ccc5ccc(-c6cccc7ccccc67)cc5c4)cc(-c4cccc5oc6ccccc6c45)c3)cccc2c1 ; c1ccc2c(-c3nc(-c4ccc5c(c4)oc4ccccc45)nc(-c4ccc(-c5cccc6ccccc56)c5ccccc45)n3)cccc2c1]

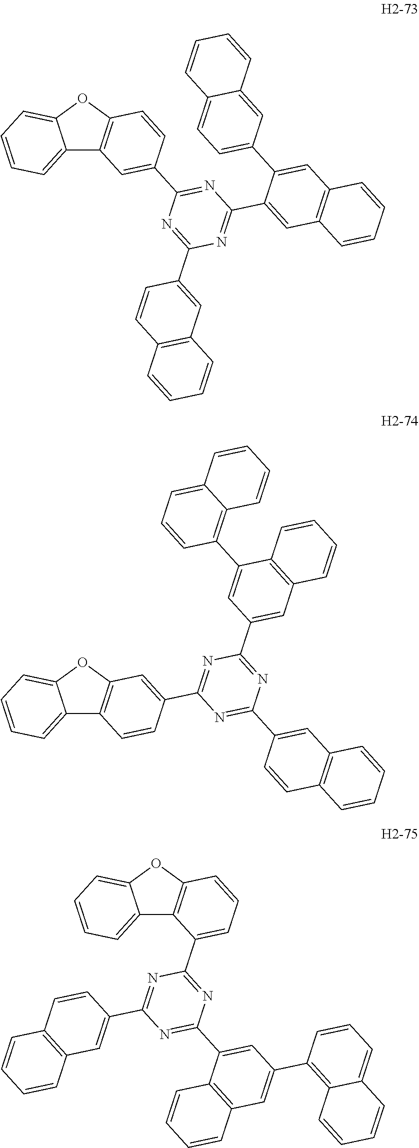 [SMILES: c1ccc2cc(-c3nc(-c4ccc5oc6ccccc6c5c4)nc(-c4cc5ccccc5cc4-c4ccc5ccccc5c4)n3)ccc2c1 ; c1ccc2cc(-c3nc(-c4cc(-c5cccc6ccccc56)c5ccccc5c4)nc(-c4ccc5c(c4)oc4ccccc45)n3)ccc2c1 ; c1ccc2cc(-c3nc(-c4cc(-c5cccc6ccccc56)cc5ccccc45)nc(-c4cccc5oc6ccccc6c45)n3)ccc2c1]

A combination of at least one of compounds H1-1 to H1-20 and at least one of compounds H2-1 to H2-75 may be used in an organic electroluminescent device.

Hereinafter, an organic electroluminescent compound according to one embodiment of the present disclosure will be described.

An organic electroluminescent compound according to one embodiment of the present disclosure is represented by the following formula 21.

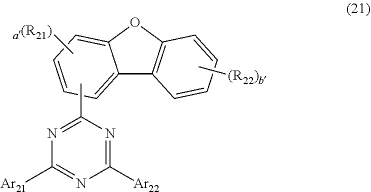

In formula 21,

Ar₂₁ represents a naphthyl unsubstituted or substituted with deuterium, a phenylnaphthyl unsubstituted or substituted with deuterium, a naphthylphenyl unsubstituted or substituted with deuterium, or a terphenyl unsubstituted or substituted with deuterium;

Ar₂₂ represents a binaphthyl unsubstituted or substituted with deuterium;

R₂₁ and R₂₂ each independently represent hydrogen or deuterium; and

a′ represents an integer of 1 to 3, and b′ represents an integer of 1 to 4, where if a′ and b′ represent an integer of 2 or more, each of R₂₁ and each of R₂₂ may be the same as or different from each other.

According to one embodiment of the present disclosure, Ar₂₁ may be a naphthyl unsubstituted or substituted with deuterium.

According to one embodiment of the present disclosure, Ar₂₂ is represented by one of the following formulas A-1 and A-2.

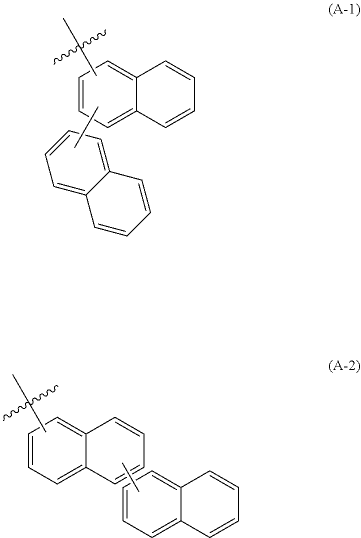

In formulas A-1 and A-2, the hydrogen of the naphthalenes may be substituted with deuterium.

According to one embodiment of the present disclosure, formula 21 is represented by the following formula 21-1.

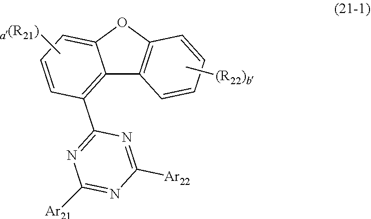

In formula 21-1, Ar₂₁, Ar₂₂, R₂₁, R₂₂, a′, and b′ are as defined in formula 21.

The compound represented by formula 21 may be at least one selected from the following compounds, but is not limited thereto.

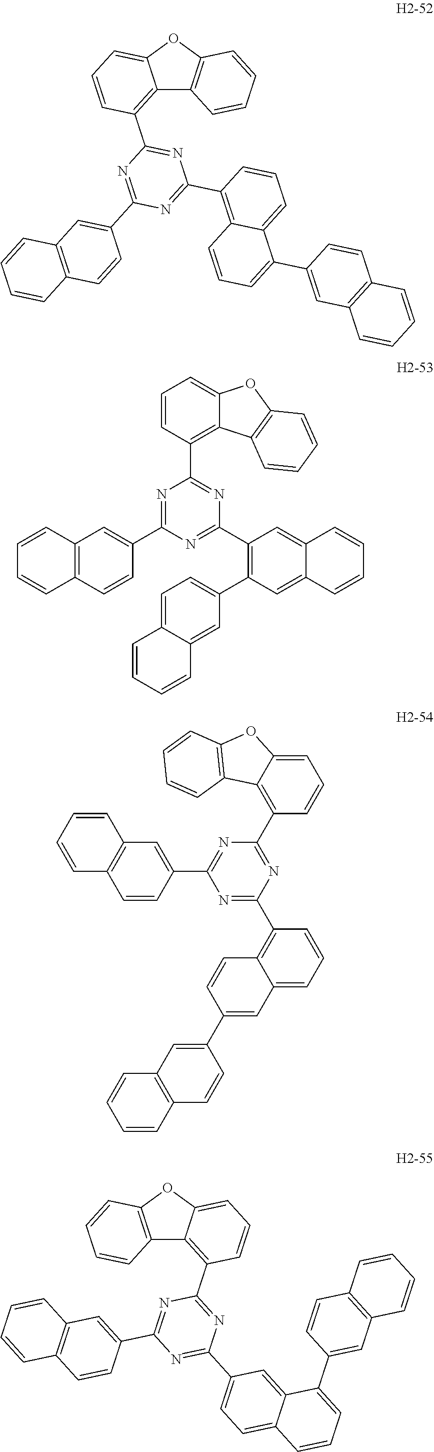 [SMILES: c1ccc2cc(-c3nc(-c4cccc5c(-c6ccc7ccccc7c6)cccc45)nc(-c4cccc5oc6ccccc6c45)n3)ccc2c1 ; c1ccc2cc(-c3nc(-c4cc5ccccc5cc4-c4ccc5ccccc5c4)nc(-c4cccc5oc6ccccc6c45)n3)ccc2c1 ; c1ccc2cc(-c3ccc4c(-c5nc(-c6ccc7ccccc7c6)nc(-c6cccc7oc8ccccc8c67)n5)cccc4c3)ccc2c1 ; c1ccc2cc(-c3nc(-c4ccc5cccc(-c6ccc7ccccc7c6)c5c4)nc(-c4cccc5oc6ccccc6c45)n3)ccc2c1]

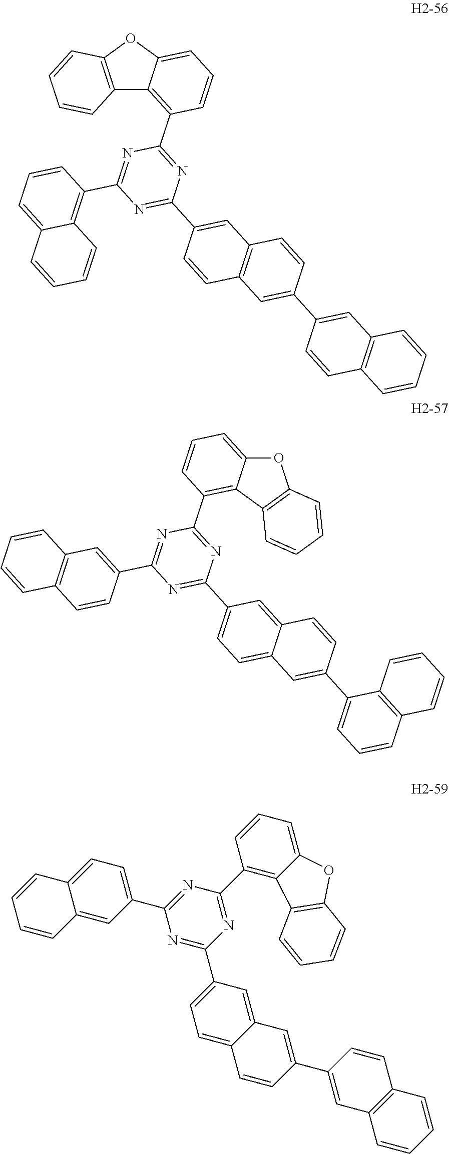 [SMILES: c1ccc2cc(-c3ccc4cc(-c5nc(-c6cccc7ccccc67)nc(-c6cccc7oc8ccccc8c67)n5)ccc4c3)ccc2c1 ; c1ccc2cc(-c3nc(-c4ccc5cc(-c6cccc7ccccc67)ccc5c4)nc(-c4cccc5oc6ccccc6c45)n3)ccc2c1 ; c1ccc2cc(-c3ccc4ccc(-c5nc(-c6ccc7ccccc7c6)nc(-c6cccc7oc8ccccc8c67)n5)cc4c3)ccc2c1]

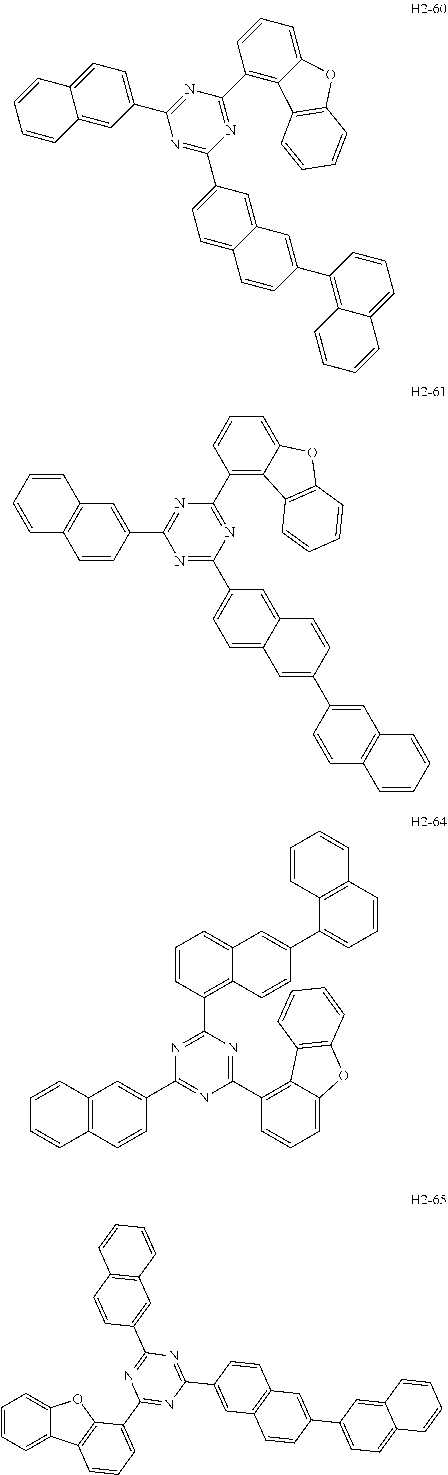 [SMILES: c1ccc2cc(-c3nc(-c4ccc5ccc(-c6cccc7ccccc67)cc5c4)nc(-c4cccc5oc6ccccc6c45)n3)ccc2c1 ; c1ccc2cc(-c3ccc4cc(-c5nc(-c6ccc7ccccc7c6)nc(-c6cccc7oc8ccccc8c67)n5)ccc4c3)ccc2c1 ; c1ccc2cc(-c3nc(-c4cccc5cc(-c6cccc7ccccc67)ccc45)nc(-c4cccc5oc6ccccc6c45)n3)ccc2c1 ; c1ccc2cc(-c3ccc4cc(-c5nc(-c6ccc7ccccc7c6)nc(-c6cccc7c6oc6ccccc67)n5)ccc4c3)ccc2c1]

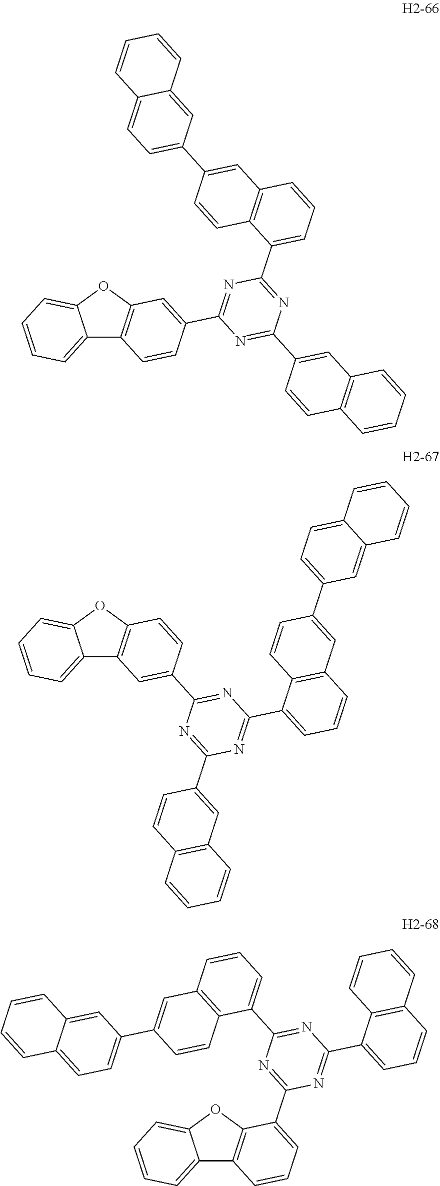 [SMILES: c1ccc2cc(-c3ccc4c(-c5nc(-c6ccc7ccccc7c6)nc(-c6ccc7c(c6)oc6ccccc67)n5)cccc4c3)ccc2c1 ; c1ccc2cc(-c3ccc4c(-c5nc(-c6ccc7ccccc7c6)nc(-c6ccc7oc8ccccc8c7c6)n5)cccc4c3)ccc2c1 ; c1ccc2cc(-c3ccc4c(-c5nc(-c6cccc7ccccc67)nc(-c6cccc7c6oc6ccccc67)n5)cccc4c3)ccc2c1]

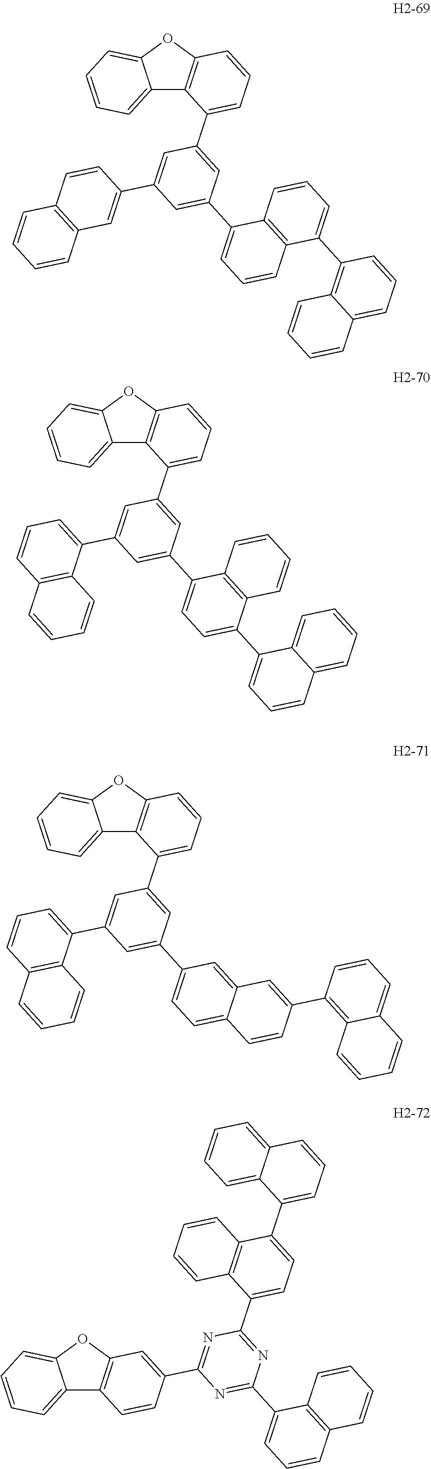 [SMILES: c1ccc2cc(-c3cc(-c4cccc5c(-c6cccc7ccccc67)cccc45)cc(-c4cccc5oc6ccccc6c45)c3)ccc2c1 ; c1ccc2c(-c3cc(-c4ccc(-c5cccc6ccccc56)c5ccccc45)cc(-c4cccc5oc6ccccc6c45)c3)cccc2c1 ; c1ccc2c(-c3cc(-c4ccc5ccc(-c6cccc7ccccc67)cc5c4)cc(-c4cccc5oc6ccccc6c45)c3)cccc2c1 ; c1ccc2c(-c3nc(-c4ccc5c(c4)oc4ccccc45)nc(-c4ccc(-c5cccc6ccccc56)c5ccccc45)n3)cccc2c1]

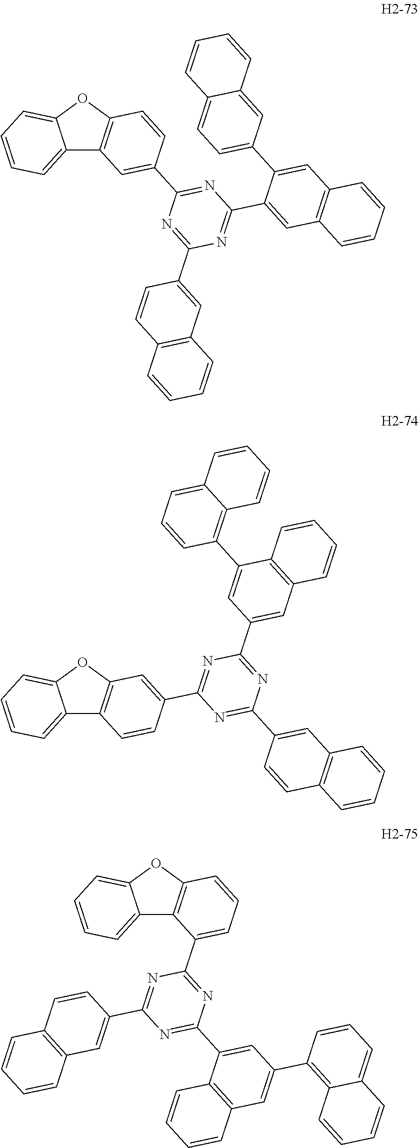 [SMILES: c1ccc2cc(-c3nc(-c4ccc5oc6ccccc6c5c4)nc(-c4cc5ccccc5cc4-c4ccc5ccccc5c4)n3)ccc2c1 ; c1ccc2cc(-c3nc(-c4cc(-c5cccc6ccccc56)c5ccccc5c4)nc(-c4ccc5c(c4)oc4ccccc45)n3)ccc2c1 ; c1ccc2cc(-c3nc(-c4cc(-c5cccc6ccccc56)cc5ccccc45)nc(-c4cccc5oc6ccccc6c45)n3)ccc2c1]

The organic electroluminescent compound according to another embodiment of the present disclosure is selected from the following compounds.

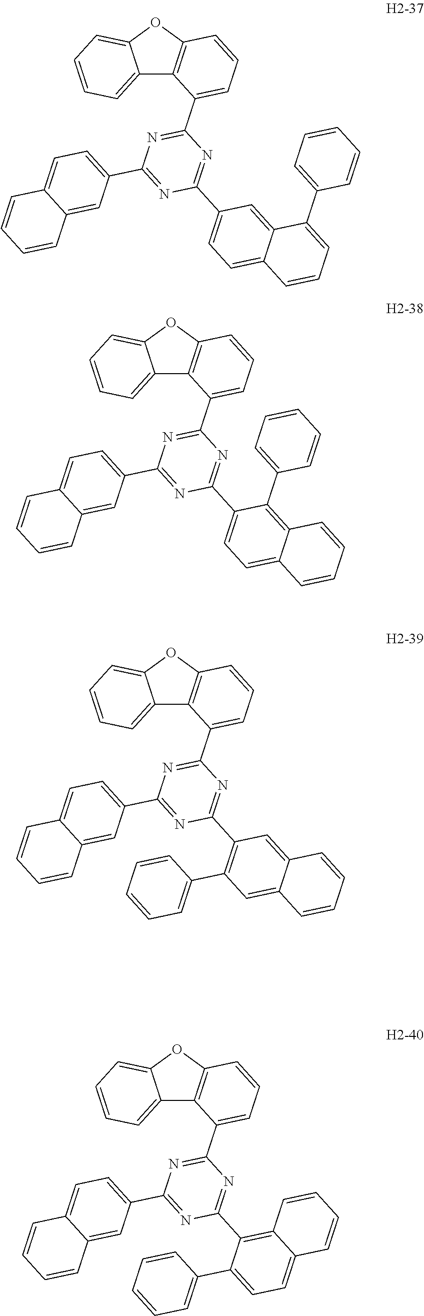

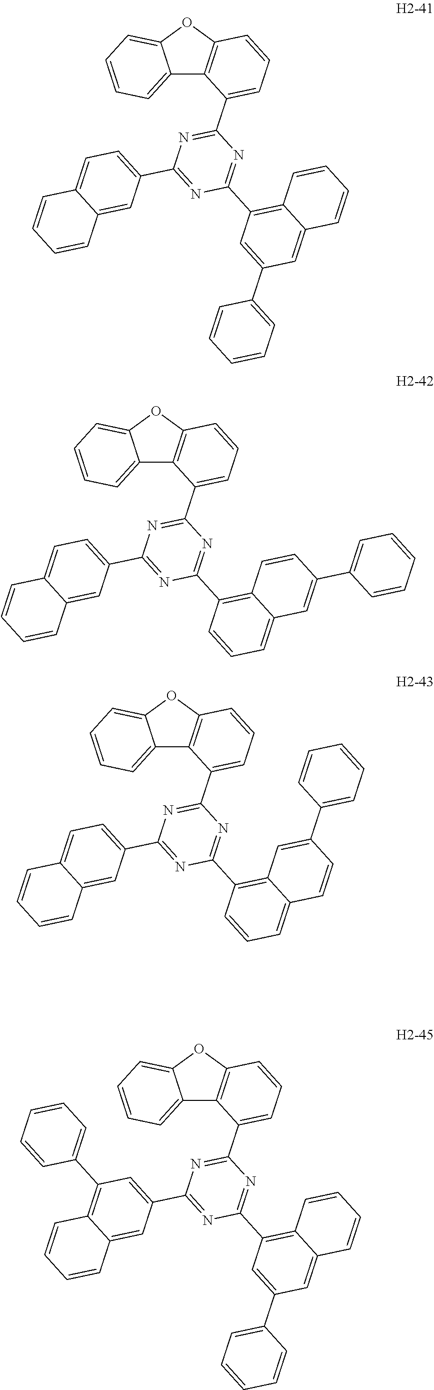 [SMILES: c1ccc(-c2cc(-c3nc(-c4ccc5ccccc5c4)nc(-c4cccc5oc6ccccc6c45)n3)c3ccccc3c2)cc1 ; c1ccc(-c2ccc3c(-c4nc(-c5ccc6ccccc6c5)nc(-c5cccc6oc7ccccc7c56)n4)cccc3c2)cc1 ; c1ccc(-c2ccc3cccc(-c4nc(-c5ccc6ccccc6c5)nc(-c5cccc6oc7ccccc7c56)n4)c3c2)cc1 ; c1ccc(-c2cc(-c3nc(-c4cc(-c5ccccc5)c5ccccc5c4)nc(-c4cccc5oc6ccccc6c45)n3)c3ccccc3c2)cc1]

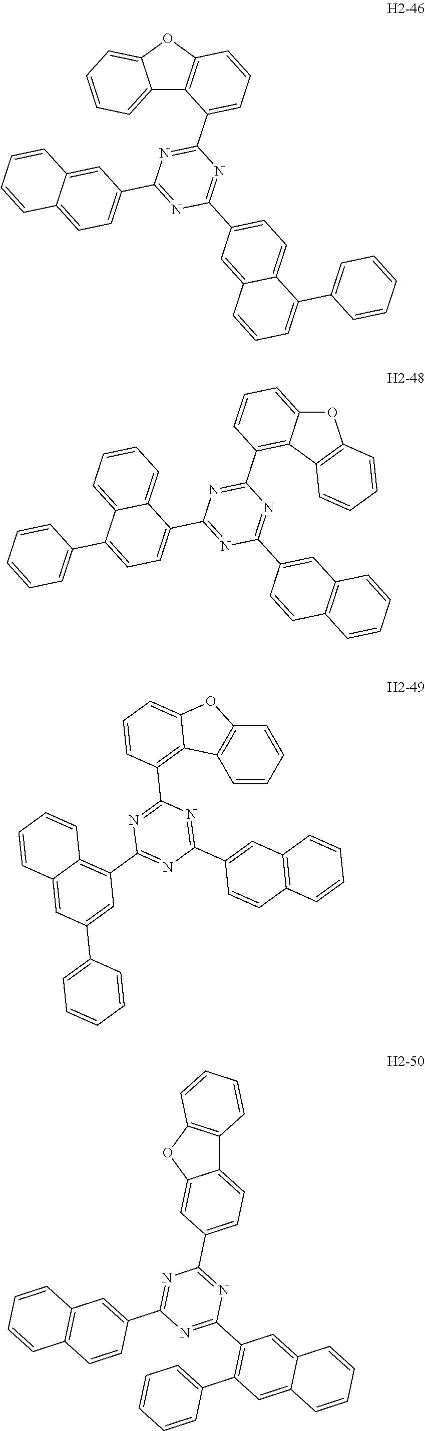 [SMILES: c1ccc(-c2cccc3cc(-c4nc(-c5ccc6ccccc6c5)nc(-c5cccc6oc7ccccc7c56)n4)ccc23)cc1 ; c1ccc(-c2ccc(-c3nc(-c4ccc5ccccc5c4)nc(-c4cccc5oc6ccccc6c45)n3)c3ccccc23)cc1 ; c1ccc(-c2cc(-c3nc(-c4ccc5ccccc5c4)nc(-c4cccc5oc6ccccc6c45)n3)c3ccccc3c2)cc1 ; c1ccc(-c2cc3ccccc3cc2-c2nc(-c3ccc4ccccc4c3)nc(-c3ccc4c(c3)oc3ccccc34)n2)cc1]

The compounds represented by formulas 1 and 2 according to the present disclosure may be produced by synthetic methods known to a person skilled in the art. For example, the compound represented by formula 1 according to the present disclosure may be produced by referring to Korean Patent Application Laid-Open Nos. 2017-0022865 (published on Mar. 2, 2017) and 2018-0099487 (published on Sep. 5, 2018), and the compound represented by formula 2 or 21 according to the present disclosure may be produced by referring to the following Reaction Scheme 1, but is not limited thereto.

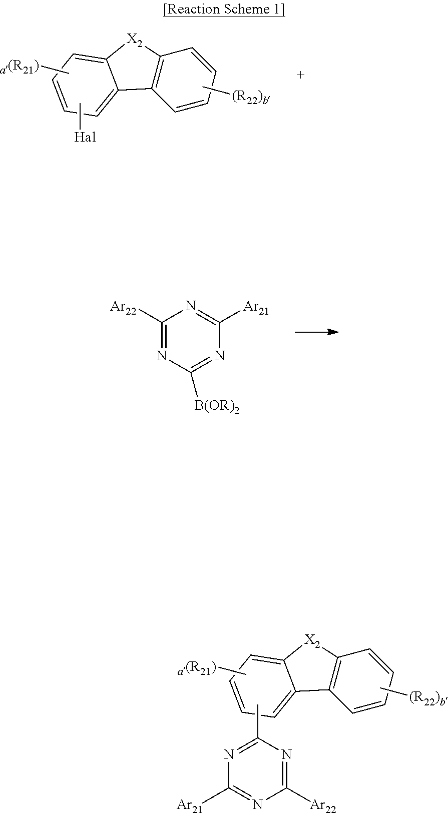

In Reaction Scheme 1, X₂, Ar₂₁, Ar₂₂, R₂₁, R₂₂, a′, and b′ are as defined in formula 2, R represents hydrogen or a (C1-C30)alkyl, and Hal means a halogen.

Although illustrative synthesis examples of the compound represented by formula 2 or 21 are described above, one skilled in the art will be able to readily understand that all of them are based on a Buchwald-Hartwig cross coupling reaction, an N-arylation reaction, a H-mont-mediated etherification reaction, a Miyaura borylation reaction, a Suzuki cross-coupling reaction, an Intramolecular acid-induced cyclization reaction, a Pd(II)-catalyzed oxidative cyclization reaction, a Grignard reaction, a Heck reaction, a Cyclic Dehydration reaction, an SN₁ substitution reaction, an SN₂ substitution reaction, and a Phosphine-mediated reductive cyclization reaction, etc., and the above reactions proceed even when substituents defined in formula 2 or 21 other than the substituents specified in the specific synthesis examples, are bonded.

An organic electroluminescent device according to the present disclosure comprises an anode, a cathode, and at least one organic layer between the anode and the cathode, wherein the organic layer may comprise a plurality of organic electroluminescent materials comprising the compound represented by formula 1 as a first organic electroluminescent material, and the compound represented by formula 2 as a second organic electroluminescent material or may comprise an organic electroluminescent material comprising the compound represented by formula 21. According to one embodiment of the present disclosure, the organic electroluminescent device according to the present disclosure comprises an anode, a cathode, and at least one light-emitting layer between the anode and the cathode, wherein the light-emitting layer may comprise the compound represented by formula 1 and the compound represented by formula 2 or the compound represented by formula 21.

The light-emitting layer comprises a host and a dopant, wherein the host comprises a plurality of host materials or an organic electroluminescent compound, the compound represented by formula 1 may be comprised as a first host compound of the plurality of host materials, and the compound represented by formula 2 may be comprised as a second host compound of the plurality of host materials. Herein, the weight ratio of the first host compound to the second host compound is about 1:99 to about 99:1, preferably about 10:90 to about 90:10, more preferably about 30:70 to about 70:30, still more preferably about 40:60 to about 60:40, even more preferably about 50:50.

In the present disclosure, the light-emitting layer is a layer from which light is emitted, and can be a single layer or a multi-layer of which two or more layers are stacked. In the plurality of host materials of the present disclosure, both the first and second host materials may be comprised in one layer, or the first and second host materials may be respectively comprised in different light-emitting layers. According to one embodiment of the present disclosure, the doping concentration of the dopant compound with respect to the host compound of the light-emitting layer may be less than 20 wt %.

The organic electroluminescent device of the present disclosure may further comprise at least one layer selected from a hole injection layer, a hole transport layer, a hole auxiliary layer, a light-emitting auxiliary layer, an electron transport layer, an electron injection layer, an interlayer, an electron buffer layer, a hole blocking layer, and an electron blocking layer. According to one embodiment of the present disclosure, the organic electroluminescent device of the present disclosure may further comprise an amine-based compound as at least one of a hole injection material, a hole transport material, a hole auxiliary material, a light-emitting material, a light-emitting auxiliary material, and an electron blocking material besides the plurality of host materials or the organic electroluminescent compound of the present disclosure. Also, according to one embodiment of the present disclosure, the organic electroluminescent device of the present disclosure may further comprise an azine-based compound as at least one of an electron transport material, an electron injection material, an electron buffer material and a hole blocking material besides the plurality of host materials or the organic electroluminescent compound of the present disclosure.

The plurality of host materials or the organic electroluminescent compound according to the present disclosure may be used as light-emitting materials for a white organic light-emitting device. The white organic light-emitting device has been suggested to have various structures such as a side-by-side structure or a stacking structure depending on the arrangement of R (Red), G (Green) or YG (yellowish green), and B (blue) light-emitting parts, or color conversion material (CCM) method, etc. In addition, the plurality of host materials or the organic electroluminescent compound according to one embodiment of the present disclosure may also be used in an organic electroluminescent device comprising a quantum dot (QD).

A hole injection layer, a hole transport layer, an electron blocking layer, or a combination thereof may be used between the anode and the light-emitting layer. The hole injection layer may be multi-layers in order to lower the hole injection barrier (or hole injection voltage) from the anode to the hole transport layer or the electron blocking layer, wherein each of the multi-layers may use two compounds simultaneously. In addition, the hole injection layer may be doped with a p-dopant. The electron blocking layer may be placed between the hole transport layer (or hole injection layer) and the light-emitting layer, and can confine the excitons within the light-emitting layer by blocking the overflow of electrons from the light-emitting layer to prevent a light-emitting leakage. The hole transport layer or the electron blocking layer may be multi-layers, wherein a plurality of compounds may be used in each of the multi-layers.

An electron buffer layer, a hole blocking layer, an electron transport layer, an electron injection layer, or a combination thereof may be used between the light-emitting layer and the cathode. The electron buffer layer may be multi-layers in order to control electron injection and improve interfacial properties between the light-emitting layer and the electron injection layer, wherein two compounds may be simultaneously used in each of the multilayers. The hole blocking layer or the electron transport layer may also be multi-layers, wherein a plurality of compounds may be used in each of the multi-layers. In addition, the electron injection layer may be doped with an n-dopant.

The dopants comprised in the organic electroluminescent device of the present disclosure may be at least one phosphorescent or fluorescent dopant, and is preferably a phosphorescent dopant. The phosphorescent dopant materials applied to the organic electroluminescent device according to the present disclosure are not particularly limited, but may be a complex compound of a metal atom selected from iridium (Ir), osmium (Os), copper (Cu), and platinum (Pt), preferably ortho-metallated complex compounds of a metal atom selected from iridium (Ir), osmium (Os), copper (Cu), and platinum (Pt), and more preferably ortho-metallated iridium complex compounds.

The dopant comprised in the organic electroluminescent device of the present disclosure may be a compound represented by the following formula 101, but is not limited thereto.

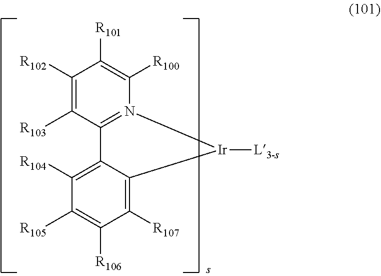

In formula 101,

L′ is selected from the following structures 1 to 3;

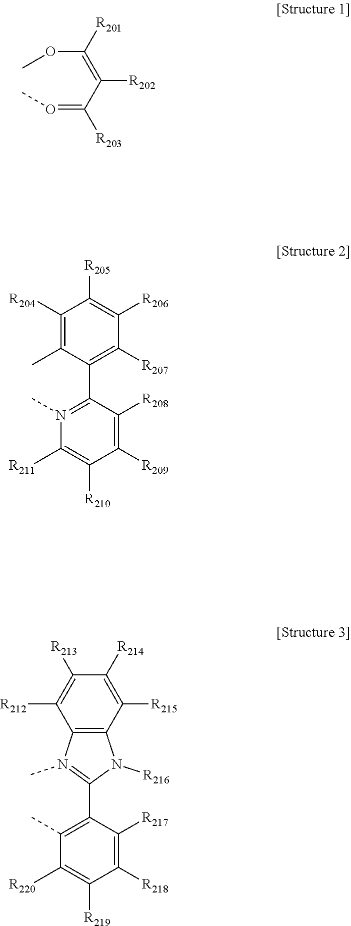

R₁₀₀ to R₁₀₃ each independently represent hydrogen, deuterium, a halogen, a (C1-C30)alkyl unsubstituted or substituted with deuterium and/or a halogen(s), a substituted or unsubstituted (C3-C30)cycloalkyl, a substituted or unsubstituted (C6-C30)aryl, a cyano, a substituted or unsubstituted (3- to 30-membered)heteroaryl, or a substituted or unsubstituted (C1-C30)alkoxy; or may be linked to an adjacent substituent(s) to form a ring(s), for example, a substituted or unsubstituted quinoline, a substituted or unsubstituted isoquinoline, a substituted or unsubstituted benzofuropyridine, a substituted or unsubstituted benzothienopyridine, a substituted or unsubstituted indenopyridine, a substituted or unsubstituted benzofuroquinoline, a substituted or unsubstituted benzothienoquinoline, or a substituted or unsubstituted indenoquinoline, together with pyridine;

R₁₀₄ to R₁₀₇ each independently represent hydrogen, deuterium, a halogen, a (C1-C30)alkyl unsubstituted or substituted with deuterium and/or a halogen(s), a substituted or unsubstituted (C3-C30)cycloalkyl, a substituted or unsubstituted (C6-C30)aryl, a substituted or unsubstituted (3- to 30-membered)heteroaryl, a cyano, or a substituted or unsubstituted (C1-C30)alkoxy; or may be linked to an adjacent substituent(s) to form a ring(s), for example, a substituted or unsubstituted naphthalene, a substituted or unsubstituted fluorene, a substituted or unsubstituted dibenzothiophene, a substituted or unsubstituted dibenzofuran, a substituted or unsubstituted indenopyridine, a substituted or unsubstituted benzofuropyridine, or a substituted or unsubstituted benzothienopyridine, together with benzene;

R₂₀₁ to R₂₂₀ each independently represent hydrogen, deuterium, a halogen, a (C1-C30)alkyl unsubstituted or substituted with deuterium and/or a halogen(s), a substituted or unsubstituted (C3-C30)cycloalkyl, or a substituted or unsubstituted (C6-C30)aryl; or may be linked to an adjacent substituent(s) to form a ring(s); and

s represents an integer of 1 to 3.

The specific examples of the dopant compound are as follows, but are not limited thereto.

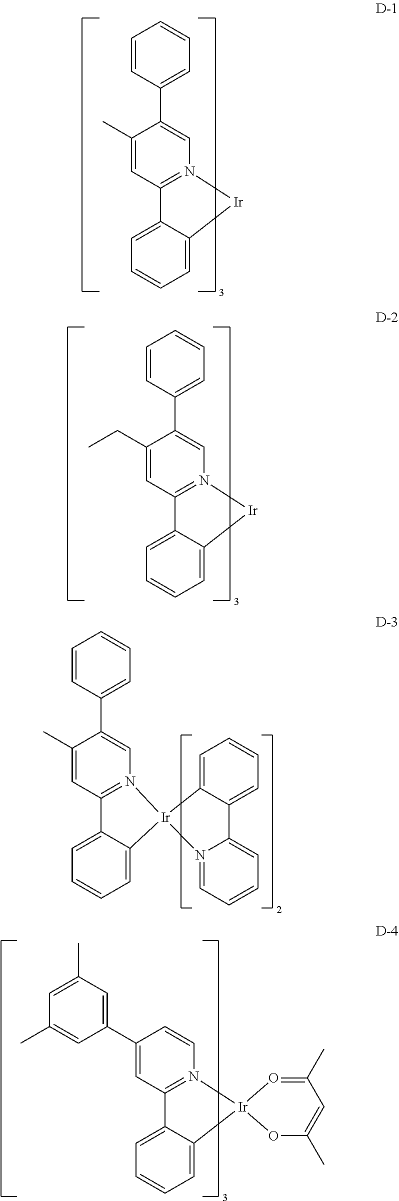

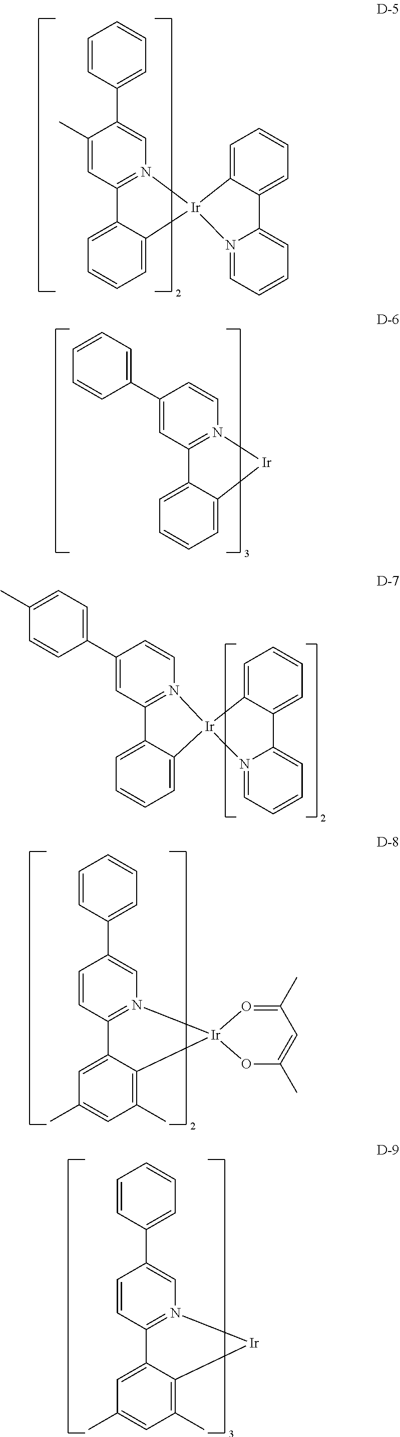

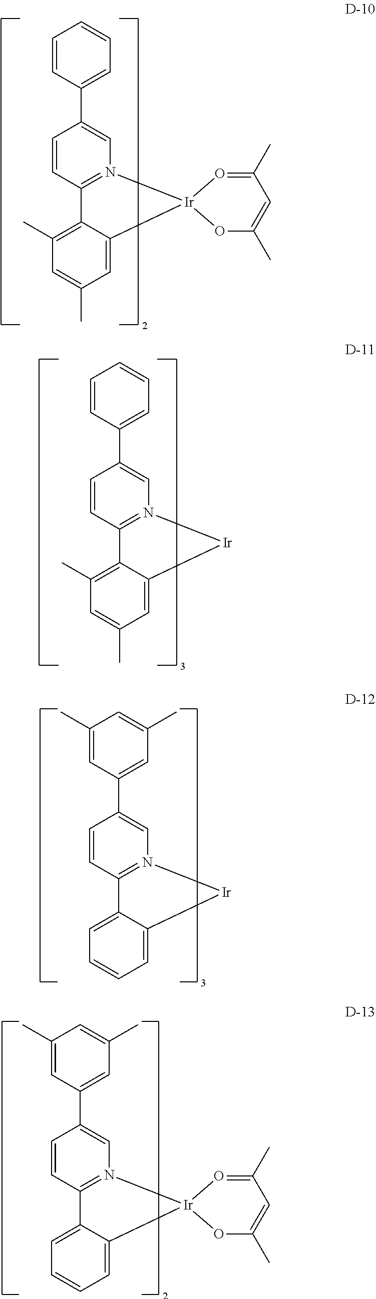

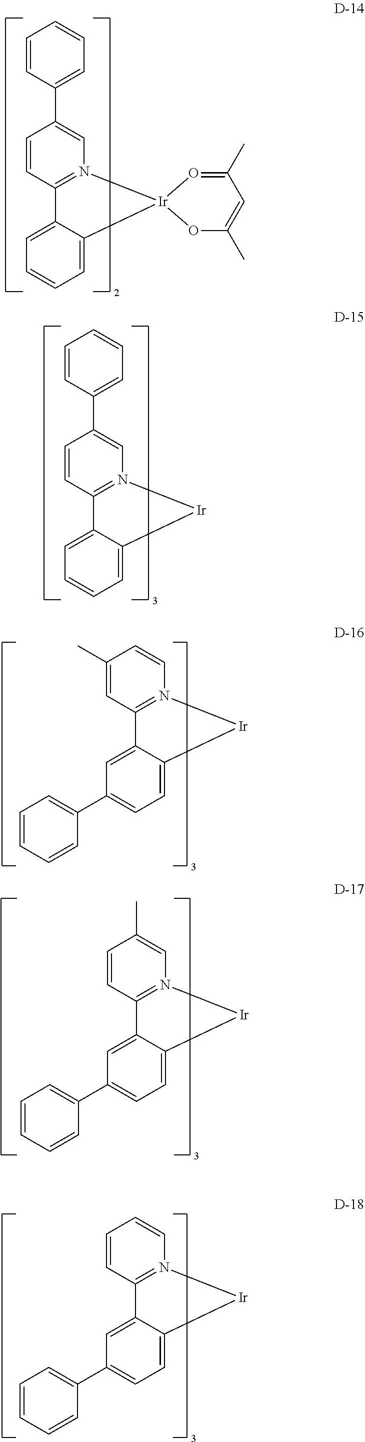

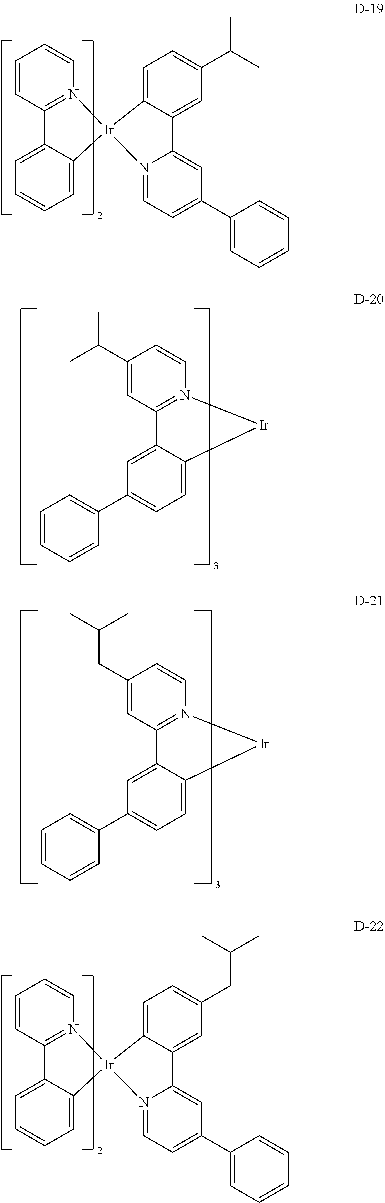

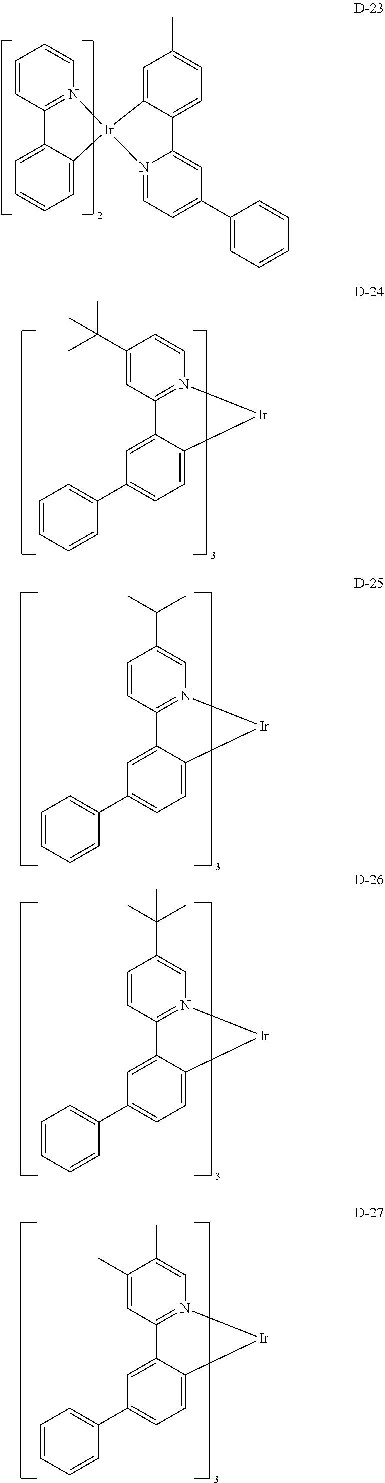

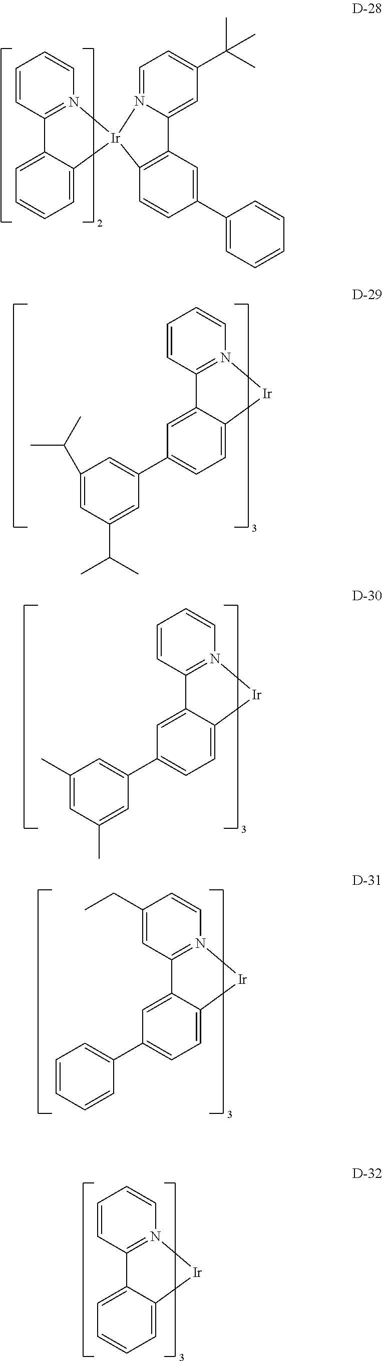

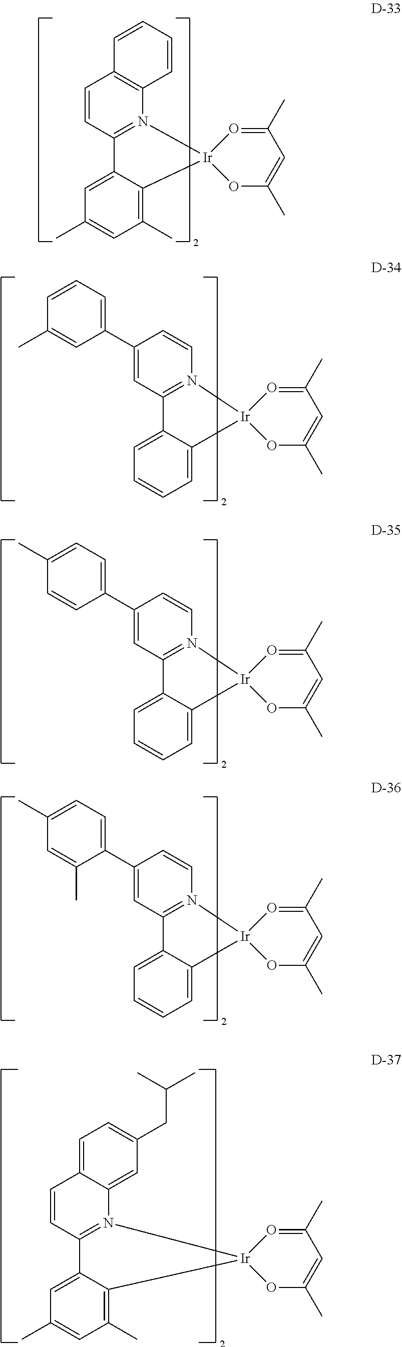

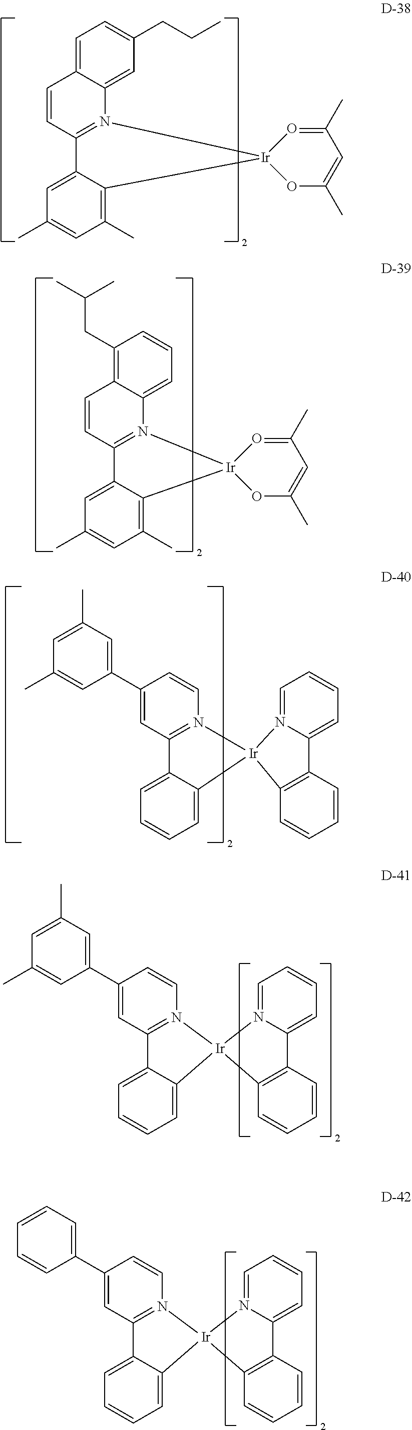

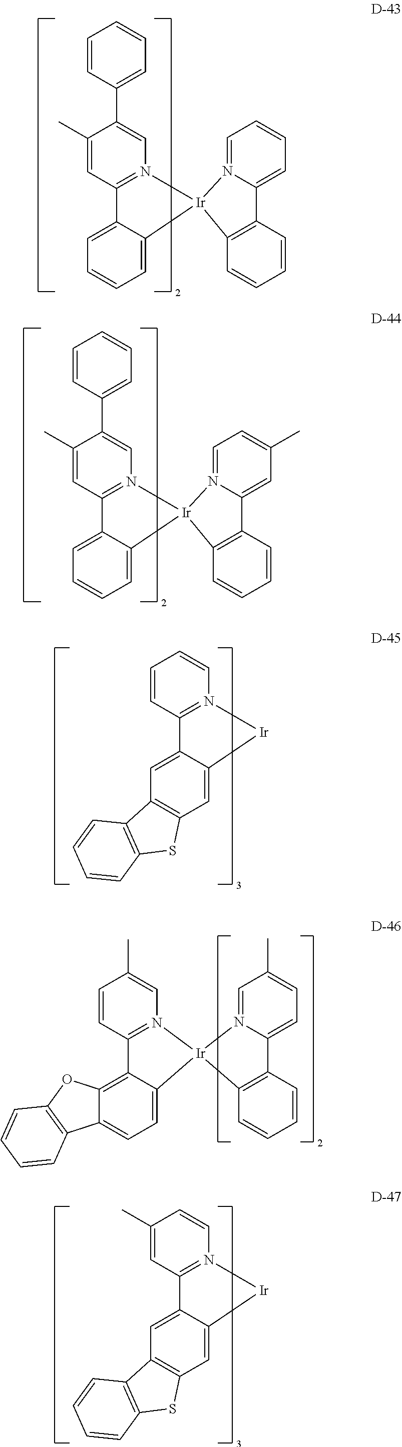

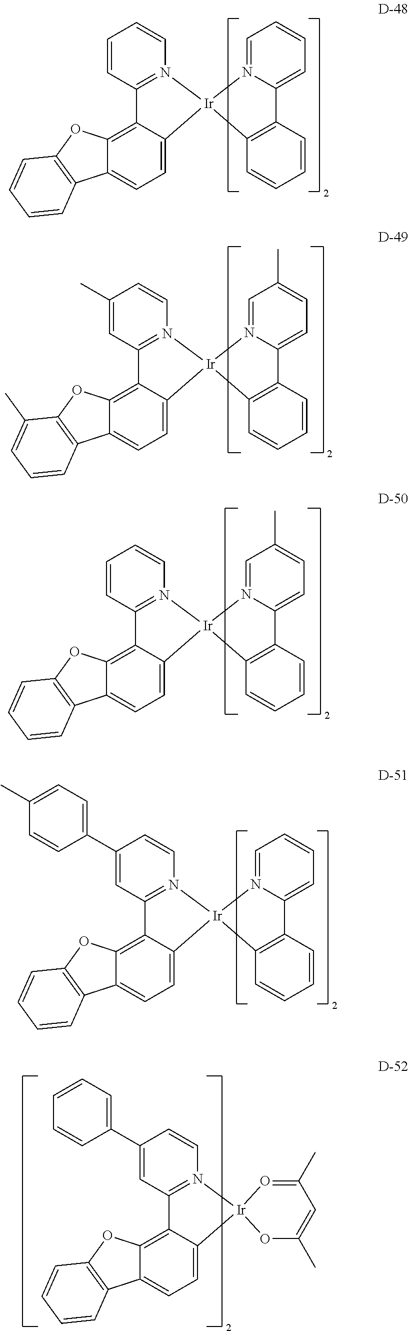

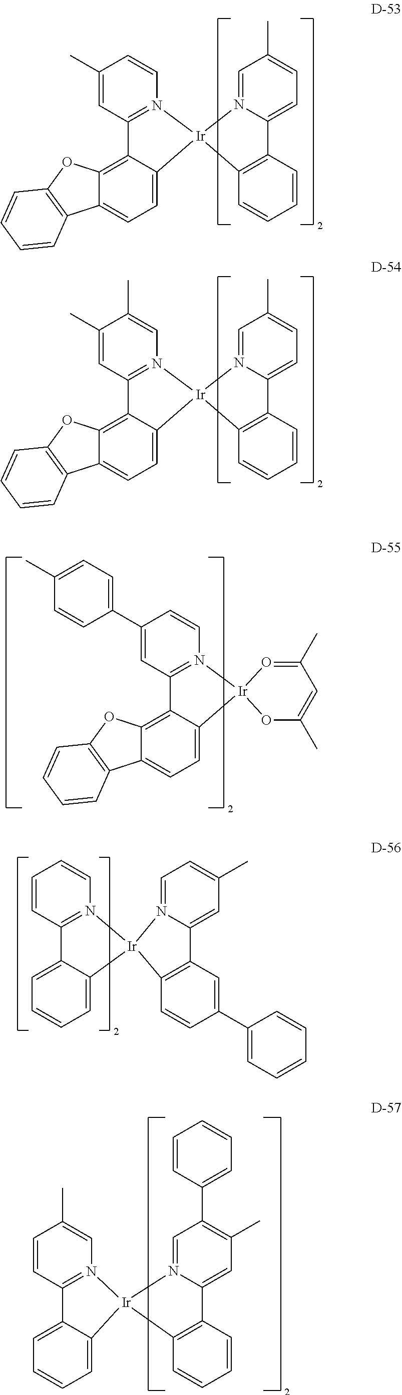

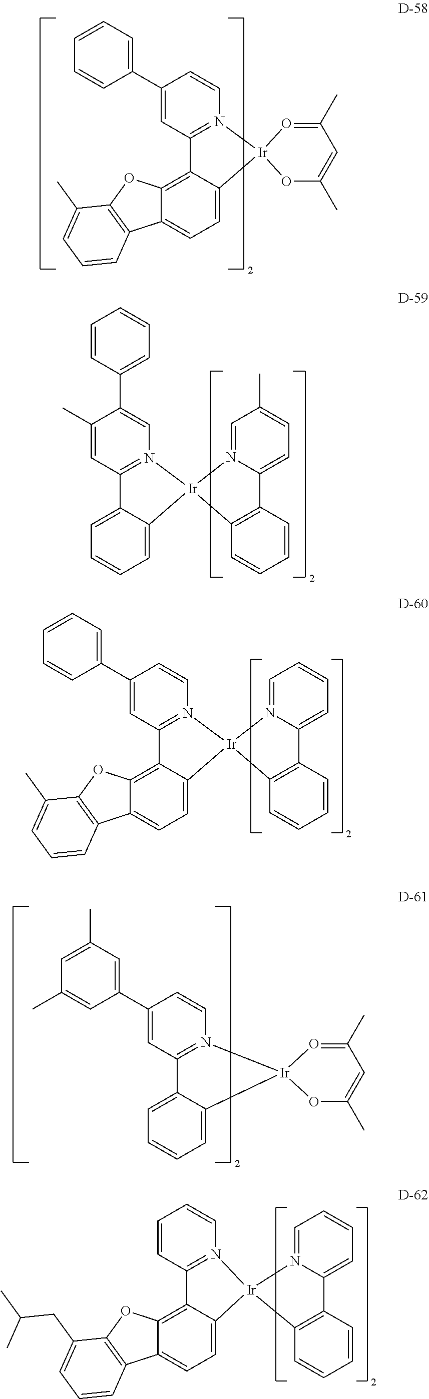

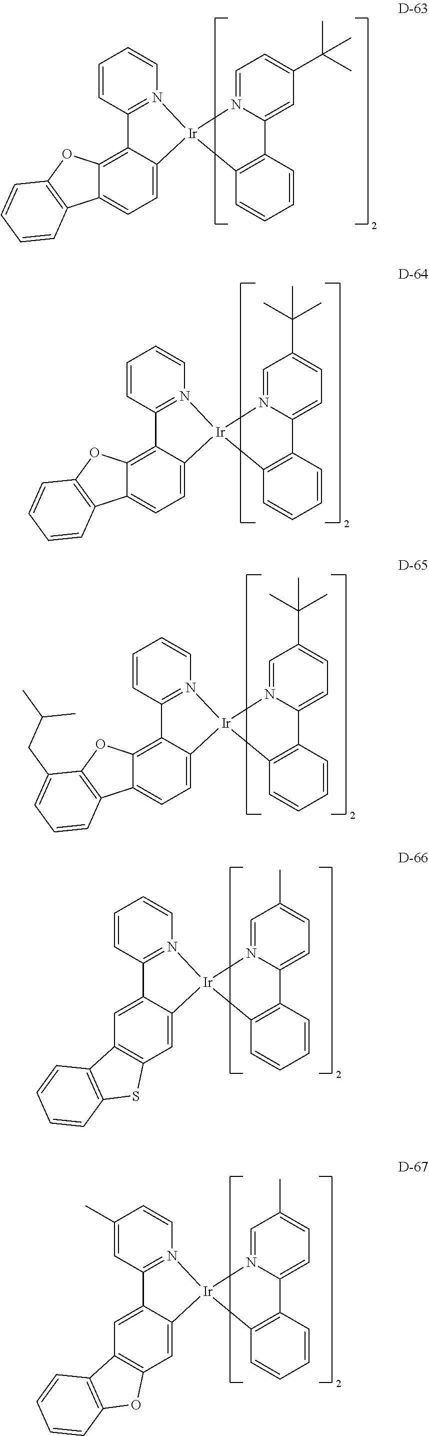

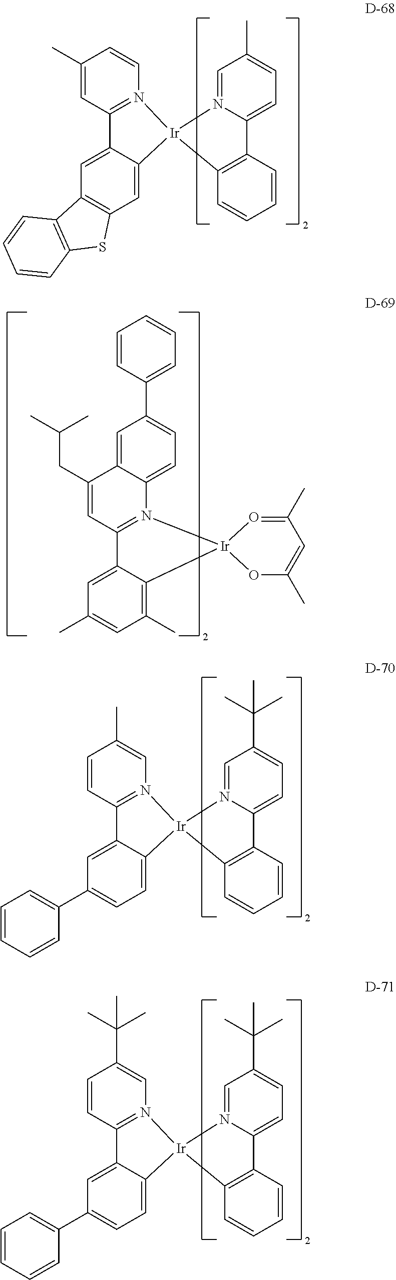

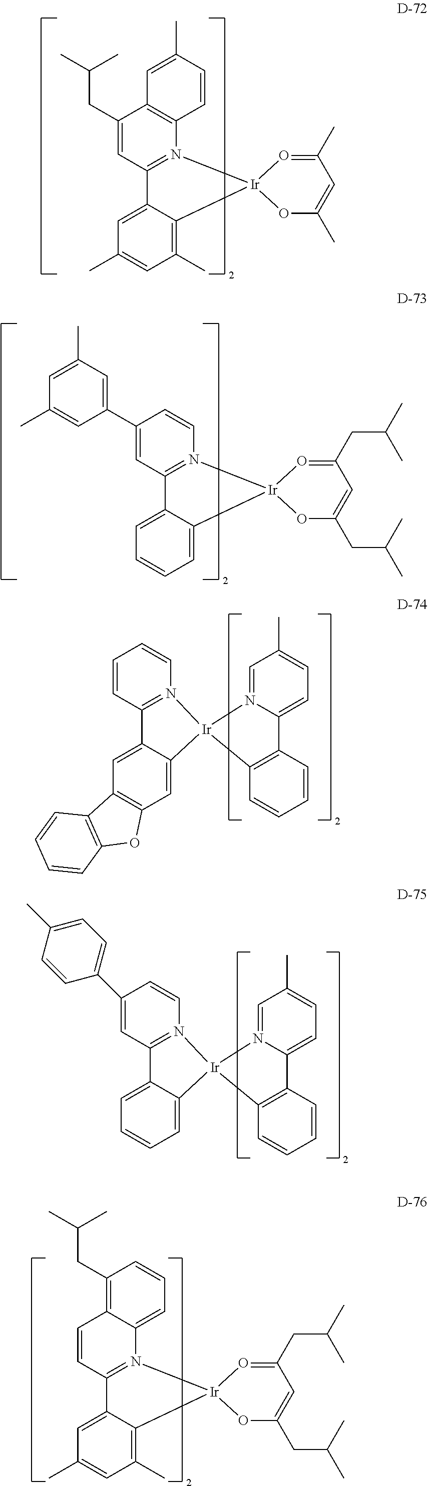

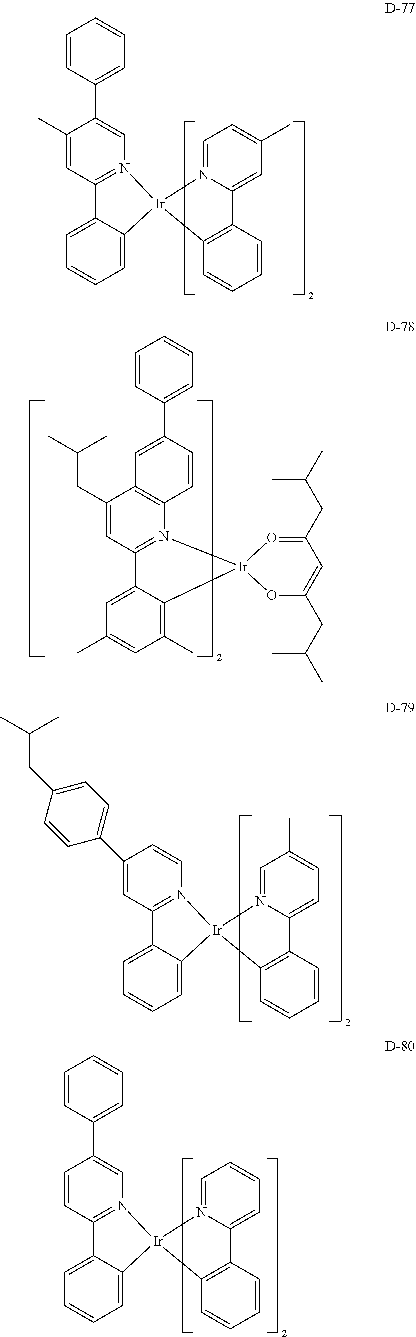

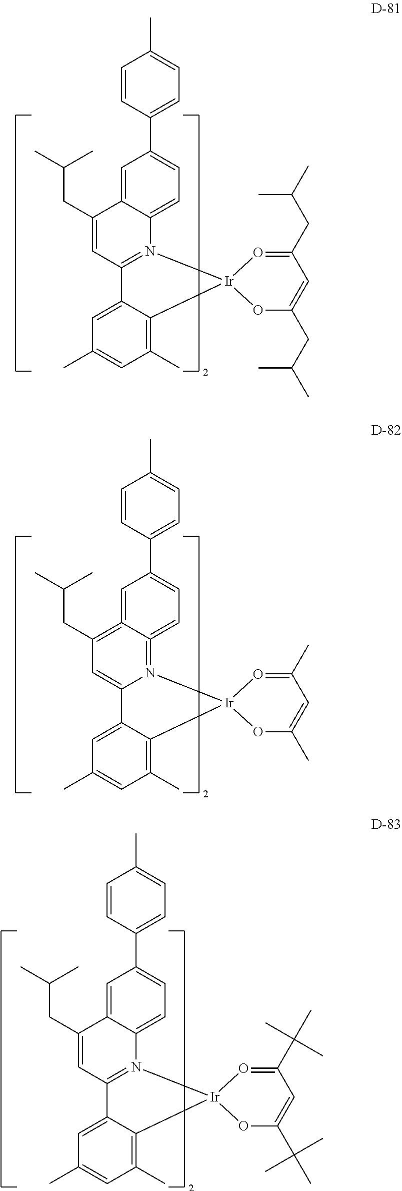

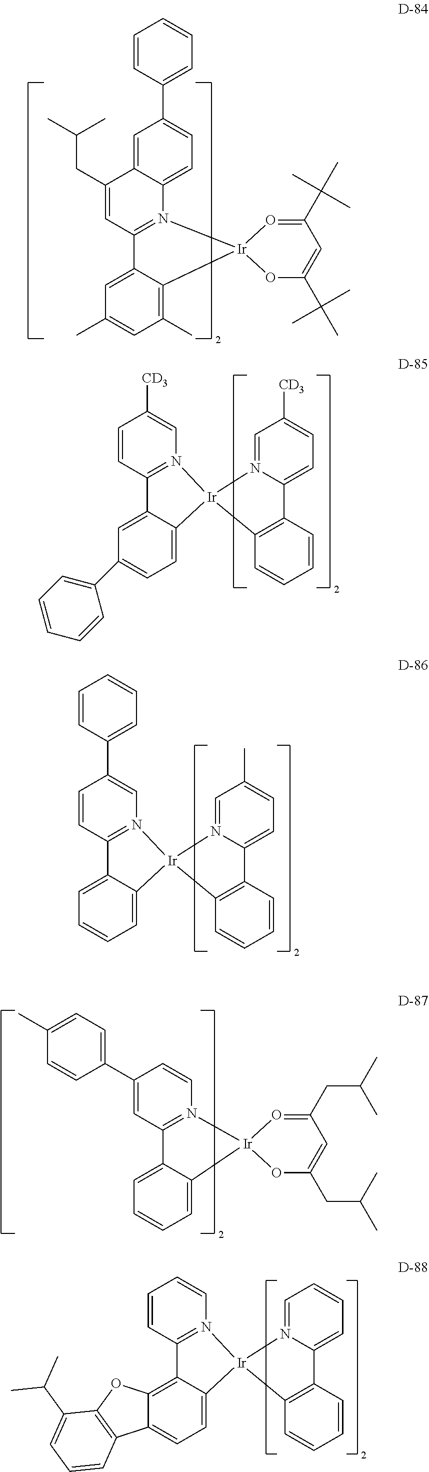

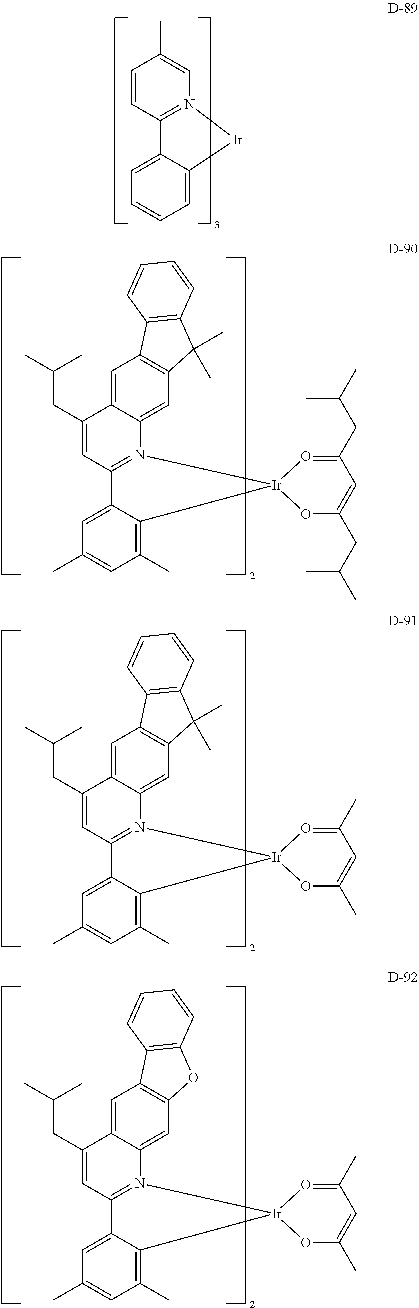

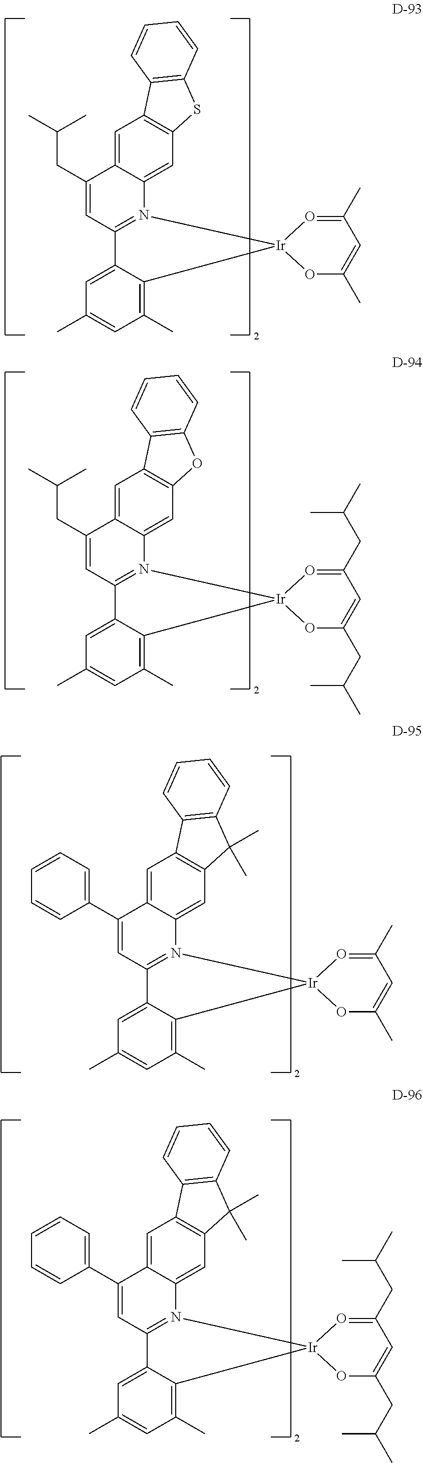

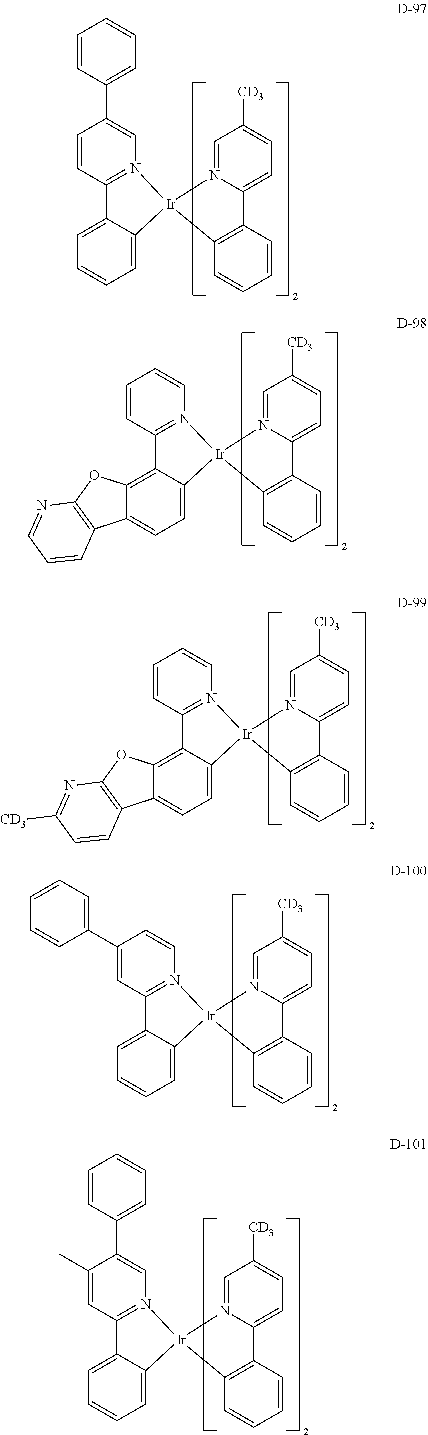

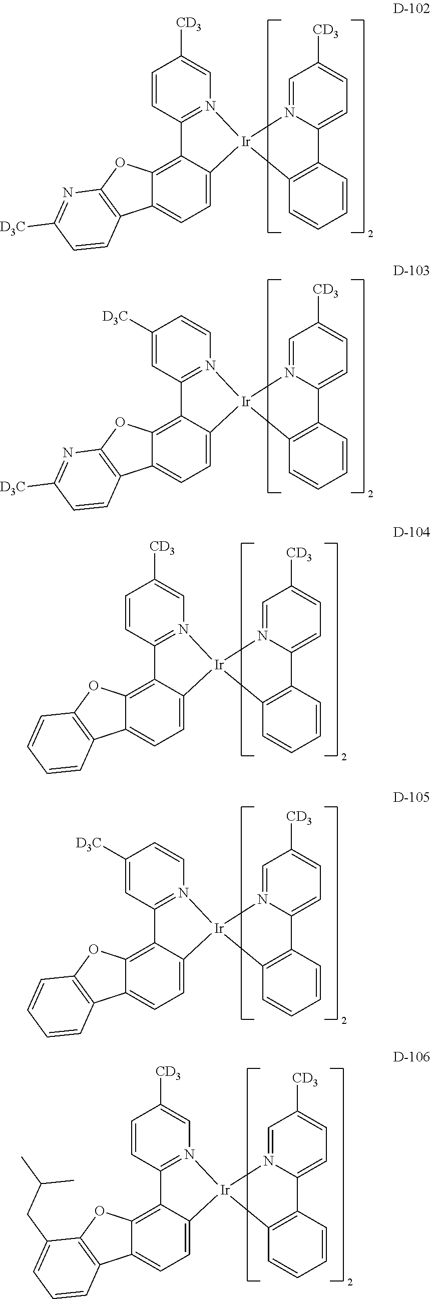

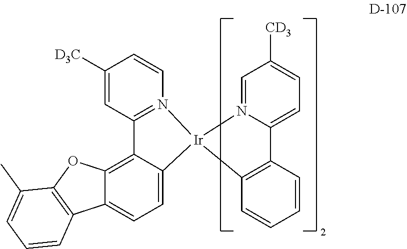

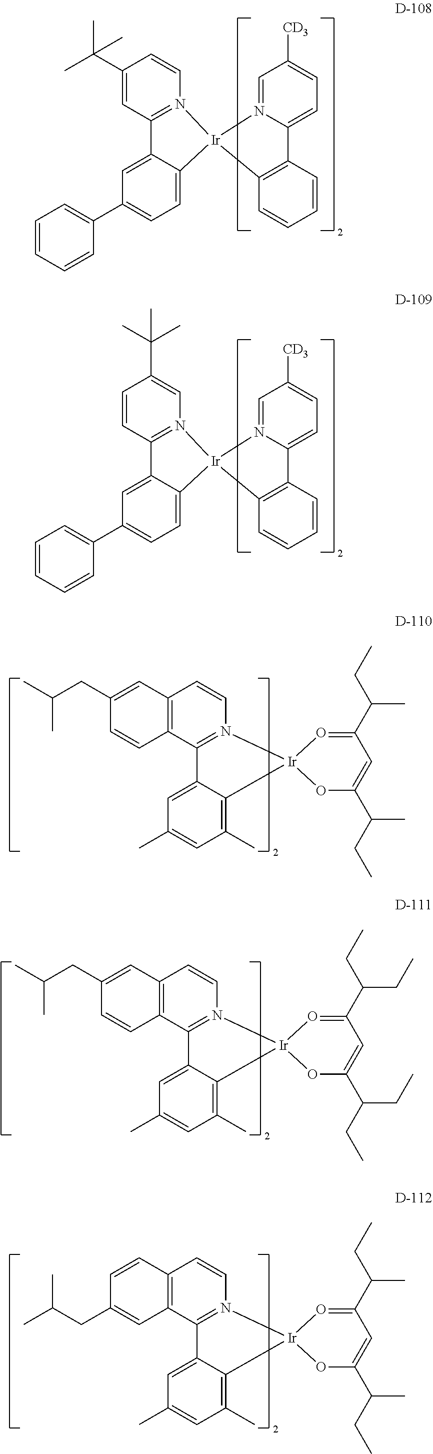

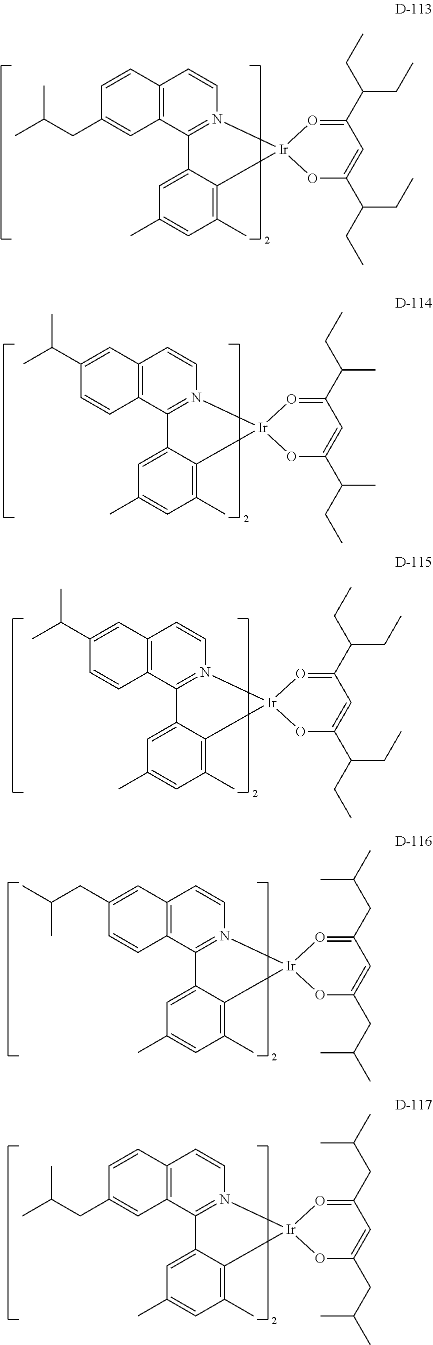

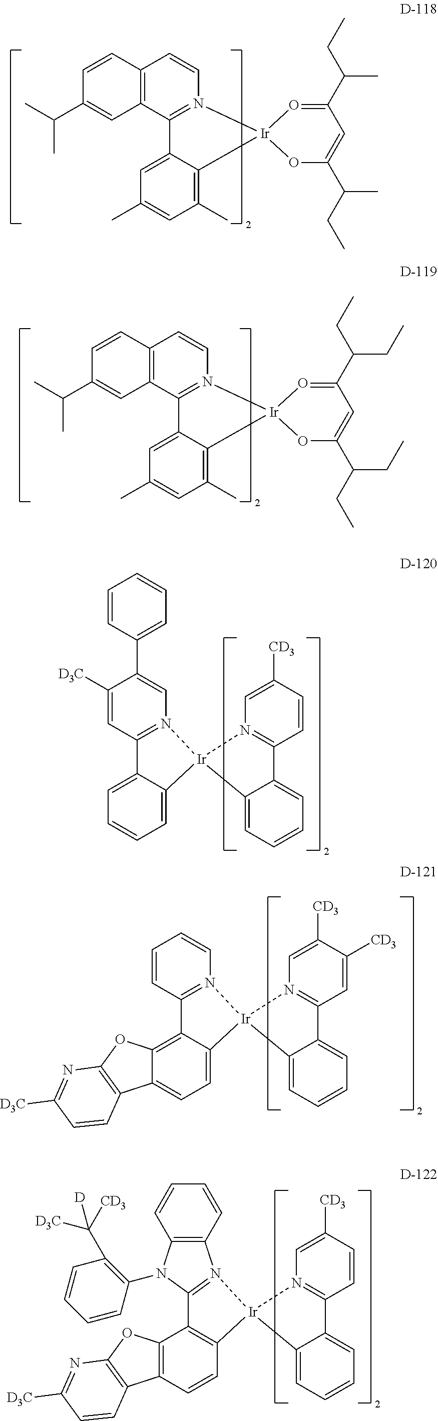

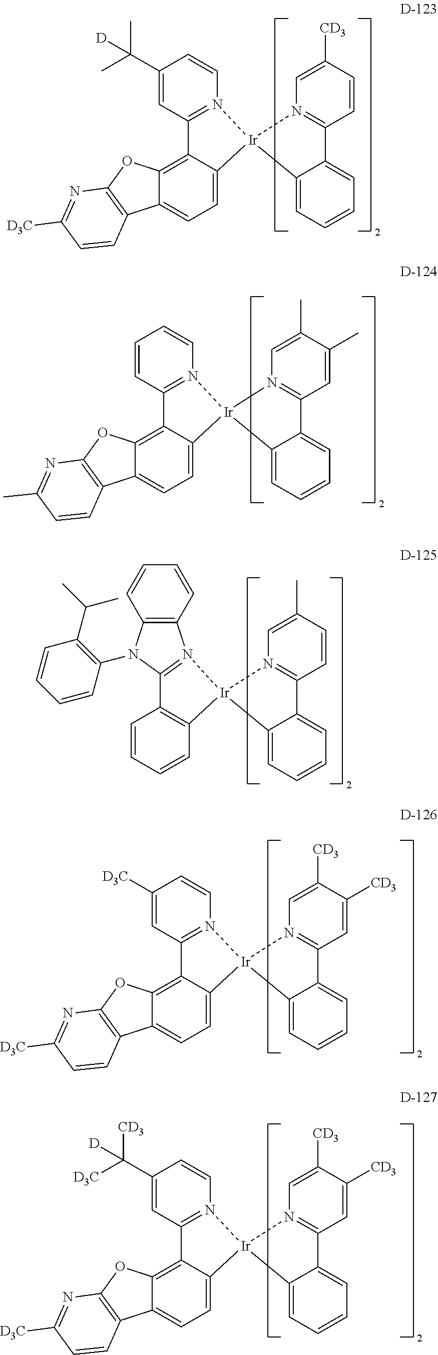

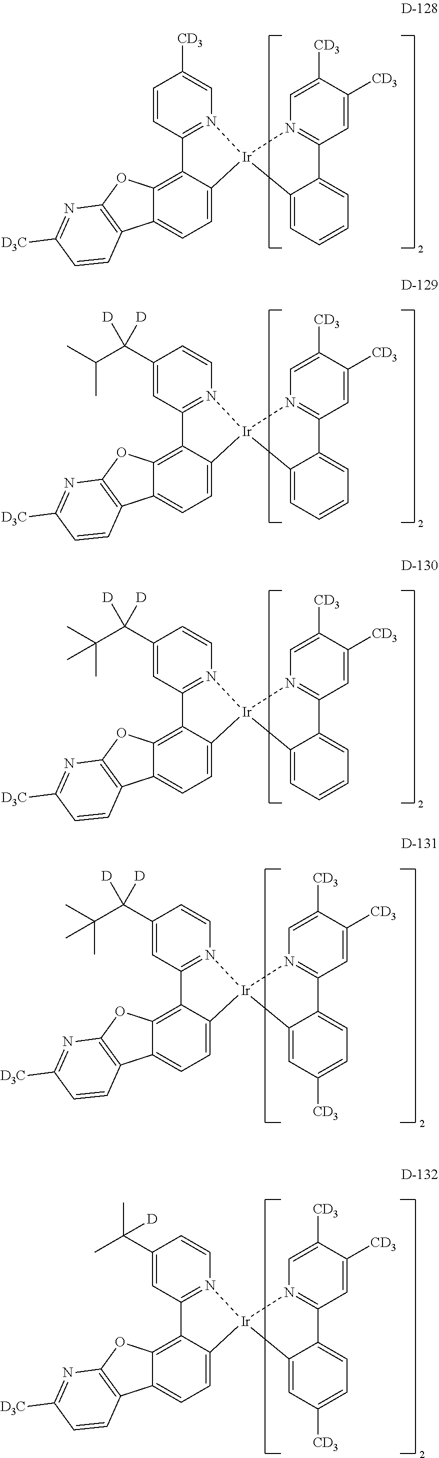

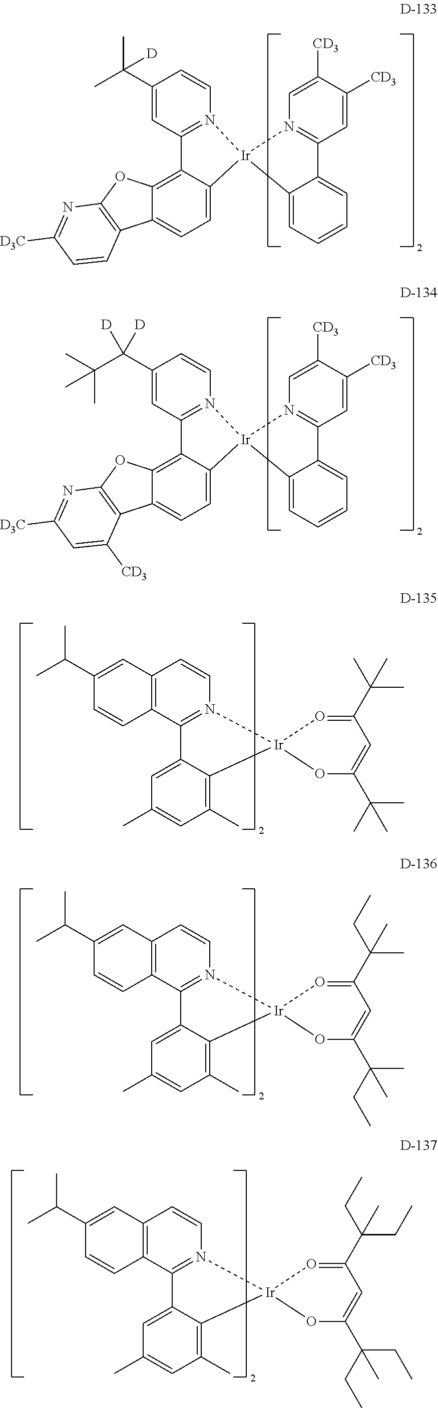

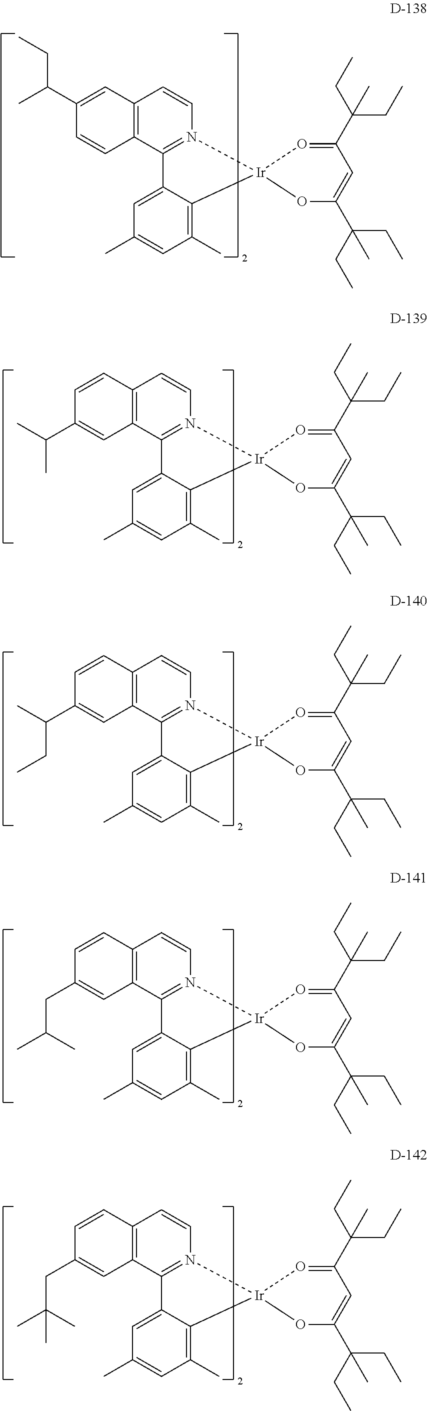

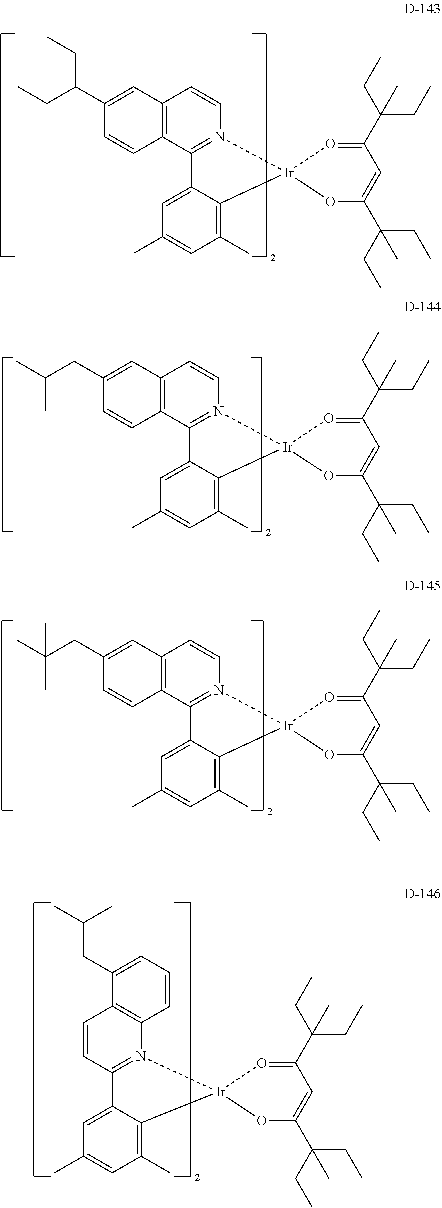

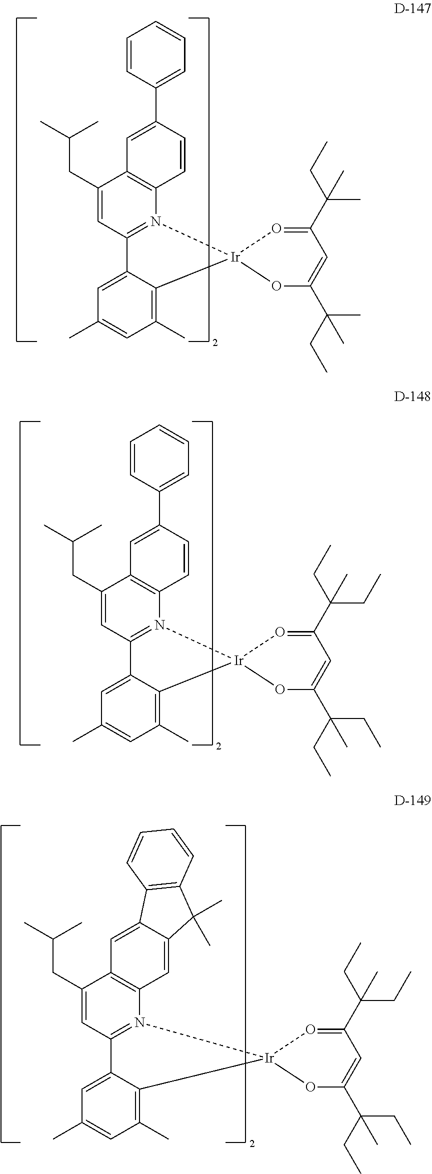

In order to form each layer of the organic electroluminescent device of the present disclosure, dry film-forming methods such as vacuum evaporation, sputtering, plasma, ion plating methods, etc., or wet film-forming methods such as ink jet printing, nozzle printing, slot coating, spin coating, dip coating, flow coating methods, etc., can be used.

When using a wet film-forming method, a thin film may be formed by dissolving or diffusing materials forming each layer into any suitable solvent such as ethanol, chloroform, tetrahydrofuran, dioxane, etc. The solvent may be any solvent where the materials forming each layer can be dissolved or diffused, and where there are no problems in film-formation capability.

In addition, the first and second host compounds of the present disclosure may be film-formed by the methods listed above, commonly by a co-evaporation process or a mixture-evaporation process. The co-evaporation is a mixed deposition method in which two or more materials are put into respective individual crucible sources and a current is applied to both cells simultaneously to evaporate the materials. The mixture-evaporation is a mixed deposition method in which two or more materials are mixed in one crucible source before evaporating them, and a current is applied to one cell to evaporate the materials. In addition, when the first host compound and the second host compound are present in the same layer or different layers in an organic electroluminescent device, each of the two host compounds may individually form films. For example, the second host compound may be deposited after depositing the first host compound.

The present disclosure can provide a display device by using the plurality of host materials comprising the compound represented by formula 1 and the compound represented by formula 2 or the organic electroluminescent compound represented by formula 21. That is, it is possible to manufacture a display system or a lighting system using the plurality of host materials or the organic electroluminescent compound of the present disclosure. Specifically, a display system, for example, a display system for white organic light-emitting devices, smartphones, tablets, notebooks, PCs, TVs, or cars; or a lighting system, for example, an outdoor or indoor lighting system, can be produced by using the plurality of host materials or the organic electroluminescent compound of the present disclosure.

Hereinafter, the preparation method of the compound according to the present disclosure and the physical properties thereof, and the properties of the organic electroluminescent device (OLED) comprising the plurality of host materials or the organic electroluminescent compound of the present disclosure will be explained with reference to the representative compounds of the present disclosure. However, the following examples are only to describe the characteristics of the OLED comprising the compound according to the present disclosure and the plurality of host materials or the organic electroluminescent compound according to the present disclosure, but the present disclosure is not limited to the following examples.

### EXAMPLE 1: PREPARATION OF COMPOUND H1-17

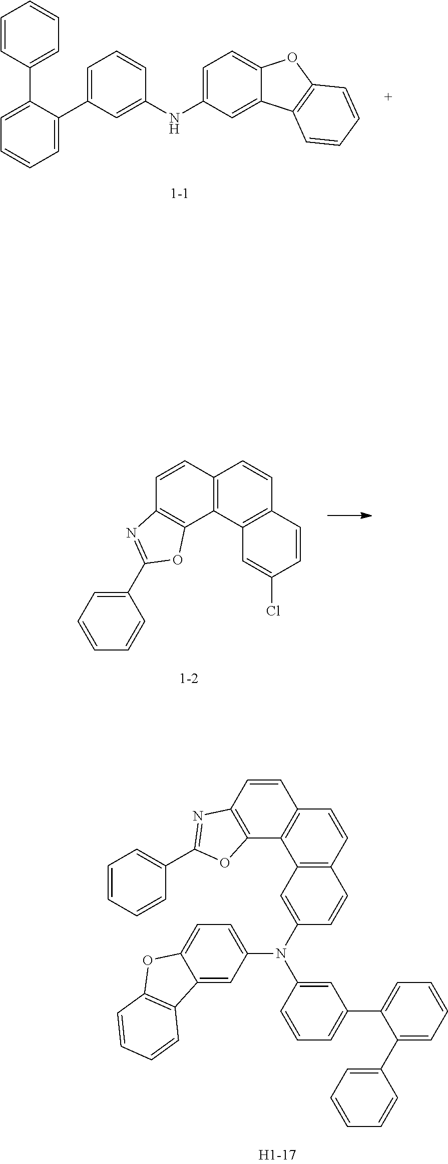 [SMILES: c1ccc(-c2ccccc2-c2cccc(Nc3ccc4oc5ccccc5c4c3)c2)cc1 ; Clc1ccc2ccc3ccc4nc(-c5ccccc5)oc4c3c2c1 ; c1ccc(-c2nc3ccc4ccc5ccc(N(c6cccc(-c7ccccc7-c7ccccc7)c6)c6ccc7oc8ccccc8c7c6)cc5c4c3o2)cc1]

Compound 1-1 (91.5 g, 222 mmol), compound 1-2 (70 g, 162.9 mmol), Pd(OAc)₂ (560 mg, 0.0025 mmol), X-Phos (2-dicyclophosphino-2′,4′,6′-triisopropylbiphenyl) (1.01 g, 0.002 mmol), NaOtBu (30.6 g, 318.4 mmol) and 2500 mL of toluene were added into a flask followed by stirring for 48 hours at 95° C. The mixture was cooled to room temperature, and the organic layer was extracted with ethyl acetate. The remaining moisture in the extracted organic layer was removed with magnesium sulfate. Thereafter, the organic layer was dried, and separated by column chromatography to obtain compound H1-17 (34 g, yield: 30%).

| | MW | M.P. |
|---|---|---|
| H1-17 | 704.83 | 200.5° C. |

### EXAMPLE 2: PREPARATION OF COMPOUND H1-16

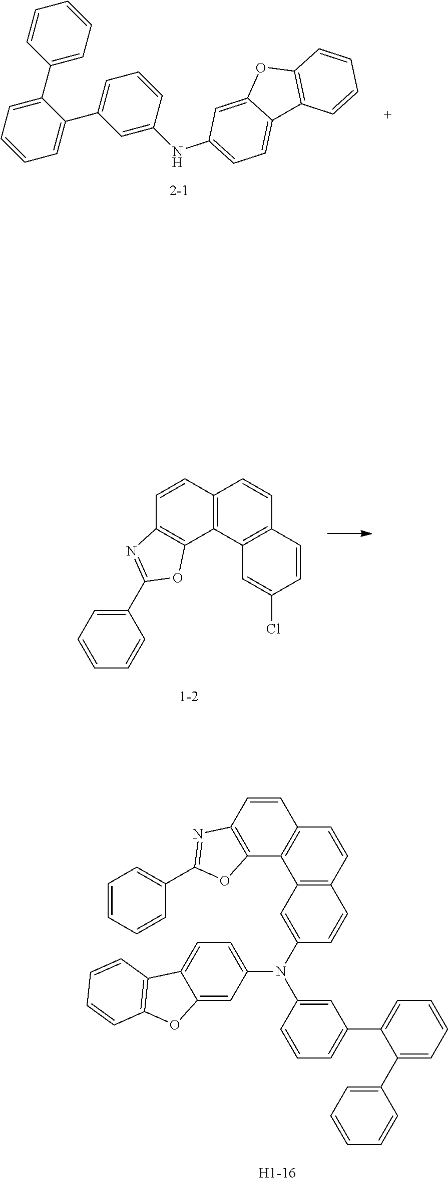 [SMILES: c1ccc(-c2ccccc2-c2cccc(Nc3ccc4c(c3)oc3ccccc34)c2)cc1 ; Clc1ccc2ccc3ccc4nc(-c5ccccc5)oc4c3c2c1 ; c1ccc(-c2nc3ccc4ccc5ccc(N(c6cccc(-c7ccccc7-c7ccccc7)c6)c6ccc7c(c6)oc6ccccc67)cc5c4c3o2)cc1]

Compound 2-1 (15 g, 36.4 mmol), compound 1-2 (10.9 g, 33.1 mmol), Pd₂(dba)₃ (1.56 g, 1.7 mmol), S-Phos (2-dicyclophosphino-2′,6′-dimethoxybiphenyl) (1.35 g, 3.31 mmol), NaOtBu (6.36 g, 66.2 mmol) and 170 mL of xylene were added into a flask followed by stirring for 2 hours at 130° C. The mixture was cooled to room temperature, and the organic layer was extracted with ethyl acetate. The remaining moisture in the extracted organic layer was removed with magnesium sulfate. Thereafter, the organic layer was dried, and separated by column chromatography to obtain compound H1-16 (4.3 g, yield: 18%).

| | MW | M.P. |
|---|---|---|
| H1-16 | 704.83 | 230° C. |

### EXAMPLE 3: PREPARATION OF COMPOUND H2-1

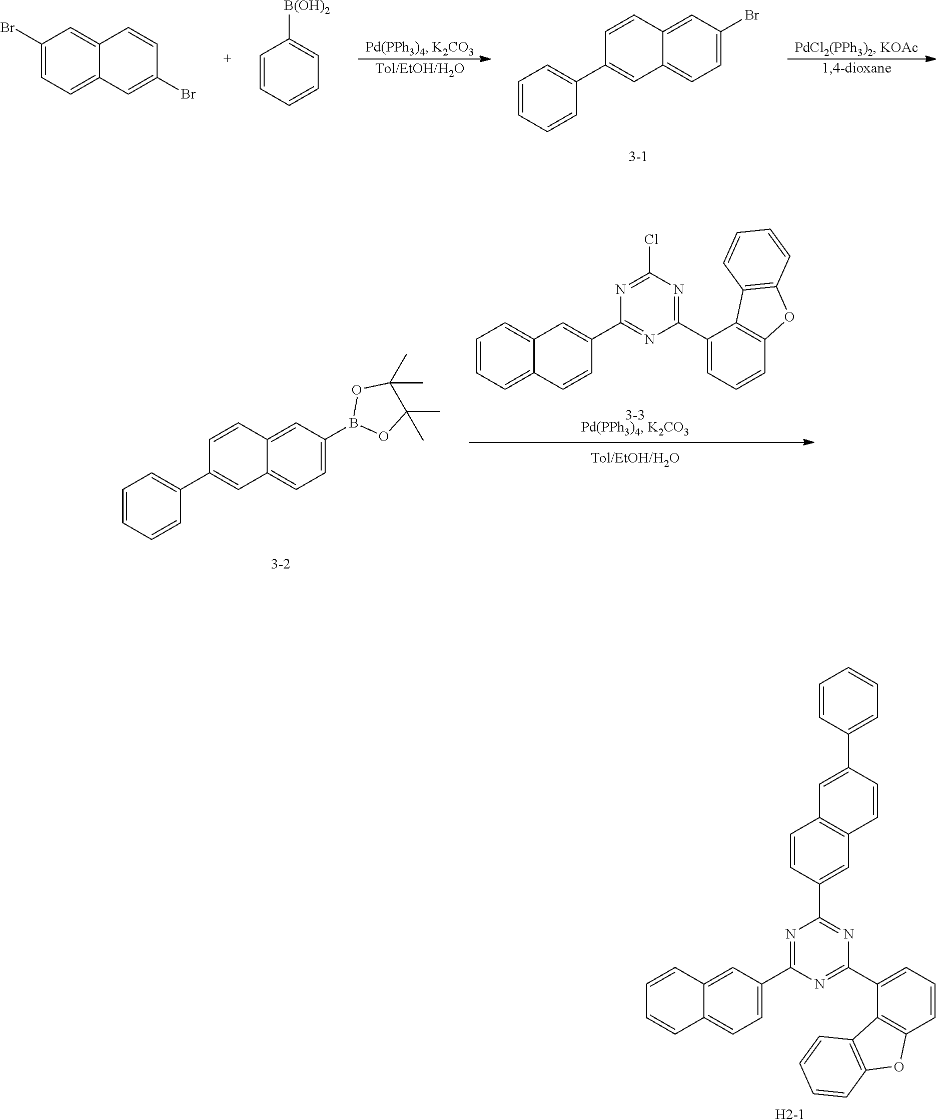

### 1) Synthesis of Compound 3-1

2,6-dibromonaphthalene (20 g, 70 mmol), phenylboronic acid (9 g, 73.4 mmol), K₂CO₃ (24 g, 175 mmol), Pd(PPh₃)₄ (4 g, 3.5 mmol), 350 mL of toluene, 170 mL of H₂O, and 170 mL of ethanol were added into a flask followed by refluxing for 1 hour at 130° C. After completion of the reaction, the organic layer was extracted with ethyl acetate, and the remaining moisture was removed with magnesium sulfate. Thereafter, the organic layer was dried, and separated by column chromatography to obtain compound 3-1 (13 g, yield: 67%).

### 2) Synthesis of Compound 3-2

Compound 3-1 (13 g, 45.9 mmol), 4,4,4′,4′,5,5,5′,5′-octamethyl-2,2′-bi(1,3,2-dioxaborolane) (17.5 g, 68.8 mmol), KOAc (11.3 g, 114.75 mmol), PdCl₂(PPh₃)₂ (3.2 g, 4.59 mmol), and 230 mL of 1,4-dioxane were added into a flask followed by refluxing for 2 hours at 150° C. After completion of the reaction, the organic layer was extracted with ethyl acetate, and the remaining moisture was removed with magnesium sulfate. Thereafter, the organic layer was dried, and separated by column chromatography to obtain compound 3-2 (9 g, yield: 59.3%).

### 3) Synthesis of Compound H2-1

Compound 3-2 (6.4 g, 19.16 mmol), compound 3-3 (6.5 g, 15.96 mmol), K₂CO₃ (5.5 g, 39.9 mmol), Pd(PPh₃)₄ (922 mg, 0.798 mmol), 80 mL of toluene, 40 mL of ethanol, and 40 mL of H₂O were added into a flask followed by refluxing for 2 hours at 130° C. After completion of the reaction, the organic layer was extracted with ethyl acetate, and the remaining moisture was removed with magnesium sulfate. Thereafter, the organic layer was dried, and separated by column chromatography to obtain compound H2-1 (4.9 g, yield: 53.3%).

| | MW | M.P. |
|---|---|---|
| H2-1 | 575.20 | 242.5° C. |

### EXAMPLE 4: PREPARATION OF COMPOUND H2-3

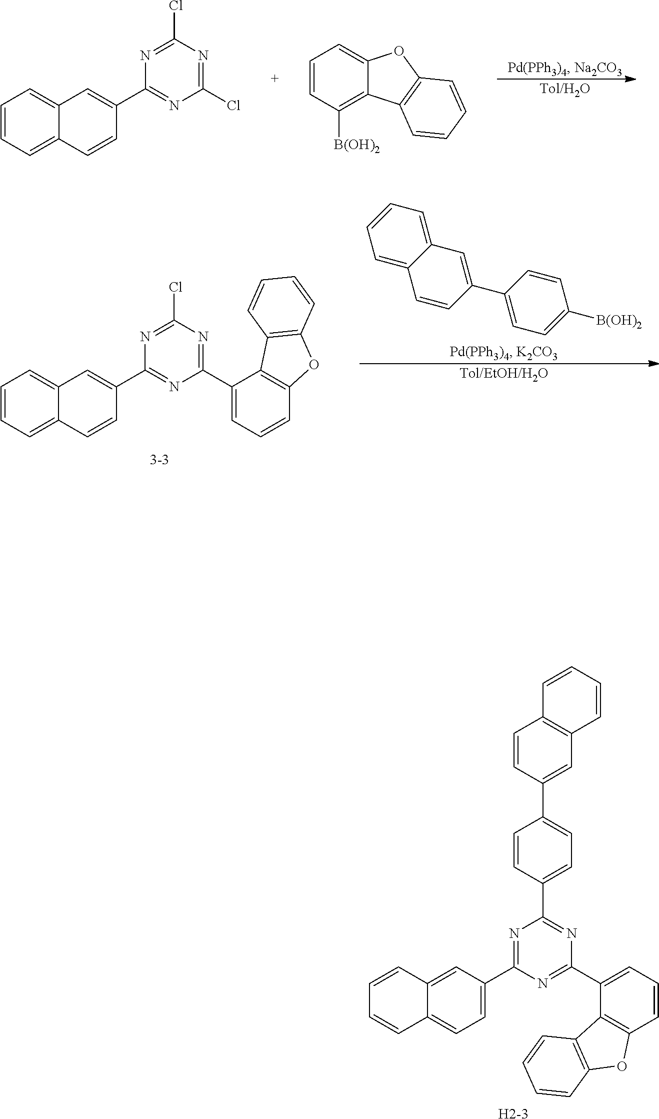

### 1) Synthesis of Compound 3-3

2,4-dichloro-6-(naphthalen-2-yl)-1,3,5-triazine (58 g, 212 mmol), dibenzo[b,d]furan-1-yl boronic acid (30 g, 141 mmol), Na₂CO₃ (45 g, 424 mmol), Pd(PPh₃)₄ (4.9 g, 7.05 mmol), 1.4 L of toluene and 352 mL of H₂O were added into a flask followed by refluxing for 18 hours at 100° C. After completion of the reaction, the organic layer was extracted with ethyl acetate, and the remaining moisture was removed with magnesium sulfate. Thereafter, the organic layer was dried, and separated by column chromatography to obtain compound 3-3 (30 g, yield: 52%).

### 2) Synthesis of Compound H2-3

Compound 3-3 (6 g, 14.7 mmol), 4-(naphthalen-2-yl)-phenyl boronic acid (5.8 g, 17.64 mmol), K₂CO₃ (5.0 g, 36.75 mmol), Pd(PPh₃)₄ (0.85 mg, 0.73 mmol), 70 mL of toluene, 35 mL of ethanol, and 35 mL of H₂O were added into a flask followed by refluxing for 4 hours at 130° C. After completion of the reaction, the organic layer was extracted with ethyl acetate, and the remaining moisture was removed with magnesium sulfate. Thereafter, the organic layer was dried, and separated by column chromatography to obtain compound H2-3 (4.9 g, yield: 58%).

| | MW | M.P. |
|---|---|---|
| H2-3 | 575.20 | 192.9° C. |

### EXAMPLE 5: PREPARATION OF COMPOUND H2-39

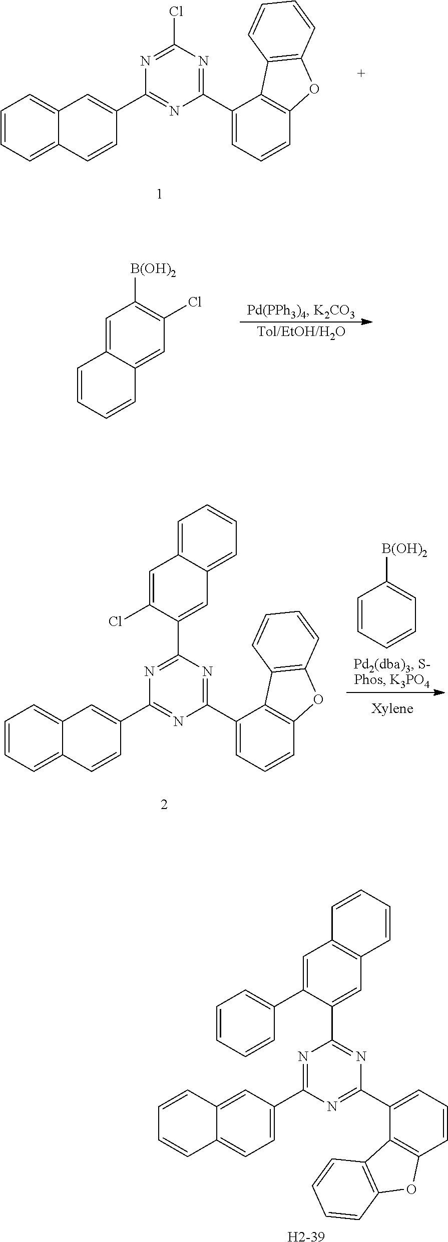

### 1) Synthesis of Compound 2

Compound 1 (5 g, 12.2 mmol), 3-chloronaphthalen-2-yl boronic acid (3 g, 14.7 mmol), Pd(PPh₃)₄ (704 mg, 0.61 mmol), K₂CO₃ (4.2 g, 30.2 mmol), 60 mL of toluene, 30 mL of ethanol, and 30 mL of H₂O were added into a flask followed by stirring for 1 hour at 130° C. The mixture was cooled to room temperature, and the organic layer was extracted with ethyl acetate. The remaining moisture in the extracted organic layer was removed with magnesium sulfate. Thereafter, the organic layer was dried, and separated by column chromatography to obtain compound 2 (6 g, yield: 92%).

### 2) Synthesis of Compound H2-39

Compound 2 (4 g, 7.48 mmol), phenylboronic acid (1.1 g, 8.23 mmol), Pd₂(dba)₃ (340 mg, 0.374 mmol), S-Phos (246 mg, 0.598 mmol), K₃PO₄ (3.97 g, 18.7 mmol), and 70 mL of xylene were added into a flask followed by stirring under reflux for 12 hours at 130° C. The mixture was cooled to room temperature, and the organic layer was extracted with ethyl acetate. The remaining moisture in the extracted organic layer was removed with magnesium sulfate. Thereafter, the organic layer was dried, and separated by column chromatography to obtain compound H2-39 (1.4 g, yield: 32.5%).

| | MW | M.P. |
|---|---|---|
| H2-39 | 575.20 | 216.8° C. |

### EXAMPLE 6: PREPARATION OF COMPOUND H2-41

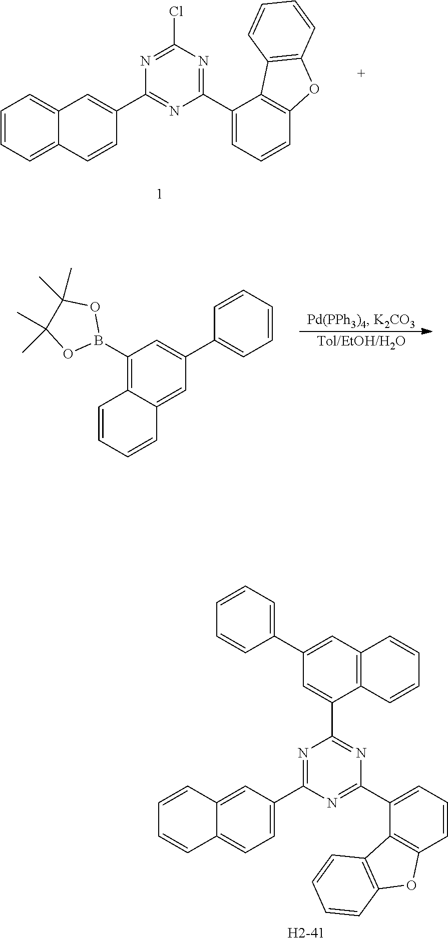

Compound 1 (8.2 g, 24.8 mmol), 4,4,5,5-tetramethyl-2-(3-phenylnaphthalen-1-yl)-1,3,2-dioxaborolane (12 g, 29.8 mmol), Pd(PPh₃)₄ (1.4 mg, 1.24 mmol), K₂CO₃ (8.6 g, 62 mmol), 120 mL of toluene, 60 mL of ethanol, and 60 mL of H₂O were added into a flask followed by stirring for 1 hour at 130° C. The mixture was cooled to room temperature, and the organic layer was extracted with ethyl acetate. The remaining moisture in the extracted organic layer was removed with magnesium sulfate. Thereafter, the organic layer was dried, and separated by column chromatography to obtain compound H2-41 (4.1 g, yield: 28.7%).

| | MW | M.P. |
|---|---|---|
| H2-41 | 575.20 | 159.6° C. |

### EXAMPLE 7: PREPARATION OF COMPOUND H2-44

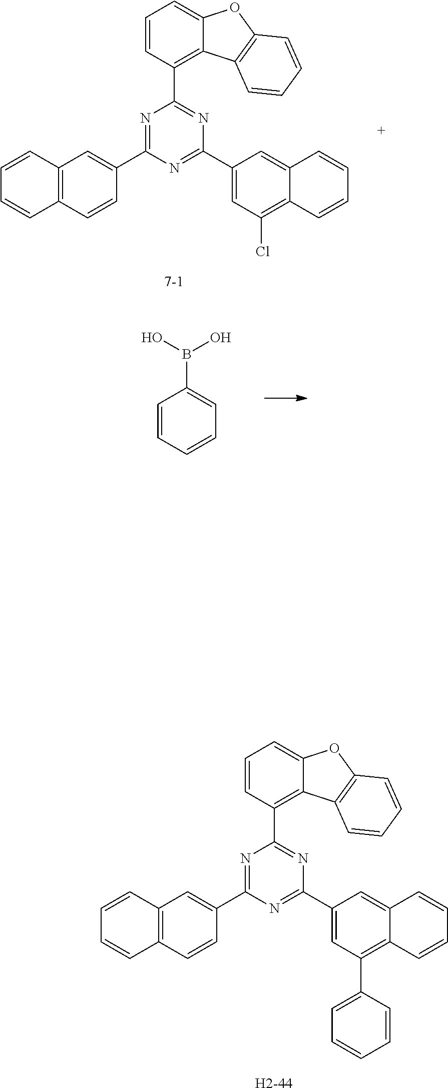 [SMILES: Clc1cc(-c2nc(-c3ccc4ccccc4c3)nc(-c3cccc4oc5ccccc5c34)n2)cc2ccccc12 ; "7-1" ; OB(O)c1ccccc1 ; c1ccc(-c2cc(-c3nc(-c4ccc5ccccc5c4)nc(-c4cccc5oc6ccccc6c45)n3)cc3ccccc23)cc1 ; "H2-44"]

Compound 7-1 (8.5 g, 15.91 mol), phenylboronic acid (2.3 g, 19.10 mmol), K₃PO₄ (8.4 g, 39.77 mmol), S-Phos (653 mg, 1.591 mmol), Pd₂(dba)₃ (1.4 g, 1.591 mmol), and 100 mL of toluene were added into a flask followed by stirring under reflux for 12 hours at 130° C. After completion of the reaction, the organic layer was extracted with ethyl acetate, and the remaining moisture was removed with magnesium sulfate. Thereafter, the organic layer was dried, and separated by column chromatography to obtain compound H2-44 (4.0 g, yield: 43%).

| | MW | M.P. |
|---|---|---|
| H2-44 | 575.67 | 231.9° C. |

### EXAMPLE 8: PREPARATION OF COMPOUND H2-42

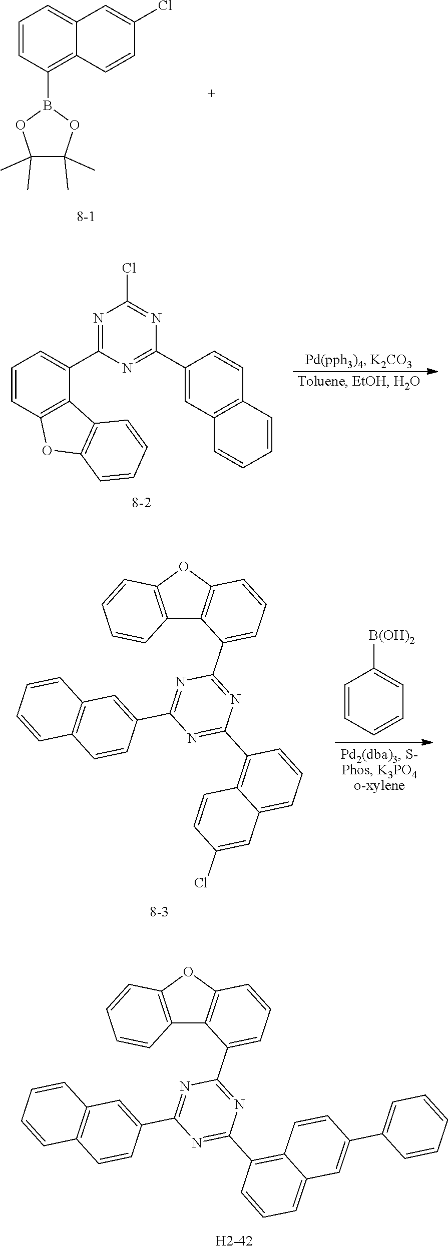

### 1) Synthesis of Compound 8-3

Compound 8-1 (21.0 g, 72.77 mmol), compound 8-2 (35.6 g, 87.32 mmol), Pd(pph₃)₄ (4.2 g, 3.64 mmol), and K₂CO₃ (138.21 g, 149.54 mmol) were dissolved in 365 mL of toluene, 90 mL of ethanol, and 90 mL of H₂O and stirred under reflux for 2 hours. The mixture was cooled to room temperature. H₂O was added to the reactant in which the solid was formed, and the mixture was stirred for 30 minutes and filtered. The filtrate was recrystallized to obtain compound 8-3 (33.1 g, yield: 85.3%).

### 2) Synthesis of Compound H2-42

Compound 8-3 (10.0 g, 18.73 mmol), phenylboronic acid (9.2 g, 74.90 mmol), Pd₂(dba)₃ (1.8 g, 1.88 mmol), S-Phos (0.8 g, 3.74 mmol), and K₃PO₄ (20.0 g, 93.64 mmol) were dissolved in 150 mL of o-xylene and stirred under reflux for 2 hours 30 minutes. The mixture was cooled to room temperature, filtered through celite, separated by column chromatography, and recrystallized to obtain compound H2-42 (3.0 g, yield: 28.0%).

| | MW | M.P. |
|---|---|---|
| H2-42 | 575.66 | 227° C. |

### EXAMPLE 9: PREPARATION OF COMPOUND H2-46

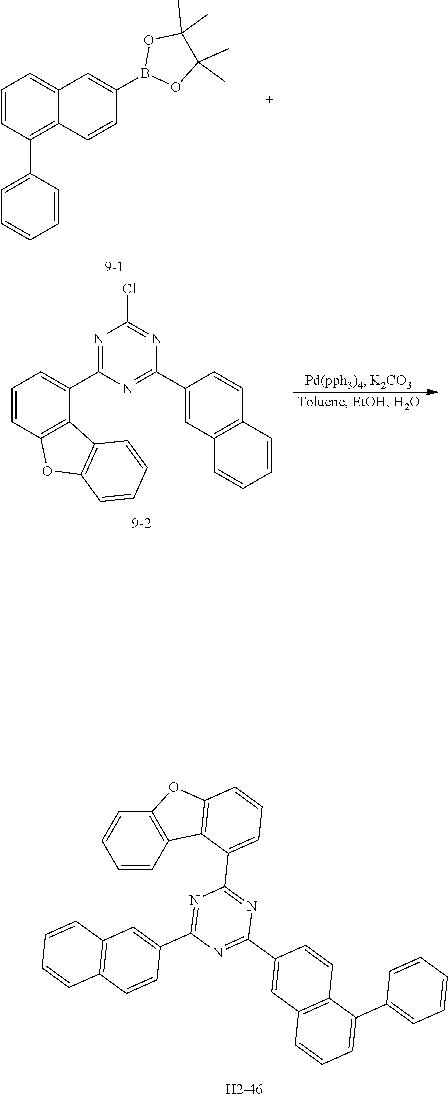 [SMILES: CC1(C)OB(c2ccc3c(-c4ccccc4)cccc3c2)OC1(C)C ; Clc1nc(-c2ccc3ccccc3c2)nc(-c2cccc3oc4ccccc4c23)n1 ; "Pd(pph3)4, K2CO3" ; "Toluene, EtOH, H2O" ; c1ccc(-c2cccc3cc(-c4nc(-c5ccc6ccccc6c5)nc(-c5cccc6oc7ccccc7c56)n4)ccc23)cc1]

Compound 9-1 (15.2 g, 46.03 mmol), compound 9-2 (22.5 g, 55.23 mmol), Pd(pph₃)₄ (2.7 g, 2.30 mmol), and K₂CO₃ (12.7 g, 92.06 mmol) were dissolved in 230 mL of toluene, 60 mL of ethanol, and 60 mL of H₂O and stirred under reflux for 3 hours. The mixture was cooled to room temperature. H₂O was added to the reactant in which solid was formed, and the mixture was stirred for 30 minutes, and then filtered. The filtrate was filtered through silica and then recrystallized to obtain compound H2-46 (19.6 g, yield: 73.9%).

| | MW | M.P. |
|---|---|---|
| H2-46 | 575.66 | 209° C. |

### EXAMPLE 10: PREPARATION OF COMPOUND H2-37

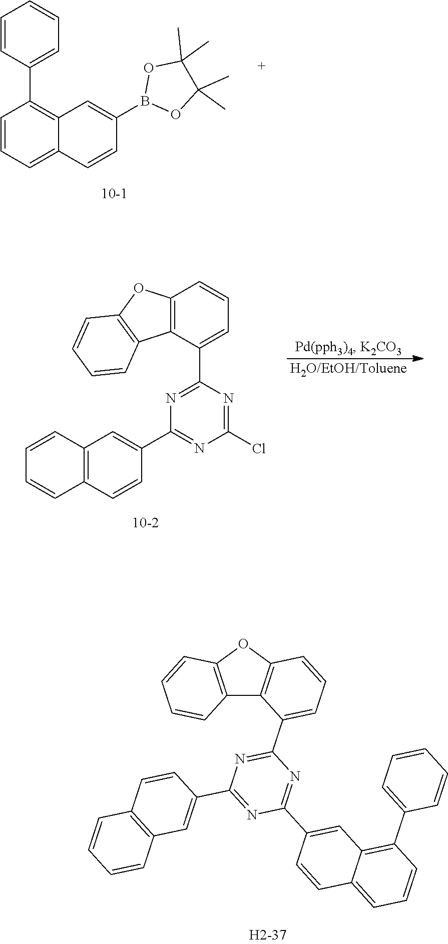 [SMILES: CC1(C)OB(c2ccc3cccc(-c4ccccc4)c3c2)OC1(C)C ; Clc1nc(-c2ccc3ccccc3c2)nc(-c2cccc3oc4ccccc4c23)n1 ; "H2O/EtOH/Toluene" ; "Pd(pph3)4, K2CO3" ; c1ccc(-c2cccc3ccc(-c4nc(-c5ccc6ccccc6c5)nc(-c5cccc6oc7ccccc7c56)n4)cc23)cc1]

Compound 10-1 (4.6 g, 13.93 mmol), compound 10-2 (5.6 g, 13.93 mmol), Pd(pph₃)₄ (0.8 g, 0.696 mmol), K₂CO₃ (5.7 g, 41.79 mmol), 20 mL of H₂O, 20 mL of ethanol, and 80 mL of toluene were added into a flask followed by stirring under reflux for 2 hours. After completion of the reaction, the mixture was cooled to room temperature. Then, methanol was added dropwise to the mixture, and filtered. The filtrate was dissolved in o-xylene and filtered through silica to obtain compound H2-37 (3.9 g, yield: 48%).

| | MW | M.P. |
|---|---|---|
| H2-37 | 575.6 | 264.1° C. |

### EXAMPLE 11: PREPARATION OF COMPOUND H2-43

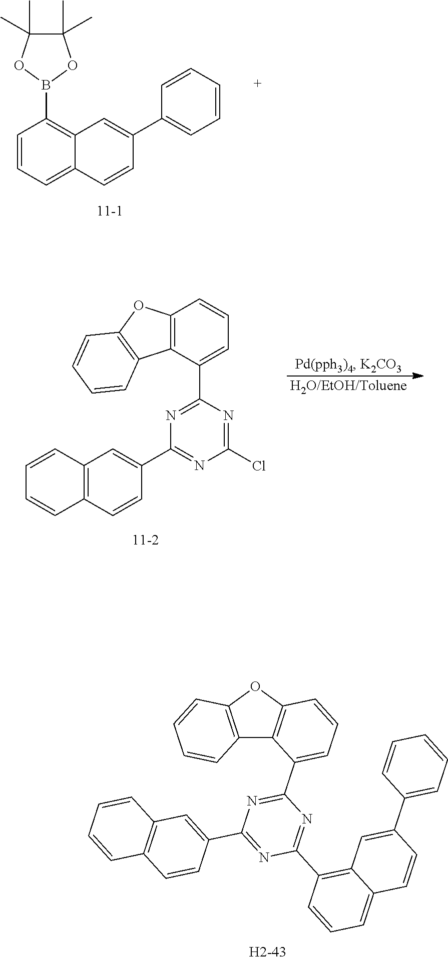 [SMILES: CC1(C)OB(c2cccc3ccc(-c4ccccc4)cc23)OC1(C)C ; Clc1nc(-c2ccc3ccccc3c2)nc(-c2cccc3oc4ccccc4c23)n1 ; "H2O/EtOH/Toluene" ; "Pd(pph3)4, K2CO3" ; c1ccc(-c2ccc3cccc(-c4nc(-c5ccc6ccccc6c5)nc(-c5cccc6oc7ccccc7c56)n4)c3c2)cc1]

Compound 11-1 (4.4 g, 13.48 mmol), compound 11-2 (5 g, 12.25 mmol), Pd(pph₃)₄ (0.7 g, 0.612 mmol), K₂CO₃ (5.1 g, 36.77 mmol), 20 mL of H₂O, 20 mL of ethanol, and 80 mL of toluene were added into a flask followed by stirring under reflux for 2 hours. After completion of the reaction, the mixture was cooled to room temperature. Then, methanol was added dropwise to the mixture, and filtered. The filtrate was dissolved in o-xylene and filtered through silica to obtain compound H2-43 (4.6 g, yield: 65%).

| | MW | M.P. |
|---|---|---|
| H2-43 | 575.6 | 224.9° C. |

### EXAMPLE 12: PREPARATION OF COMPOUND H2-61

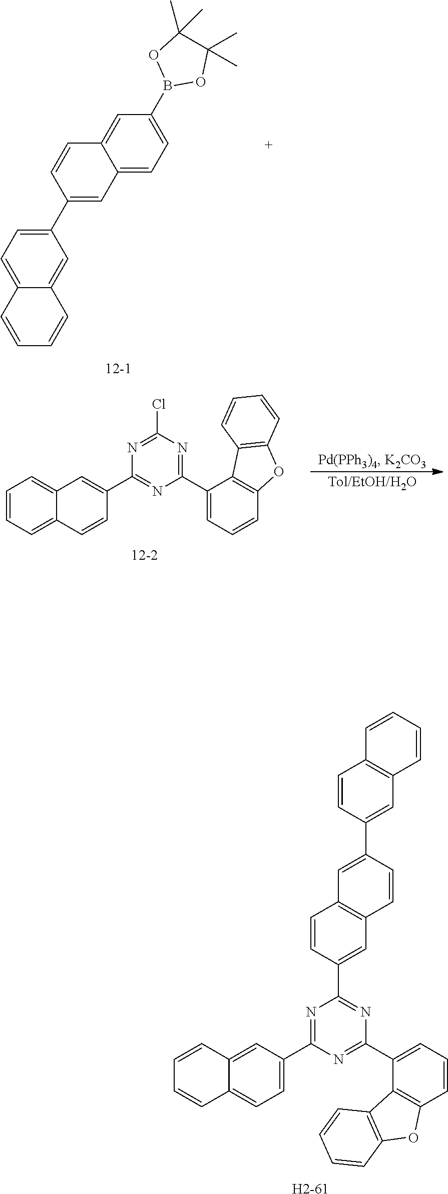

Compound 12-1 (10 g, 24.5 mmol), compound 12-2 (3 g, 14.7 mmol), Pd(PPh₃)₄ (1.4 g, 1.225 mmol), K₂CO₃ (6.7 g, 49 mmol), 120 mL of toluene, 60 mL of ethanol, and 60 mL of H₂O were added into a flask followed by stirring for 3 hours at 130° C. After completion of the reaction, the mixture was cooled to room temperature, and the organic layer was extracted with ethyl acetate. The remaining moisture in the extracted organic layer was removed with magnesium sulfate. Thereafter, the organic layer was dried, and separated by column chromatography to obtain compound H2-61 (13 g, yield: 84%).

| | MW | M.P. |
|---|---|---|
| H2-61 | 625.73 | 229.1° C. |

### EXAMPLE 13: PREPARATION OF COMPOUND H2-64

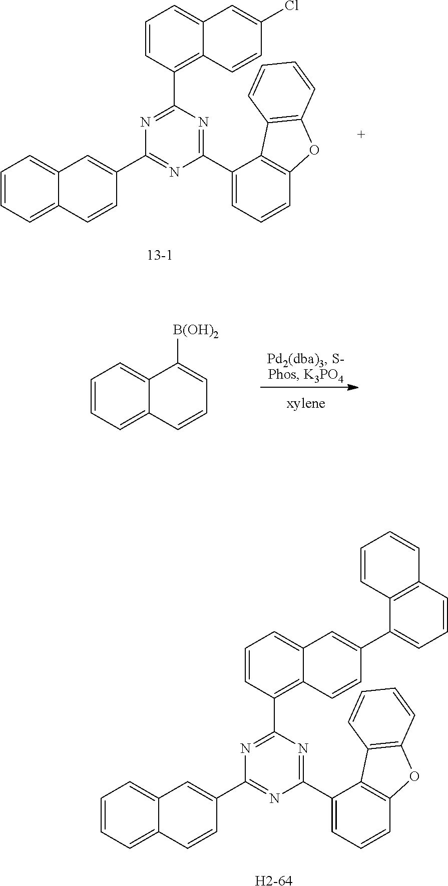

Compound 13-1 (10 g, 18.7 mmol), naphthalen-1-yl-boronic acid (6.5 g, 37.4 mmol), Pd₂(dba)₃ (856 mg, 0.935 mmol), S-Phos (767 mg, 1.87 mmol), K₃PO₄ (9.9 g, 46.75 mmol), and 93.5 mL of xylene were added into a flask followed by stirring for 18 hours at 160° C. After completion of the reaction, the mixture was cooled to room temperature, and the organic layer was extracted with ethyl acetate. The remaining moisture in the extracted organic layer was removed with magnesium sulfate. Thereafter, the organic layer was dried, and separated by column chromatography to obtain compound H2-64 (4.4 g, yield: 37.6%).

| | MW | M.P. |
|---|---|---|
| H2-64 | 625.73 | 237.2° C. |

### DEVICE EXAMPLES 1 TO 6: PRODUCING OLEDS COMPRISING THE PLURALITY OF HOST MATERIALS ACCORDING TO THE PRESENT DISCLOSURE

An OLED according to the present disclosure was produced. First, a transparent electrode indium tin oxide (ITO) thin film (Ω/sq) on a glass substrate for an OLED (GEOMATEC CO., LTD., Japan) was subjected to an ultrasonic washing with acetone and isopropyl alcohol, sequentially, and then was stored in isopropyl alcohol. The ITO substrate was mounted on a substrate holder of a vacuum vapor deposition apparatus. Compound HI-1 shown in Table 7 was introduced into a cell of the vacuum vapor deposition apparatus, and compound HT-1 was introduced into another cell. The two materials were evaporated at different rates, and compound HI-1 was deposited in a doping amount of 3 wt % based to the total amount of compound HI-1 and compound HT-1 to form a hole injection layer with a thickness of 10 nm. Subsequently, compound HT-1 was deposited on the hole injection layer to form a first hole transport layer with a thickness of 80 nm. Next, compound HT-2 was introduced into another cell of the vacuum vapor deposition apparatus and was evaporated by applying an electric current to the cell, thereby depositing a second hole transport layer with a thickness of 60 nm on the first hole transport layer. After forming the hole injection layer and the hole transport layers, a light-emitting layer was deposited thereon as follows: Each of the first host compound and the second host compound shown in Tables 1 to 3 below were introduced into two cells of the vacuum vapor deposition apparatus as hosts, and compound D-39 was introduced into another cell as a dopant. The two host materials were evaporated at a rate of 1:1 and the dopant material was simultaneously evaporated at a different rate, and the dopant was deposited in a doping amount of 3 wt % based on the total amount of the hosts and dopant to form a light-emitting layer with a thickness of 40 nm on the second hole transport layer. Then, compound ETL-1 and compound EIL-1 were evaporated at a weight ratio of 50:50 as an electron transport material to form an electron transport layer having a thickness of 35 nm on the light-emitting layer. After depositing compound EIL-1 as an electron injection layer with a thickness of 2 nm on the electron transport layer, an AI cathode was deposited with a thickness of 80 nm on the electron injection layer by using another vacuum vapor deposition apparatus, thereby producing an OLED. All the materials used for producing the OLED were purified by vacuum sublimation at 10⁻⁶ torr.

### COMPARATIVE EXAMPLES 1 TO 5: PRODUCING OLEDS COMPRISINQ A HOST COMBINATION NOT ACCORDING TO THE PRESENT DISCLOSURE

OLEDs were produced in the same manner as in Device Examples 1 to 6, except that the host compound shown in Tables 1 to 3 was used as the first host compound of the light-emitting layer.

The driving voltage, luminous efficiency, and light-emitting color at a luminance of 1,000 nit, and the time taken for luminance to reduce from 100% to 95% at a luminance of 10,000 nit (lifespan: T95) of the organic electroluminescent devices of Device Examples 1 to 6 and Comparative Examples 1 to 5 produced as described above, are shown in the following Tables 1 to 3.

TABLE 1

| | | | Driving | Luminous | Light- | |
|---|---|---|---|---|---|---|
| | First Host | Second Host | Voltage | Efficiency | Emitting | Lifespan |
| | Compound | Compound | (V) | (cd/A) | Color | T95(hr) |
| Device | H1-16 | H2-1 | 2.9 | 32.7 | Red | 104 |
| Example 1 | | | | | | |
| Device | H1-17 | H2-1 | 2.9 | 32.8 | Red | 96 |
| Example 2 | | | | | | |
| Comparative | Ref-1 | H2-1 | 3.0 | 30.9 | Red | 74 |
| Example 1 | | | | | | |
| Comparative | Ref-2 | H2-1 | 3.0 | 28.7 | Red | 64 |
| Example 2 | | | | | | |

TABLE 2

| | | | Driving | Luminous | Light- | |
|---|---|---|---|---|---|---|
| | First Host | Second Host | Voltage | Efficiency | Emitting | Lifespan |
| | Compound | Compound | (V) | (cd/A) | Color | T95(hr) |
| Device | H1-16 | H2-2 | 3.0 | 33.2 | Red | 42 |
| Example 3 | | | | | | |
| Device | H1-17 | H2-2 | 2.9 | 33.0 | Red | 46 |
| Example 4 | | | | | | |
| Comparative | Ref-1 | H2-2 | 3.0 | 30.7 | Red | 18 |
| Example 3 | | | | | | |
| Comparative | Ref-2 | H2-2 | 3.0 | 29.3 | Red | 23 |
| Example 4 | | | | | | |

TABLE 3

| | | | Driving | Luminous | Light- | |
|---|---|---|---|---|---|---|
| | First Host | Second Host | Voltage | Efficiency | Emitting | Lifespan |
| | Compound | Compound | (V) | (cd/A) | Color | T95(hr) |
| Device | H1-16 | H2-4 | 3.0 | 33.0 | Red | 82 |
| Example 5 | | | | | | |
| Device | H1-17 | H2-4 | 2.9 | 32.8 | Red | 85 |
| Example 6 | | | | | | |
| Comparative | Ref-1 | H2-4 | 3.0 | 31.8 | Red | 46 |
| Example 5 | | | | | | |

From Tables 1 to 3 above, it can be confirmed that the OLEDs (Device Examples 1 to 6) comprising a specific combination of compounds according to the present disclosure as host materials, exhibit lower driving voltage and/or higher luminous efficiency, and significantly improved lifespan characteristics compared to the OLEDs (Comparative Examples 1 to 5) comprising a host combination not according to the present disclosure.

[Characteristic Analysis]

In order to support the theory of the combination of the host material and the electron transport zone according to the present disclosure, a Hole Only Device (HOD) was produced to confirm and compare the hole current characteristics in devices based on the properties of biphenyl and terphenyl in phenanthroxazole derivatives. The structure of the hole only device is as follows.

Hole Only Device (HOD) Example

An ITO substrate was mounted on a substrate holder of a vacuum vapor deposition apparatus. Compound HI-1 shown in Table 7 was introduced into a cell of the vacuum vapor deposition apparatus, and then the pressure in the chamber of the apparatus was controlled to 10⁻⁷ torr. Thereafter, an electric current was applied to the cell to evaporate the above-introduced material, thereby forming a hole injection layer having a thickness of 10 nm on the ITO substrate. Compound HI-1 was introduced into a cell of the vacuum vapor deposition apparatus, and compound HT-1 was introduced into another cell. The two materials were evaporated at different rates, and compound HI-1 was deposited in a doping amount of 3 wt % based to the total amount of compound HI-1 and compound HT-1 to form a first hole transport layer with a thickness of 10 nm. Next, compound HT-2 was introduced into another cell of the vacuum vapor deposition apparatus and was evaporated by applying an electric current to the cell, thereby depositing a second hole transport layer with a thickness of 10 nm on the first hole transport layer. After forming the hole injection layer and the hole transport layers, a light-emitting layer was deposited thereon as follows: The compound shown in Table 4 below was introduced into a cell of the vacuum vapor deposition apparatus as a host, and evaporated to form a light-emitting layer with a thickness of 40 nm on the second hole transport layer. Then, Compound HI-1 was introduced into a cell of the vacuum vapor deposition apparatus, and compound HT-1 was introduced into another cell. The two materials were evaporated at different rates, and compound HI-1 was deposited in a doping amount of 3 wt % based to the total amount of compound HI-1 and compound HT-1 to form a electron blocking layer with a thickness of 10 nm on the light-emitting layer. Then, an AI cathode was deposited with a thickness of 80 nm on the electron blocking layer by using another vacuum vapor deposition apparatus, thereby producing an OLED. All the materials used for producing the OLED were purified by vacuum sublimation at 10⁻⁷ torr.

Table 4 below shows current densities (mA/cm²) reaching a voltage of 2 V depending on the material of the light-emitting layer of the hole only device produced as described above.

TABLE 4

| Llight-Emitting | Current Density |
|---|---|
| Layer | (mA/cm²) |
| Ref-1 | 11 |
| H1-16 | 20 |

From Table 4 above, it can be confirmed that the hole only device comprising the compound according to the present disclosure, exhibits higher current density and faster hole current characteristics compared to the hole only device comprising the compound not according to the present disclosure. Upon comparing the HOMO energy levels of the compounds included in the second hole transport layer and the light-emitting layer in the Hole Only Device Example, the compound Ref-1 comprising a biphenyl group and the compound H1-16 comprising a terphenyl group have energy levels of −4.95 eV and −4.92 eV, respectively, and the compound HT-2 included in the second hole transport layer has an energy level of −4.88 eV. Therefore, without being limited by theory, it can be confirmed that the hole only device comprising the compound according to the present disclosure smoothly injects holes from the hole transport layer to the light-emitting layer. Accordingly, an organic electroluminescent device comprising the compound according to the present disclosure may exhibit low driving voltage, high luminous efficiency, and/or long lifespan characteristics.

### DEVICE EXAMPLES 7 TO 12: PRODUCING OLEDS COMPRISING THE PLURALITY OF HOST MATERIALS ACCORDING TO THE PRESENT DISCLOSURE

OLEDs were produced in the same manner as in Device Examples 1 to 6, except that compound HT-3 and compound HT-4 were used instead of compound HT-1 and compound HT-2, respectively, and the compounds shown in Table 5 were used as the first host compound and the second host compound of the light-emitting layer.

The driving voltage, luminous efficiency, and light-emitting color at a luminance of 1,000 nit, and the time taken for luminance to reduce from 100% to 95% at a luminance of 10,000 nit (lifespan: T95) of the OLEDs of Device Examples 7 to 12 produced as described above, are shown in the following Table 5.

TABLE 5

| | | | Driving | Luminous | Light- | |
|---|---|---|---|---|---|---|
| | First Host | Second Host | Voltage | Efficiency | Emitting | Lifespan |
| | Compound | Compound | (V) | (cd/A) | Color | T95(hr) |
| Device | H1-16 | H2-39 | 3.3 | 36.1 | Red | 252 |
| Example 7 | | | | | | |
| Device | H1-16 | H2-41 | 2.9 | 32.4 | Red | 193 |
| Example 8 | | | | | | |
| Device | H1-16 | H2-44 | 2.9 | 32.9 | Red | 255 |
| Example 9 | | | | | | |
| Device | H1-16 | H2-42 | 3.0 | 35.4 | Red | 220 |
| Example 10 | | | | | | |
| Device | H1-16 | H2-64 | 3.1 | 35.5 | Red | 276 |
| Example 11 | | | | | | |
| Device | H1-16 | H2-61 | 3.0 | 32.3 | Red | 219 |
| Example 12 | | | | | | |

### DEVICE EXAMPLE 13: PRODUCING AN OLED COMPRISING THE SINGLE HOST MATERIAL ACCORDING TO THE PRESENT DISCLOSURE

An OLED was produced in the same manner as in Device Example 7, except that the host compound shown in Table 6 below was used alone as a host material of a light-emitting layer.

### COMPARATIVE EXAMPLE 6: PRODUCING AN OLED COMPRISING A CONVENTIONAL HOST MATERIAL

An OLED was produced in the same manner as in Device Example 13, except that the host compound shown in Table 6 below was used as a host material of a light-emitting layer.

The luminous efficiency and light-emitting color at a luminance of 1,000 nit of the OLEDs of Device Example 13 and Comparative Example 6 produced as described above are shown in the following Table 6.

TABLE 6

| | | Luminous | Light- |
|---|---|---|---|
| | Single Host | Efficiency | Emitting |
| | Compound | (cd/A) | Color |
| Device Example 13 | H2-64 | 30.0 | Red |
| Comparative Example 6 | H2-51 | 26.4 | Red |

From Table 6 above, it can be confirmed that the OLED comprising an organic electroluminescent compound according to the present disclosure as a single host material, exhibits higher luminous efficiency compared to the OLED comprising a conventional host material.

### DEVICE EXAMPLE 14: PRODUCING AN OLED COMPRISING THE PLURALITY OF HOST MATERIALS ACCORDING TO THE PRESENT DISCLOSURE

An OLED was produced in the same manner as in Device Example 7, except that compound HT-5 was used instead of compound HT-4, and the compounds shown in Table 7 were used as the first host compound and the second host compound of the light-emitting layer.

### COMPARATIVE EXAMPLE 7: PRODUCING AN OLED COMPRISING A CONVENTIONAL HOST MATERIAL

An OLED was produced in the same manner as in Device Example 14, except that the host compound shown in Table 7 below was used as a host material of a light-emitting layer.

The driving voltage, power efficiency, and light-emitting color at a luminance of 1,000 nit, and the time taken for luminance to reduce from 100% to 95% at a luminance of 10,000 nit (lifespan: T95) of the OLEDs of Device Example 14 and Comparative Example 7 produced as described above, are shown in the following Table 7.

TABLE 7

| | | | Driving | Power | Light- | |
|---|---|---|---|---|---|---|
| | First Host | Second Host | Voltage | Efficiency | Emitting | Lifespan |
| | Compound | Compound | (V) | (Lm/W) | Color | T95(hr) |
| Device | H1-9 | H2-2 | 2.8 | 39.1 | Red | 195 |
| Example 14 | | | | | | |
| Comparative | Ref-2 | H2-2 | 3.0 | 36.7 | Red | 135 |
| Example 7 | | | | | | |

From Table 7 above, it can be confirmed that the OLED comprising the plurality of host materials according to the present disclosure, exhibits lower driving voltage, higher power efficiency, and excellent lifespan properties compared to the OLED comprising a conventional host material.

The compounds used in the Device Examples, Comparative Examples, and Hole Only Device Example are shown in Table 8 below.

TABLE 8

| | |
|---|---|
| Hole Injection Layer/Hole Transport Layer/ Electron Blocking Layer | 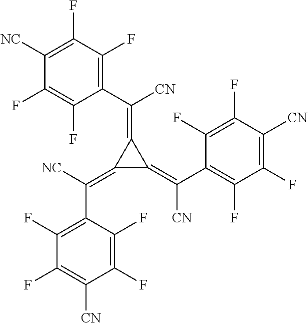 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F] |
| | HI-1 |
| | 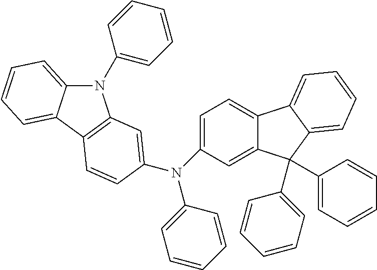 [SMILES: c1ccc(N(c2ccc3c(c2)C(c2ccccc2)(c2ccccc2)c2ccccc2-3)c2ccc3c4ccccc4n(-c4ccccc4)c3c2)cc1] |
| | HT-1 |
| | 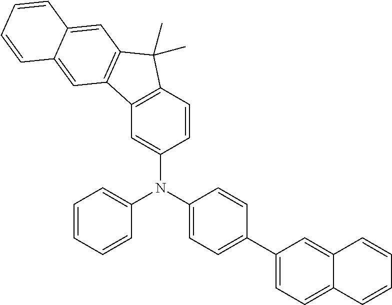 [SMILES: CC1(C)c2ccc(N(c3ccccc3)c3ccc(-c4ccc5ccccc5c4)cc3)cc2-c2cc3ccccc3cc21] |
| | HT-2 |
| | 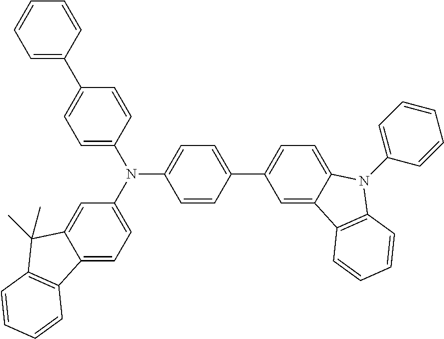 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21] |
| | HT-3 |
| | 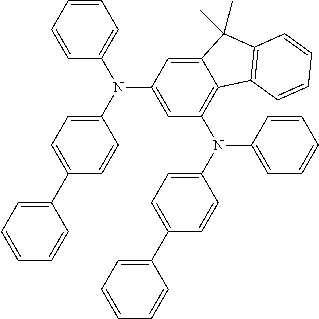 [SMILES: CC1(C)c2ccccc2-c2c(N(c3ccccc3)c3ccc(-c4ccccc4)cc3)cc(N(c3ccccc3)c3ccc(-c4ccccc4)cc3)cc21] |
| | HT-4 |
| | 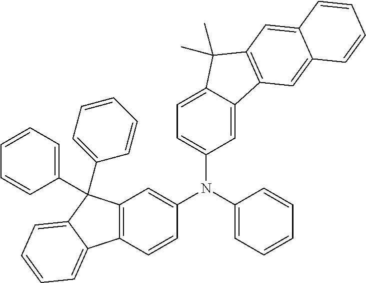 [SMILES: CC1(C)c2ccc(N(c3ccccc3)c3ccc4c(c3)C(c3ccccc3)(c3ccccc3)c3ccccc3-4)cc2-c2cc3ccccc3cc21] |
| | HT-5 |
| Light-Emitting Layer | 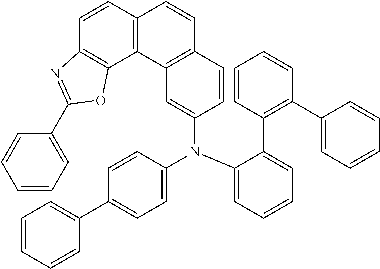 [SMILES: c1ccc(-c2ccc(N(c3ccc4ccc5ccc6nc(-c7ccccc7)oc6c5c4c3)c3ccccc3-c3ccccc3-c3ccccc3)cc2)cc1] |
| | H1-9 |
| | 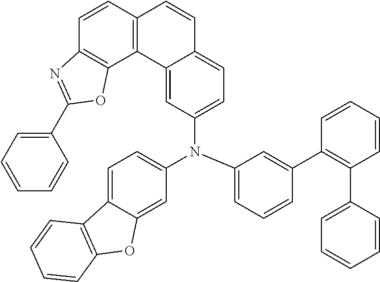 [SMILES: c1ccc(-c2nc3ccc4ccc5ccc(N(c6cccc(-c7ccccc7-c7ccccc7)c6)c6ccc7c(c6)oc6ccccc67)cc5c4c3o2)cc1] |
| | H1-16 |
| | 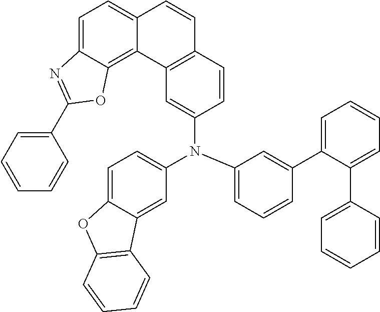 [SMILES: c1ccc(-c2nc3ccc4ccc5ccc(N(c6cccc(-c7ccccc7-c7ccccc7)c6)c6ccc7oc8ccccc8c7c6)cc5c4c3o2)cc1] |
| | H1-17 |
| | 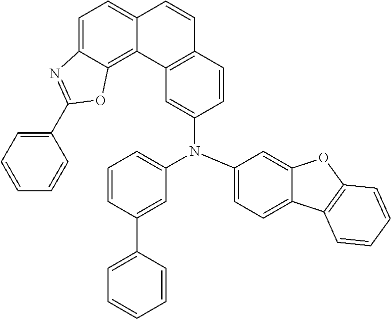 [SMILES: c1ccc(-c2cccc(N(c3ccc4c(c3)oc3ccccc34)c3ccc4ccc5ccc6nc(-c7ccccc7)oc6c5c4c3)c2)cc1] |
| | Ref-1 |
| | 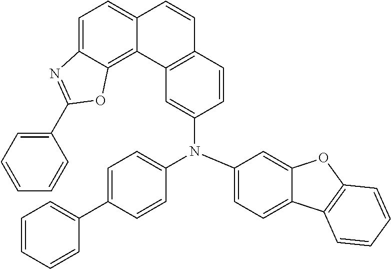 [SMILES: c1ccc(-c2ccc(N(c3ccc4c(c3)oc3ccccc34)c3ccc4ccc5ccc6nc(-c7ccccc7)oc6c5c4c3)cc2)cc1] |
| | Ref-2 |
| | 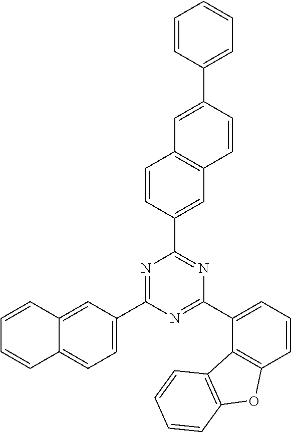 [SMILES: c1ccc(-c2ccc3cc(-c4nc(-c5ccc6ccccc6c5)nc(-c5cccc6oc7ccccc7c56)n4)ccc3c2)cc1] |
| | H2-1 |
| | 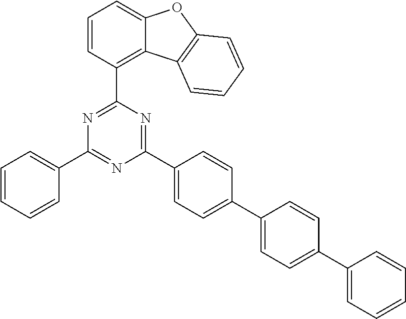 [SMILES: c1ccc(-c2ccc(-c3ccc(-c4nc(-c5ccccc5)nc(-c5cccc6oc7ccccc7c56)n4)cc3)cc2)cc1] |
| | H2-2 |
| | 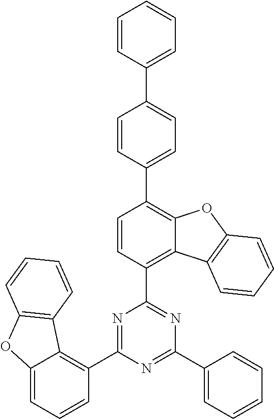 [SMILES: c1ccc(-c2ccc(-c3ccc(-c4nc(-c5ccccc5)nc(-c5cccc6oc7ccccc7c56)n4)c4c3oc3ccccc34)cc2)cc1] |
| | H2-4 |
| | 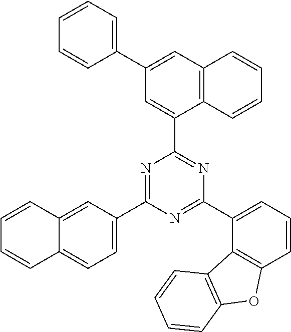 [SMILES: c1ccc(-c2cc(-c3nc(-c4ccc5ccccc5c4)nc(-c4cccc5oc6ccccc6c45)n3)c3ccccc3c2)cc1] |
| | H2-41 |
| | 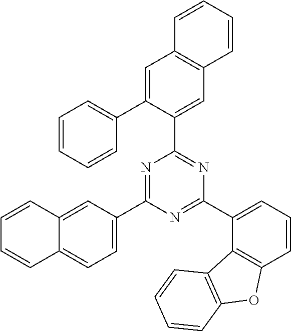 [SMILES: c1ccc(-c2cc3ccccc3cc2-c2nc(-c3ccc4ccccc4c3)nc(-c3cccc4oc5ccccc5c34)n2)cc1] |
| | H2-39 |
| | 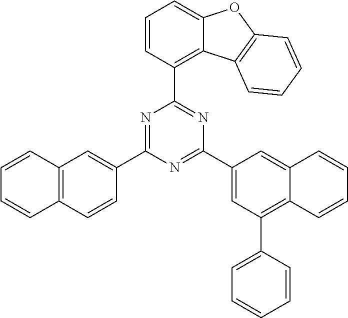 [SMILES: c1ccc(-c2cc(-c3nc(-c4ccc5ccccc5c4)nc(-c4cccc5oc6ccccc6c45)n3)cc3ccccc23)cc1] |
| | H2-44 |
| | 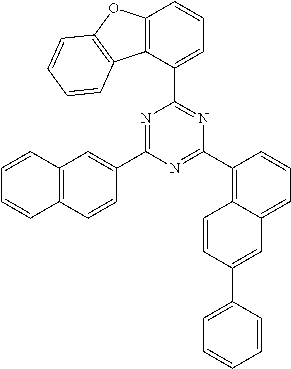 [SMILES: c1ccc(-c2ccc3c(-c4nc(-c5ccc6ccccc6c5)nc(-c5cccc6oc7ccccc7c56)n4)cccc3c2)cc1] |
| | H2-42 |
| | 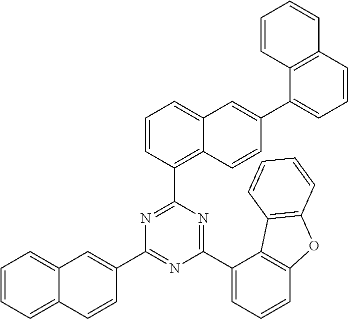 [SMILES: c1ccc2cc(-c3nc(-c4cccc5cc(-c6cccc7ccccc67)ccc45)nc(-c4cccc5oc6ccccc6c45)n3)ccc2c1] |
| | H2-64 |
| | 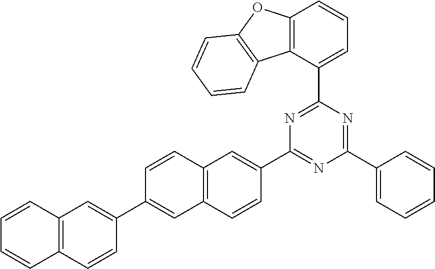 [SMILES: c1ccc(-c2nc(-c3ccc4cc(-c5ccc6ccccc6c5)ccc4c3)nc(-c3cccc4oc5ccccc5c34)n2)cc1] |
| | H2-61 |
| | 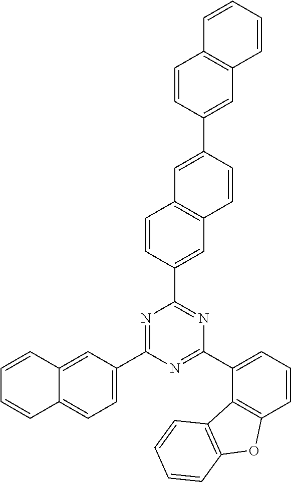 [SMILES: c1ccc2cc(-c3ccc4cc(-c5nc(-c6ccc7ccccc7c6)nc(-c6cccc7oc8ccccc8c67)n5)ccc4c3)ccc2c1] |
| | H2-51 |
| | 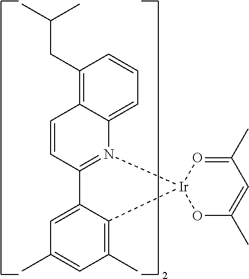 |
| | D-39 |
| Electron Transport Layer/ Electron Injection Layer | 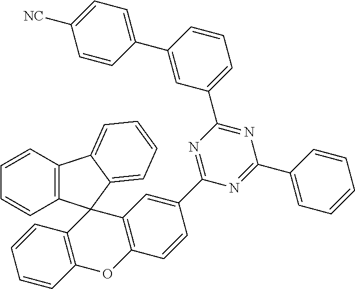 [SMILES: N#Cc1ccc(-c2cccc(-c3nc(-c4ccccc4)nc(-c4ccc5c(c4)C4(c6ccccc6O5)c5ccccc5-c5ccccc54)n3)c2)cc1] |
| | ETL-1 |
| | 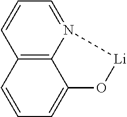 |
| | EIL-1 |

1. A plurality of host materials comprising at least one first host compound and at least one second host compound, wherein the first host compound is represented by the following formula 1, and the second host compound is represented by the following formula 2: 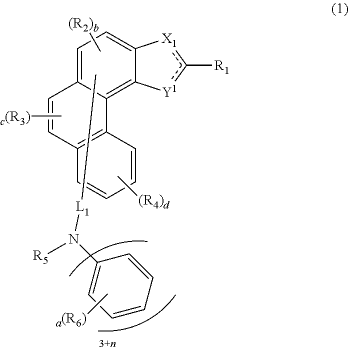
in formula 1,
X₁, and Y₁, each independently represent —N═, —NR₁₁, —O— or —S—, with a proviso that any one of X₁, and Y₁, represents —N═, and the other of X₁, and Y₁, represents —NR₁₁—, —O— or —S—;
R₁ represents a substituted or unsubstituted (C6-C30)aryl, or a substituted or unsubstituted (3- to 30-membered)heteroaryl;
R₂ to R₄ and R₁₁ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring group of a (C3-C30) aliphatic ring(s) and a (C6-C30) aromatic ring(s), or -L₂-N(Ar₁)(Ar₂); or may be linked to an adjacent substituent(s) to form a ring(s);
R₅ represents a substituted or unsubstituted (C6-C30)aryl, or a substituted or unsubstituted (3- to 30-membered)heteroaryl;
R₆ each independently represents hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring group of a (C3-C30) aliphatic ring(s) and a (C6-C30) aromatic ring(s), or -L₂-N(Ar₁)(Ar₂);
L₁ and L₂ each independently represent a single bond, a substituted or unsubstituted (C6-C30)arylene, or a substituted or unsubstituted (3- to 30-membered)heteroarylene;
Ar₁ and Ar₂ each independently represent hydrogen, a substituted or unsubstituted (C1-C30)alkyl, a substituted or unsubstituted (C2-C30)alkenyl, a substituted or unsubstituted fused ring group of a (C3-C30) aliphatic ring(s) and a (C6-C30) aromatic ring(s), a substituted or unsubstituted (C6-C30)aryl, or a substituted or unsubstituted (3- to 30-membered)heteroaryl; and
n represents an integer of 0 to 3, a represents an integer of 1 to 5, d represents an integer of 1 to 4, and b and c each independently represent an integer of 1 or 2, where if a to d are an integer of 2 or more, each of R₂ to each of R₄, and each of R₆ may be the same as or different from each other; 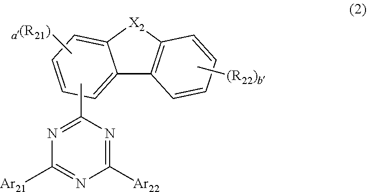
in formula 2,
X₂ represents —O— or —S—;
R₂₁ and R₂₂ each independently represent hydrogen, deuterium, or a substituted or unsubstituted (C6-C30)aryl;
Ar₂₁ represents a substituted or unsubstituted naphthyl, a substituted or unsubstituted dibenzofuranyl, a substituted or unsubstituted dibenzothiophenyl, or a substituted or unsubstituted terphenyl;
Ar₂₂ represents a substituted or unsubstituted phenyl, a substituted or unsubstituted biphenyl, a substituted or unsubstituted naphthyl, or a substituted or unsubstituted terphenyl; and
a′ represents an integer of 1 to 3, and b′ represents an integer of 1 to 4, where if a′ and b′ represent an integer of 2 or more, each of R₂₁ and each of R₂₂ may be the same as or different from each other,
the substituent(s) of the substituted aryl, the substituted phenyl, the substituted biphenyl, the substituted terphenyl, the substituted naphthyl, the substituted dibenzofuranyl, and the substituted dibenzothiophenyl in formula 2 are each independently at least one of deuterium and a (C6-C30) aryl.

2. The plurality of host materials according to claim 1, wherein the substituent(s) of the substituted alkyl, the substituted alkenyl, the substituted aryl, the substituted arylene, the substituted heteroaryl, the substituted heteroarylene, the substituted cycloalkyl, the substituted alkoxy, the substituted trialkylsilyl, the substituted dialkylarylsilyl, the substituted alkyldiarylsilyl, the substituted triarylsilyl, and the substituted fused ring group of an aliphatic ring(s) and an aromatic ring(s) in formula 1 each independently are at least one selected from the group consisting of deuterium; a halogen; a cyano; a carboxyl; a nitro; a hydroxyl; a phosphine oxide; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (3- to 7-membered)heterocycloalkyl; a (C6-C30)aryloxy; a (C6-C30)arylthio; a (3- to 30-membered)heteroaryl; a (C6-C30)aryl unsubstituted or substituted with at least one of deuterium and a (C6-C30)aryl(s); a tri(C1-C30)alkylsilyl(s); a tri(C6-C30)arylsilyl(s); a di(C1-C30)alkyl(C6-C30)arylsilyl; a (C1-C30)alkyldi(C6-C30)arylsilyl; a fused ring group of a (C3-C30) aliphatic ring(s) and a (C6-C30) aromatic ring(s); an amino; a mono- or di- (C1-C30)alkylamino; a mono- or di- (C2-C30)alkenylamino; a (C1-C30)alkyl(C2-C30)alkenylamino; a mono- or di- (C6-C30)arylamino; a (C1-C30)alkyl(C6-C30)arylamino; a mono- or di- (3- to 30-membered)heteroarylamino; a (C1-C30)alkyl(3- to 30-membered)heteroarylamino; a (C2-C30)alkenyl(C6-C30)arylamino; a (C2-C30)alkenyl(3- to 30-membered)heteroarylamino; a (C6-C30)aryl(3- to 30-membered)heteroarylamino; a (C1-C30)alkylcarbonyl; a (C1-C30)alkoxycarbonyl; a (C6-C30)arylcarbonyl; a (C6-C30)arylphosphine; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl.

3. The plurality of host materials according to claim 1, wherein formula 1 is represented by the following formula 1-1: 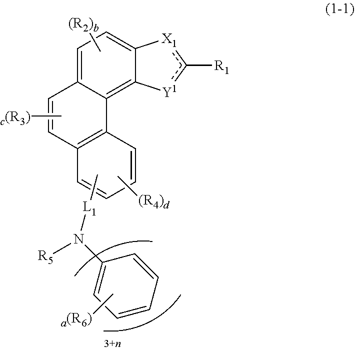
in formula 1-1,
d represents an integer of 1 to 3, where if d is an integer of 2 or more, each of R₄ may be the same as or different from each other; and
X₁, Y₁, R₁, to R₆, L₁, n, and a to c are as defined in claim 1.

4. The plurality of host materials according to claim 1, wherein formula 1 is represented by at least one of the following formulas 1-1-1 to 1-1-4: 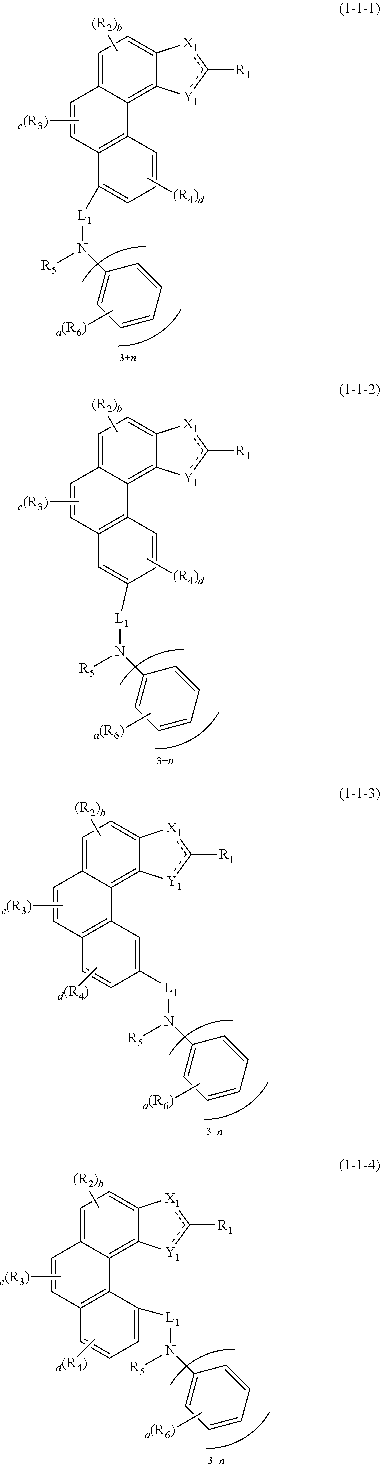
in formulas 1-1-1 to 1-1-4,
d represents an integer of 1 to 3, where if d is an integer of 2 or more, each of R₄ may be the same as or different from each other; and
X₁, Y₁, R₁, to R₆, L₁, n, and a to c are as defined in claim 1.

5. The plurality of host materials according to claim 1, wherein R₅ is a substituted or unsubstituted phenyl, a substituted or unsubstituted naphthyl, a substituted or unsubstituted biphenyl, a substituted or unsubstituted terphenyl, a substituted or unsubstituted phenanthrenyl, a substituted or unsubstituted anthracenyl, a substituted or unsubstituted fluorenyl, a substituted or unsubstituted benzofluorenyl, a substituted or unsubstituted triphenylenyl, a substituted or unsubstituted spirobifluorenyl, a substituted or unsubstituted carbazolyl, a substituted or unsubstituted dibenzothiophenyl, a substituted or unsubstituted benzothiophenyl, a substituted or unsubstituted dibenzofuranyl, or a substituted or unsubstituted benzofuranyl.

6. The plurality of host materials according to claim 1, wherein formula 2 is represented by at least one of the following formulas 2-1 to 2-4: 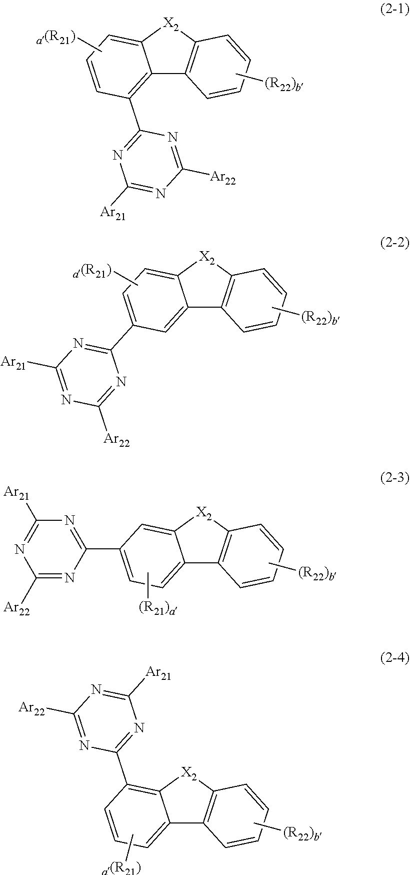
in formulas 2-1 to 2-4, X₂, Ar₂₁, Ar₂₂, R₂₁, R₂₂, a′, and b′ are as defined in claim 1.

7. The plurality of host materials according to claim 1, wherein the compound represented by formula 1 is at least one selected from the following compounds:

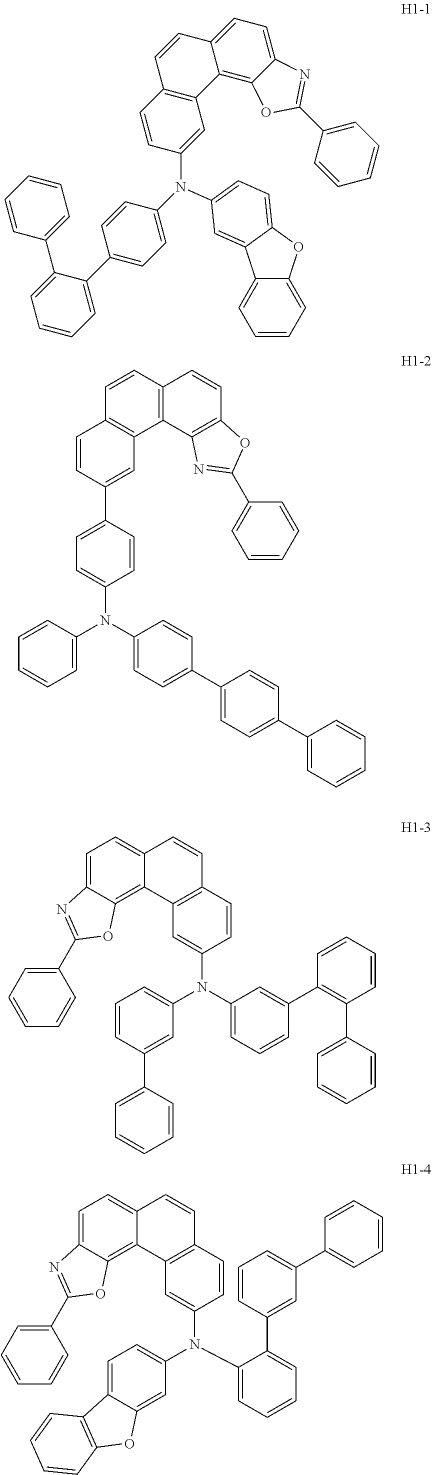

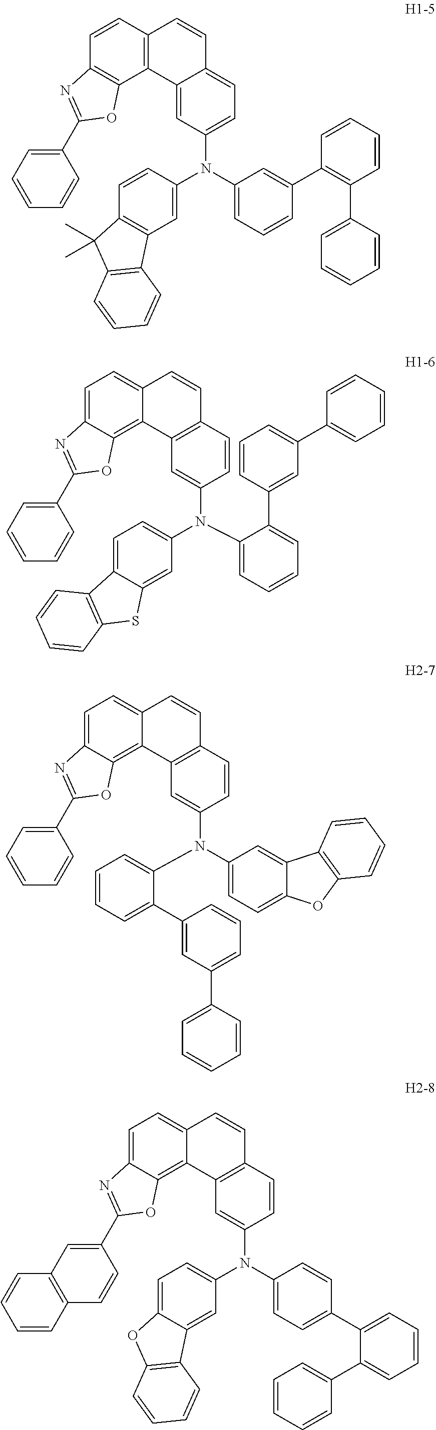

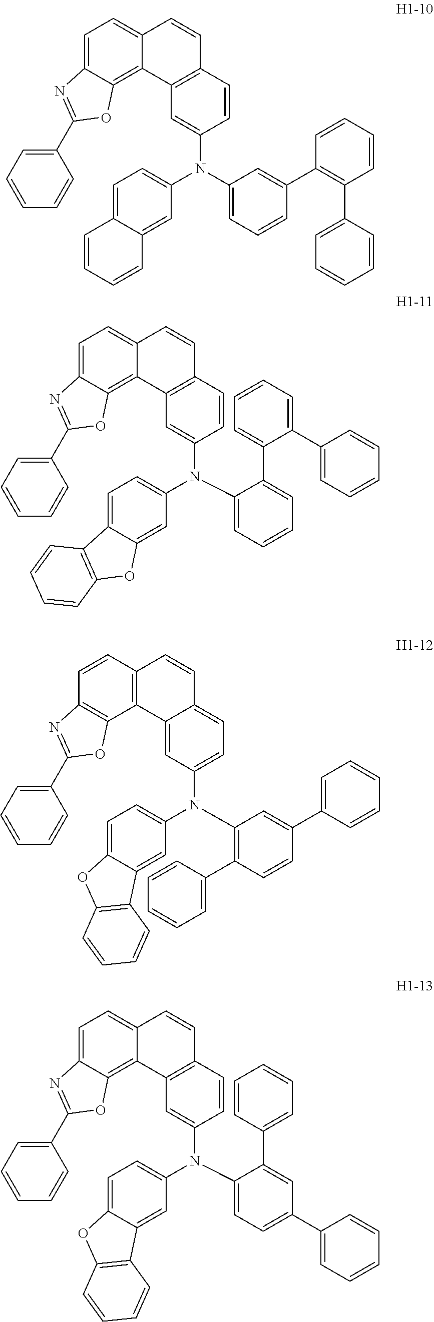

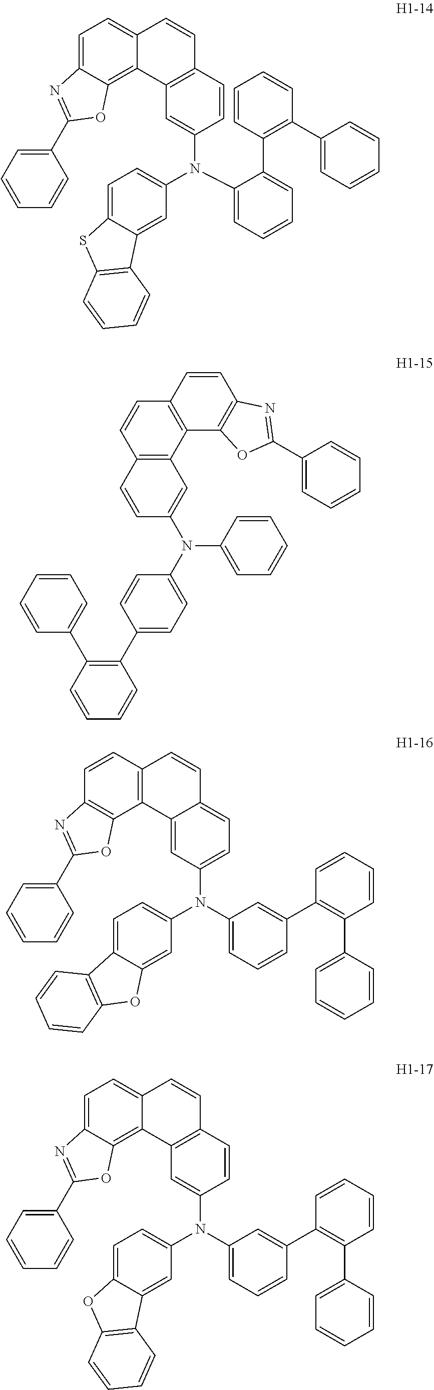

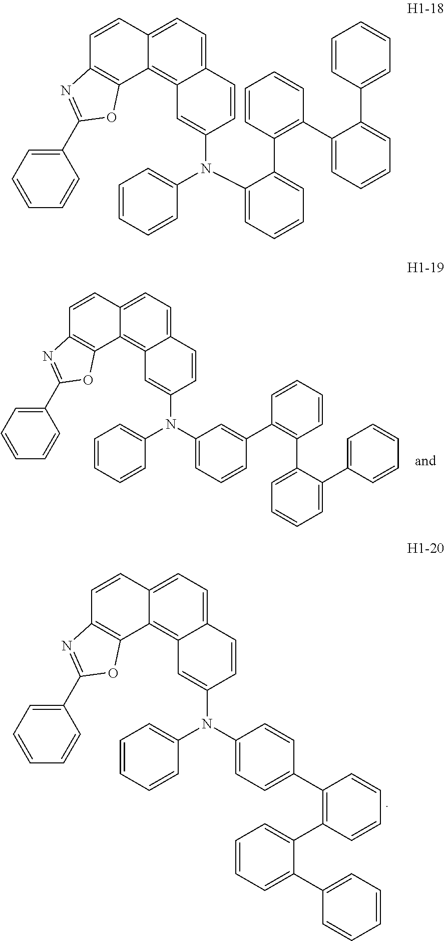 [SMILES: c1ccc(-c2nc3ccc4ccc5ccc(N(c6ccccc6)c6ccccc6-c6ccccc6-c6ccccc6-c6ccccc6)cc5c4c3o2)cc1 ; c1ccc(-c2nc3ccc4ccc5ccc(N(c6ccccc6)c6cccc(-c7ccccc7-c7ccccc7-c7ccccc7)c6)cc5c4c3o2)cc1 ; c1ccc(-c2nc3ccc4ccc5ccc(N(c6ccccc6)c6ccc(-c7ccccc7-c7ccccc7-c7ccccc7)cc6)cc5c4c3o2)cc1]

8. The plurality of host materials according to claim 1, wherein the compound represented by formula 2 is at least one selected from the following compounds:

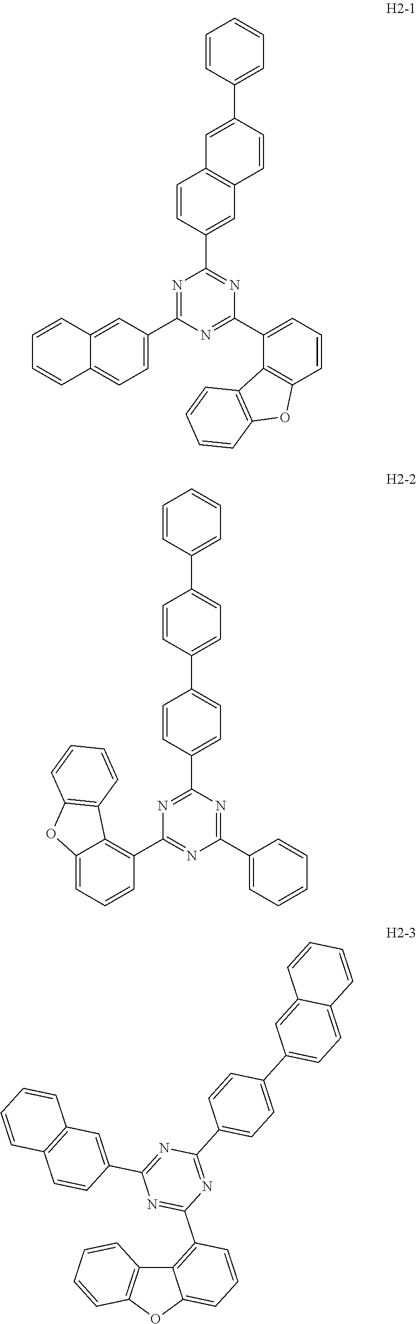

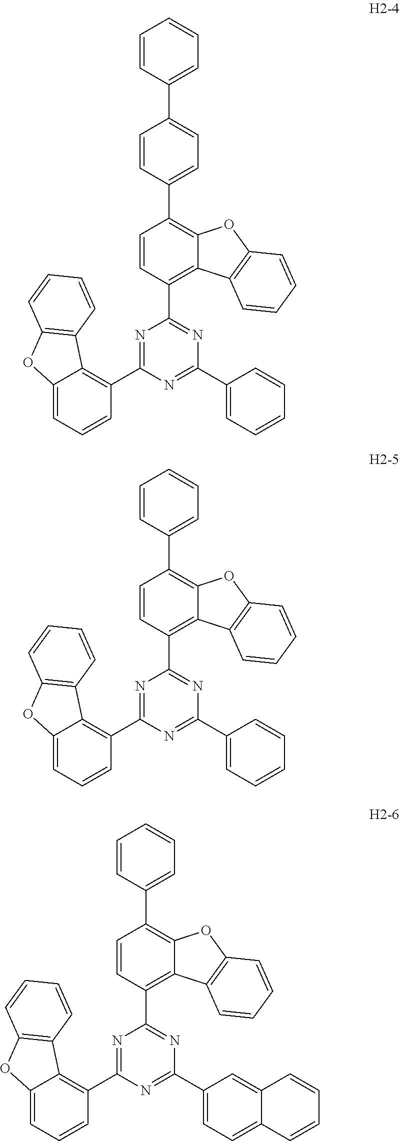 [SMILES: c1ccc(-c2ccc(-c3ccc(-c4nc(-c5ccccc5)nc(-c5cccc6oc7ccccc7c56)n4)c4c3oc3ccccc34)cc2)cc1 ; c1ccc(-c2nc(-c3cccc4oc5ccccc5c34)nc(-c3ccc(-c4ccccc4)c4oc5ccccc5c34)n2)cc1 ; c1ccc(-c2ccc(-c3nc(-c4ccc5ccccc5c4)nc(-c4cccc5oc6ccccc6c45)n3)c3c2oc2ccccc23)cc1]

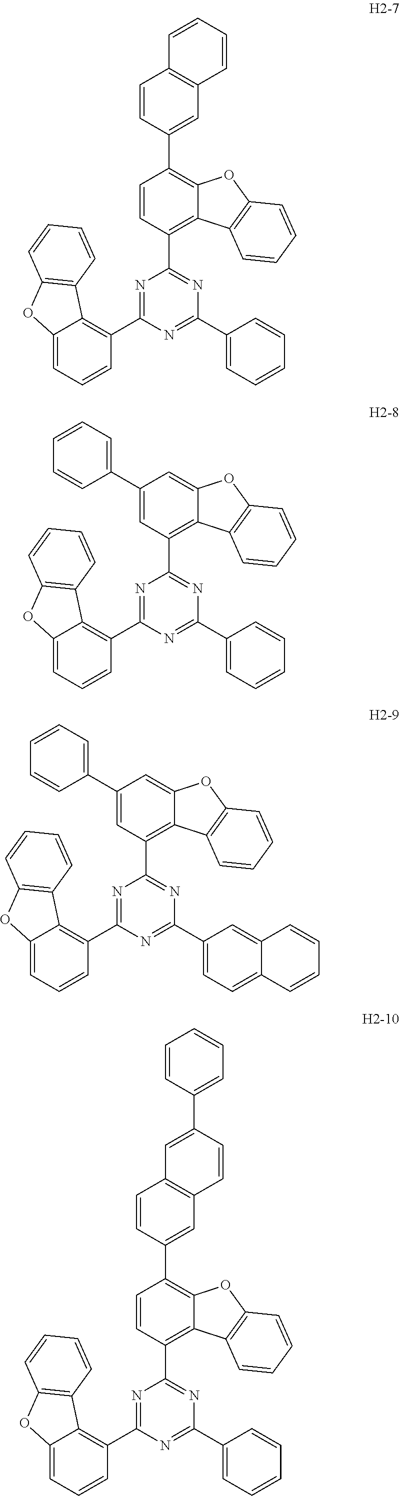

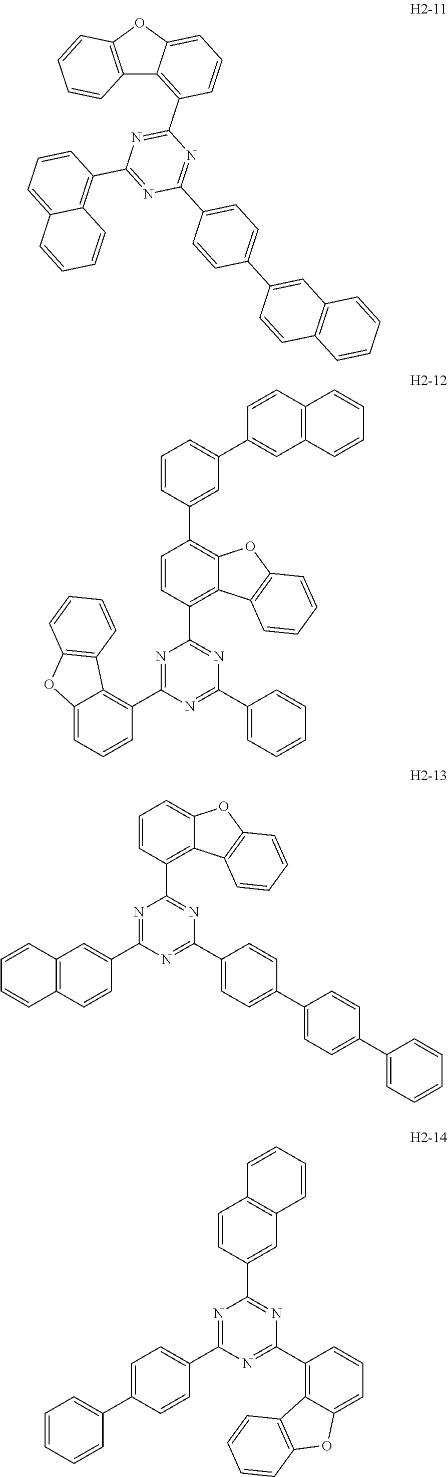

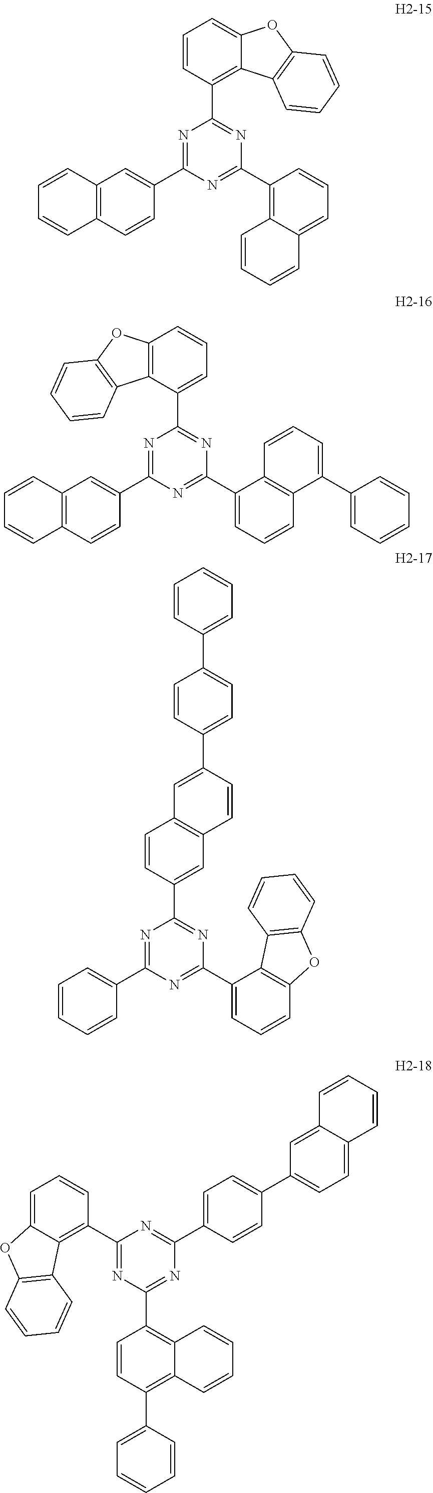 [SMILES: c1ccc2cc(-c3nc(-c4cccc5ccccc45)nc(-c4cccc5oc6ccccc6c45)n3)ccc2c1 ; c1ccc(-c2cccc3c(-c4nc(-c5ccc6ccccc6c5)nc(-c5cccc6oc7ccccc7c56)n4)cccc23)cc1 ; c1ccc(-c2ccc(-c3ccc4cc(-c5nc(-c6ccccc6)nc(-c6cccc7oc8ccccc8c67)n5)ccc4c3)cc2)cc1 ; c1ccc(-c2ccc(-c3nc(-c4ccc(-c5ccc6ccccc6c5)cc4)nc(-c4cccc5oc6ccccc6c45)n3)c3ccccc23)cc1]

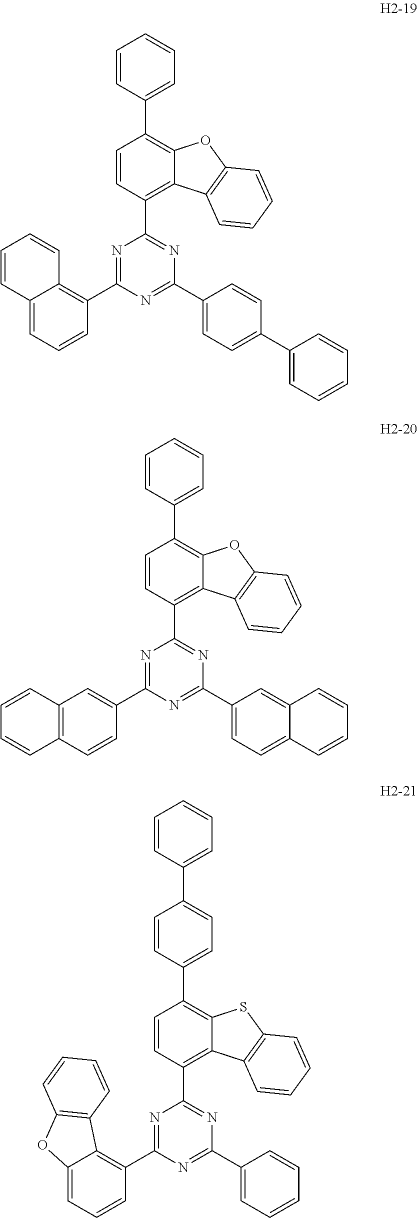 [SMILES: c1ccc(-c2ccc(-c3nc(-c4cccc5ccccc45)nc(-c4ccc(-c5ccccc5)c5oc6ccccc6c45)n3)cc2)cc1 ; c1ccc(-c2ccc(-c3nc(-c4ccc5ccccc5c4)nc(-c4ccc5ccccc5c4)n3)c3c2oc2ccccc23)cc1 ; c1ccc(-c2ccc(-c3ccc(-c4nc(-c5ccccc5)nc(-c5cccc6oc7ccccc7c56)n4)c4c3sc3ccccc34)cc2)cc1]

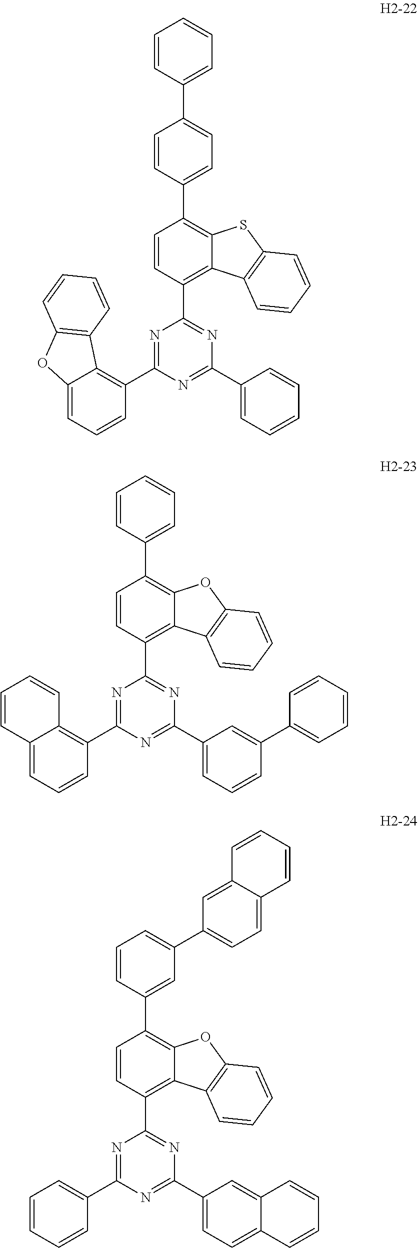 [SMILES: c1ccc(-c2ccc(-c3ccc(-c4nc(-c5ccccc5)nc(-c5cccc6oc7ccccc7c56)n4)c4c3sc3ccccc34)cc2)cc1 ; c1ccc(-c2cccc(-c3nc(-c4cccc5ccccc45)nc(-c4ccc(-c5ccccc5)c5oc6ccccc6c45)n3)c2)cc1 ; c1ccc(-c2nc(-c3ccc4ccccc4c3)nc(-c3ccc(-c4cccc(-c5ccc6ccccc6c5)c4)c4oc5ccccc5c34)n2)cc1]

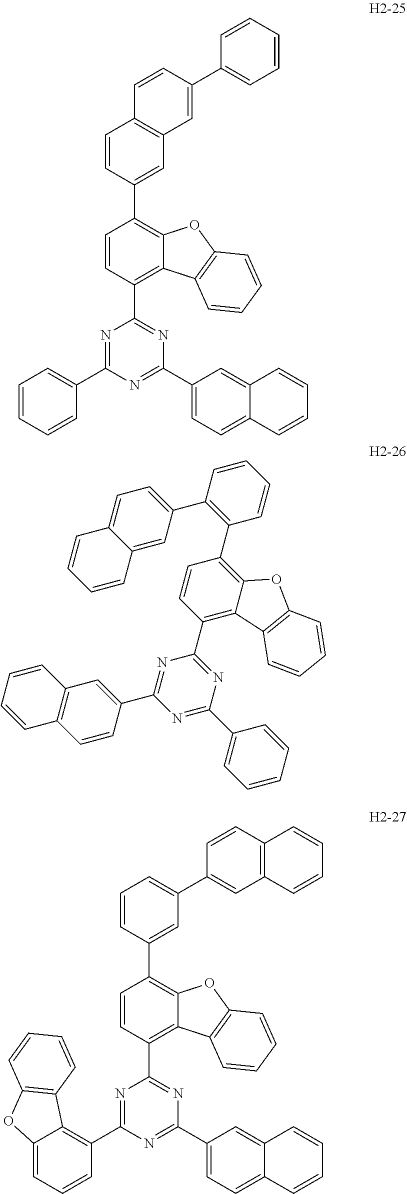

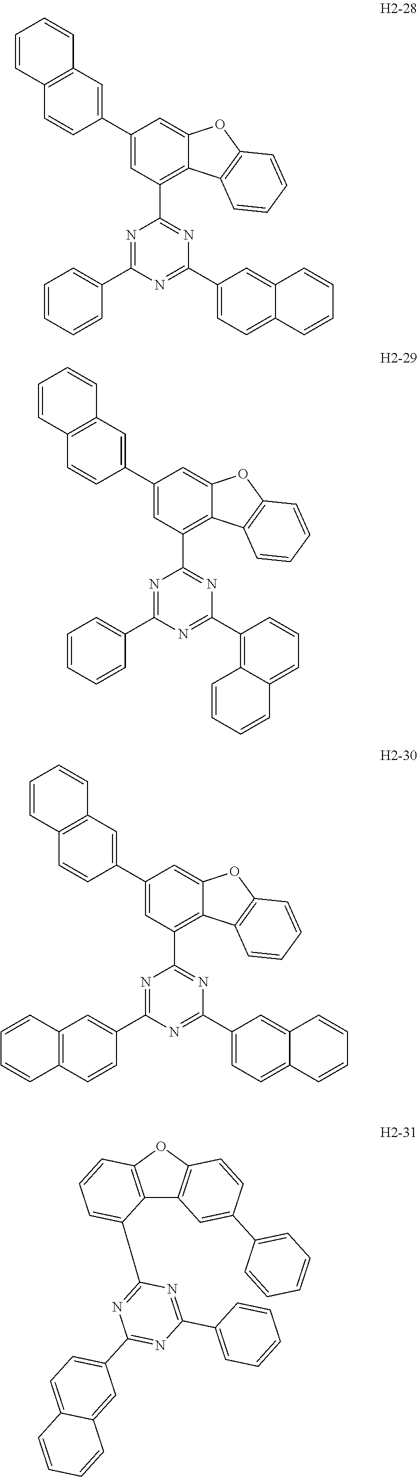

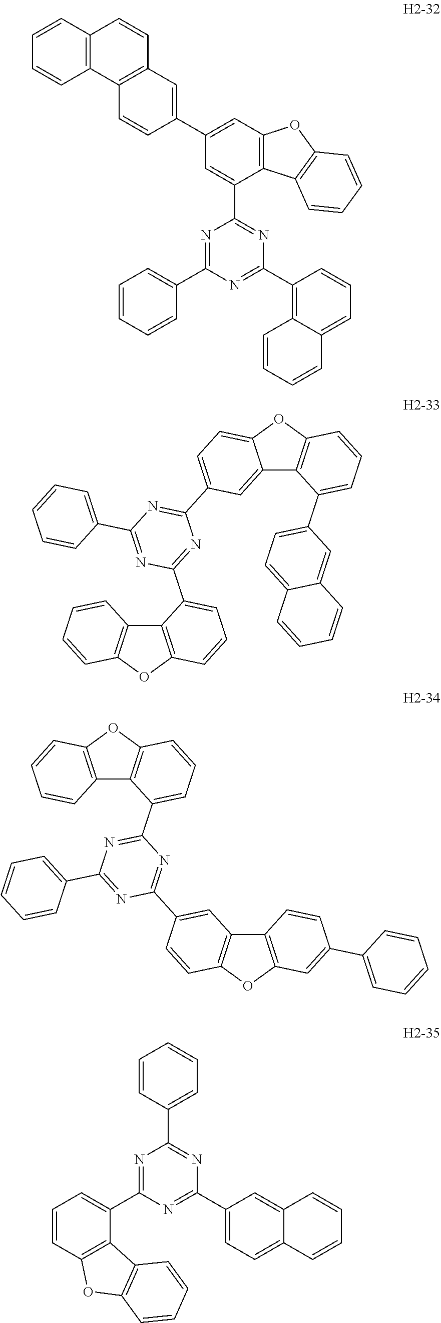

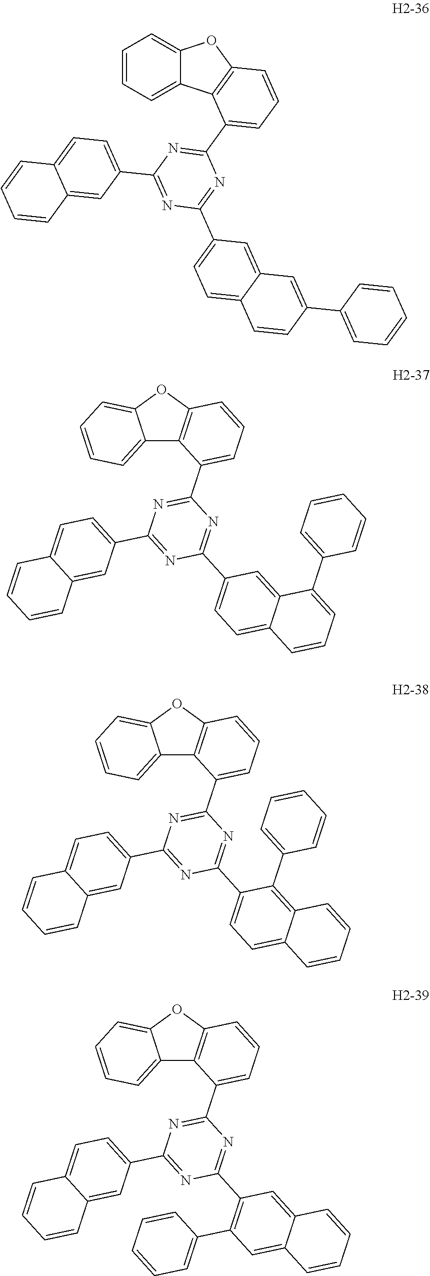 [SMILES: c1ccc(-c2ccc3ccc(-c4nc(-c5ccc6ccccc6c5)nc(-c5cccc6oc7ccccc7c56)n4)cc3c2)cc1 ; c1ccc(-c2cccc3ccc(-c4nc(-c5ccc6ccccc6c5)nc(-c5cccc6oc7ccccc7c56)n4)cc23)cc1 ; c1ccc(-c2c(-c3nc(-c4ccc5ccccc5c4)nc(-c4cccc5oc6ccccc6c45)n3)ccc3ccccc23)cc1 ; c1ccc(-c2cc3ccccc3cc2-c2nc(-c3ccc4ccccc4c3)nc(-c3cccc4oc5ccccc5c34)n2)cc1]

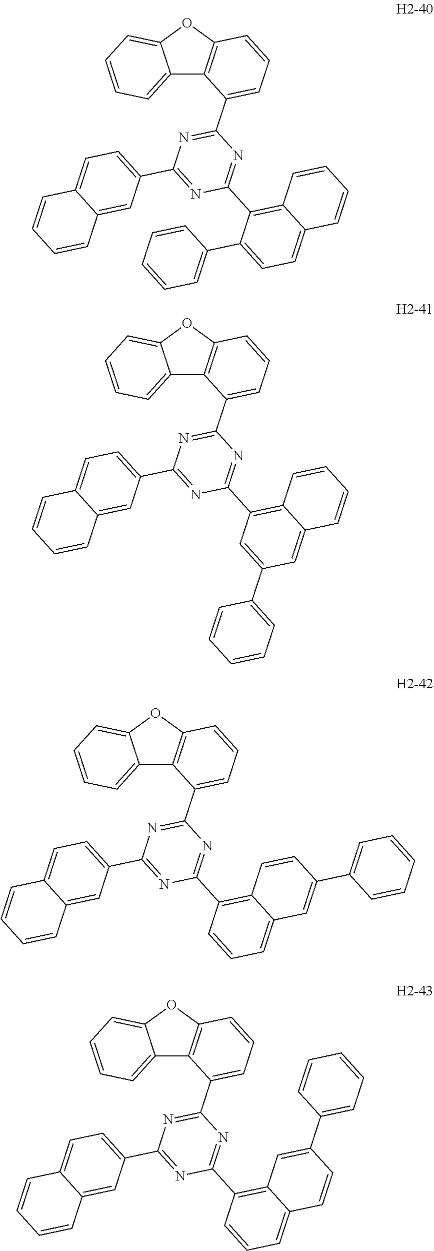

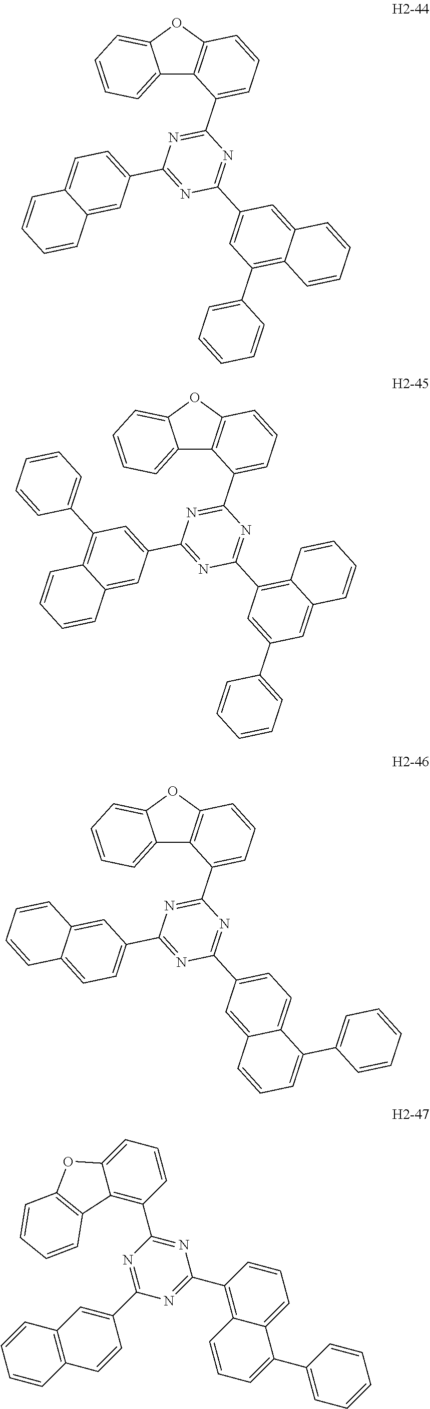

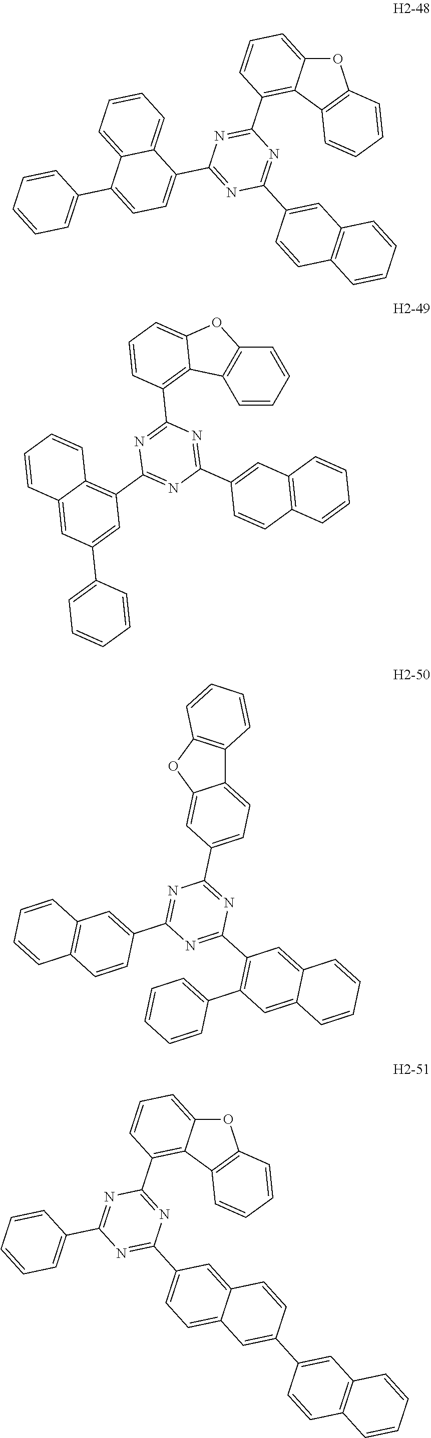 [SMILES: c1ccc(-c2ccc(-c3nc(-c4ccc5ccccc5c4)nc(-c4cccc5oc6ccccc6c45)n3)c3ccccc23)cc1 ; c1ccc(-c2cc(-c3nc(-c4ccc5ccccc5c4)nc(-c4cccc5oc6ccccc6c45)n3)c3ccccc3c2)cc1 ; c1ccc(-c2cc3ccccc3cc2-c2nc(-c3ccc4ccccc4c3)nc(-c3ccc4c(c3)oc3ccccc34)n2)cc1 ; c1ccc(-c2nc(-c3ccc4cc(-c5ccc6ccccc6c5)ccc4c3)nc(-c3cccc4oc5ccccc5c34)n2)cc1]

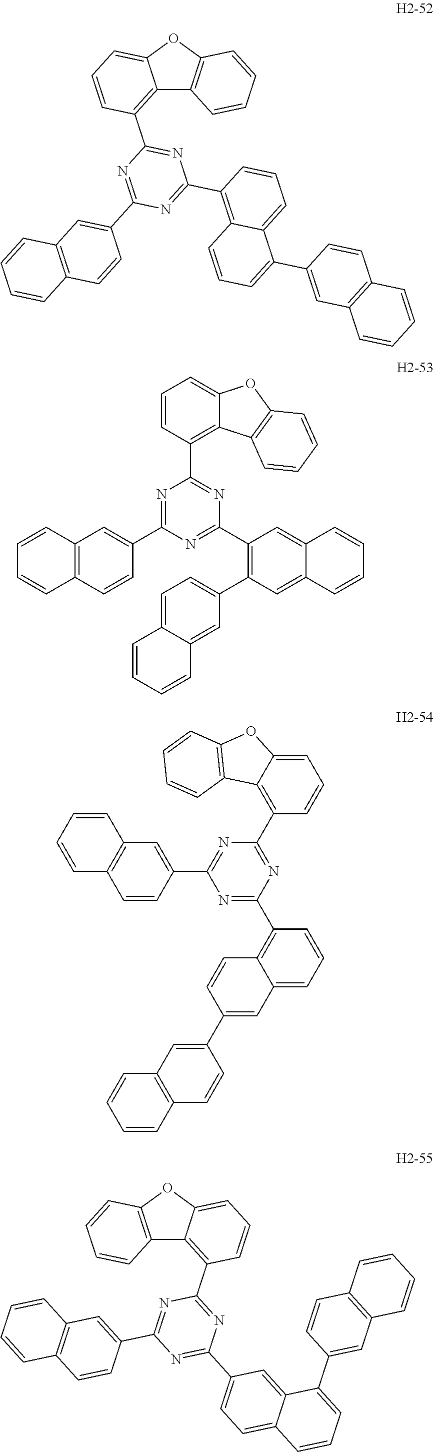 [SMILES: c1ccc2cc(-c3nc(-c4cccc5c(-c6ccc7ccccc7c6)cccc45)nc(-c4cccc5oc6ccccc6c45)n3)ccc2c1 ; c1ccc2cc(-c3nc(-c4cc5ccccc5cc4-c4ccc5ccccc5c4)nc(-c4cccc5oc6ccccc6c45)n3)ccc2c1 ; c1ccc2cc(-c3ccc4c(-c5nc(-c6ccc7ccccc7c6)nc(-c6cccc7oc8ccccc8c67)n5)cccc4c3)ccc2c1 ; c1ccc2cc(-c3nc(-c4ccc5cccc(-c6ccc7ccccc7c6)c5c4)nc(-c4cccc5oc6ccccc6c45)n3)ccc2c1]

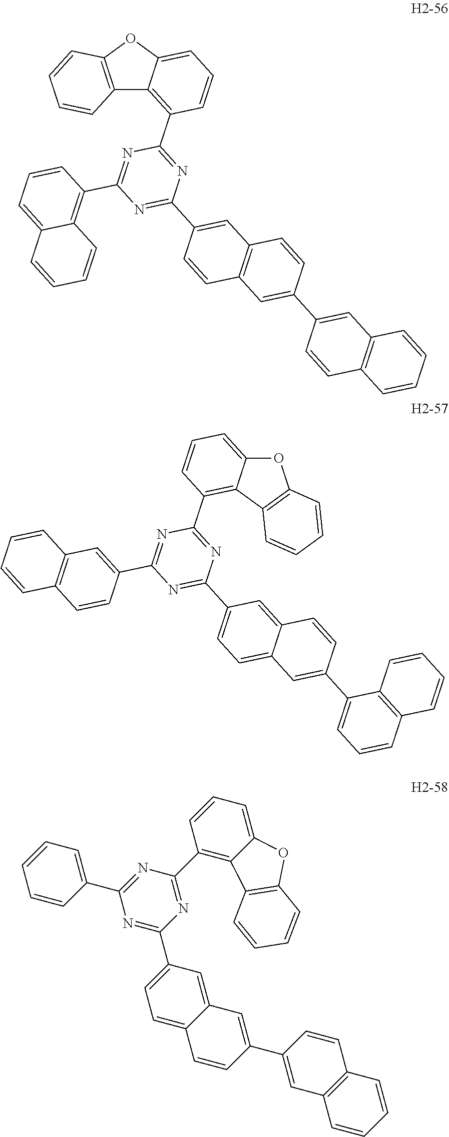 [SMILES: c1ccc2cc(-c3ccc4cc(-c5nc(-c6cccc7ccccc67)nc(-c6cccc7oc8ccccc8c67)n5)ccc4c3)ccc2c1 ; c1ccc2cc(-c3nc(-c4ccc5cc(-c6cccc7ccccc67)ccc5c4)nc(-c4cccc5oc6ccccc6c45)n3)ccc2c1 ; c1ccc(-c2nc(-c3ccc4ccc(-c5ccc6ccccc6c5)cc4c3)nc(-c3cccc4oc5ccccc5c34)n2)cc1]

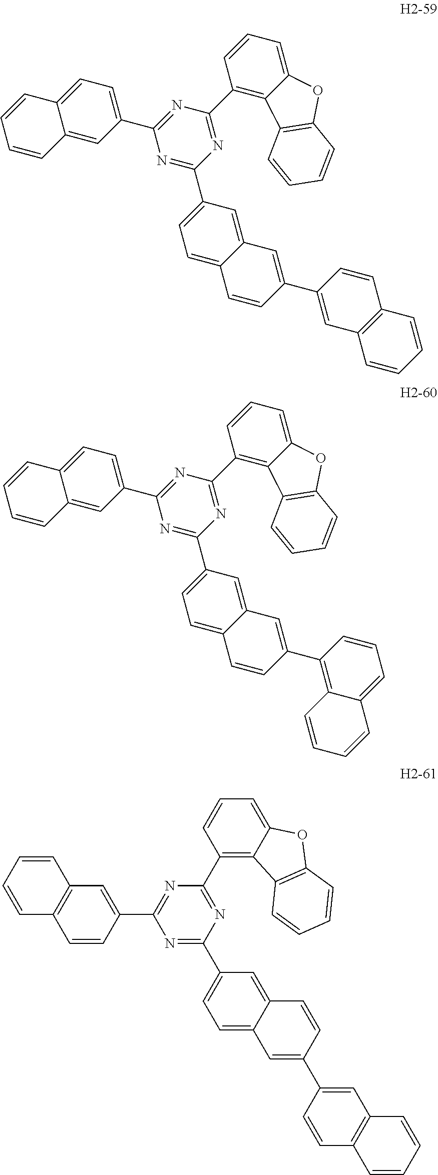 [SMILES: c1ccc2cc(-c3ccc4ccc(-c5nc(-c6ccc7ccccc7c6)nc(-c6cccc7oc8ccccc8c67)n5)cc4c3)ccc2c1 ; c1ccc2cc(-c3nc(-c4ccc5ccc(-c6cccc7ccccc67)cc5c4)nc(-c4cccc5oc6ccccc6c45)n3)ccc2c1 ; c1ccc2cc(-c3ccc4cc(-c5nc(-c6ccc7ccccc7c6)nc(-c6cccc7oc8ccccc8c67)n5)ccc4c3)ccc2c1]

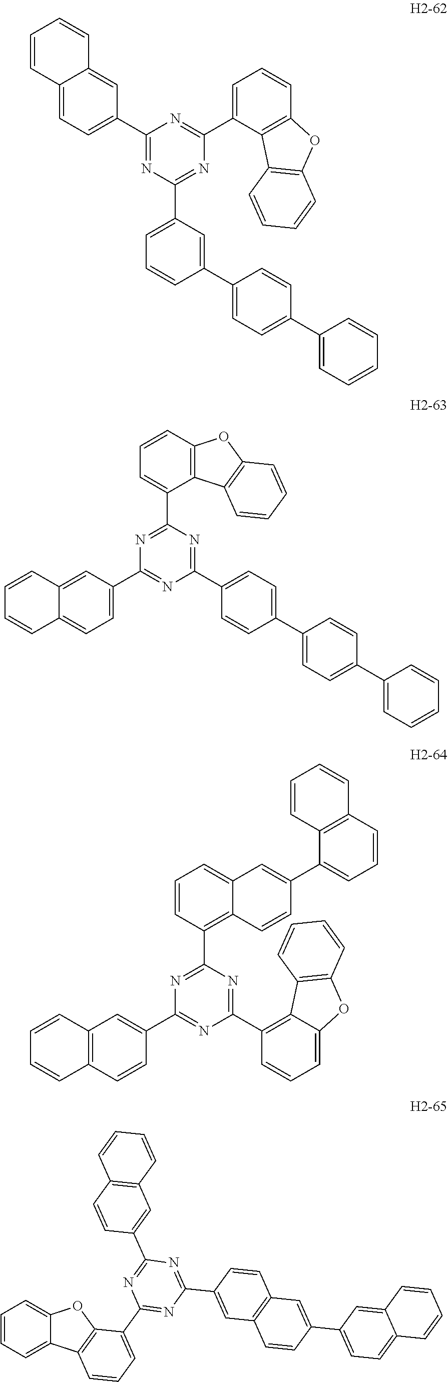 [SMILES: c1ccc(-c2ccc(-c3cccc(-c4nc(-c5ccc6ccccc6c5)nc(-c5cccc6oc7ccccc7c56)n4)c3)cc2)cc1 ; c1ccc(-c2ccc(-c3ccc(-c4nc(-c5ccc6ccccc6c5)nc(-c5cccc6oc7ccccc7c56)n4)cc3)cc2)cc1 ; c1ccc2cc(-c3nc(-c4cccc5cc(-c6cccc7ccccc67)ccc45)nc(-c4cccc5oc6ccccc6c45)n3)ccc2c1 ; c1ccc2cc(-c3ccc4cc(-c5nc(-c6ccc7ccccc7c6)nc(-c6cccc7c6oc6ccccc67)n5)ccc4c3)ccc2c1]

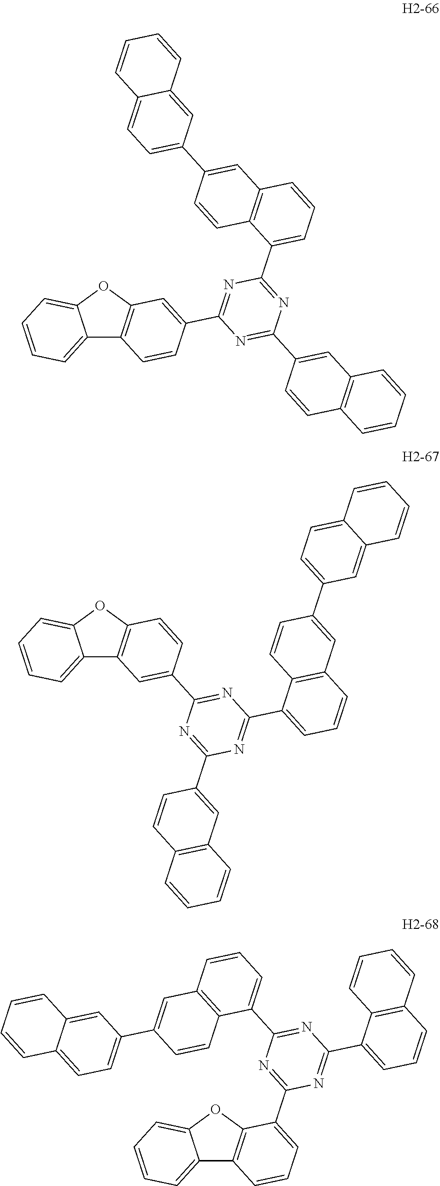 [SMILES: c1ccc2cc(-c3ccc4c(-c5nc(-c6ccc7ccccc7c6)nc(-c6ccc7c(c6)oc6ccccc67)n5)cccc4c3)ccc2c1 ; c1ccc2cc(-c3ccc4c(-c5nc(-c6ccc7ccccc7c6)nc(-c6ccc7oc8ccccc8c7c6)n5)cccc4c3)ccc2c1 ; c1ccc2cc(-c3ccc4c(-c5nc(-c6cccc7ccccc67)nc(-c6cccc7c6oc6ccccc67)n5)cccc4c3)ccc2c1]

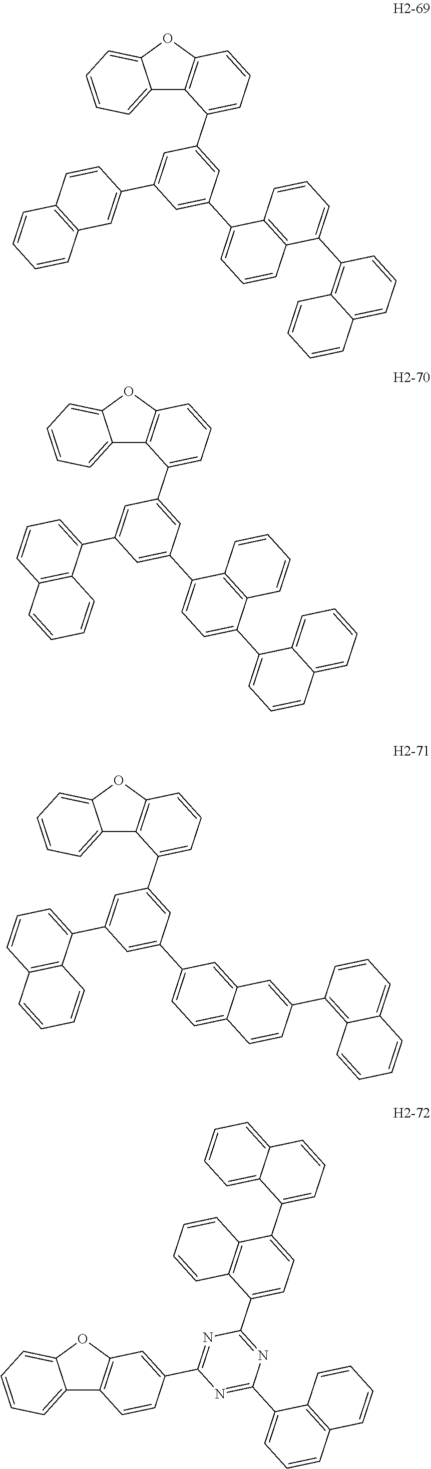 [SMILES: c1ccc2cc(-c3cc(-c4cccc5c(-c6cccc7ccccc67)cccc45)cc(-c4cccc5oc6ccccc6c45)c3)ccc2c1 ; c1ccc2c(-c3cc(-c4ccc(-c5cccc6ccccc56)c5ccccc45)cc(-c4cccc5oc6ccccc6c45)c3)cccc2c1 ; c1ccc2c(-c3cc(-c4ccc5ccc(-c6cccc7ccccc67)cc5c4)cc(-c4cccc5oc6ccccc6c45)c3)cccc2c1 ; c1ccc2c(-c3nc(-c4ccc5c(c4)oc4ccccc45)nc(-c4ccc(-c5cccc6ccccc56)c5ccccc45)n3)cccc2c1]

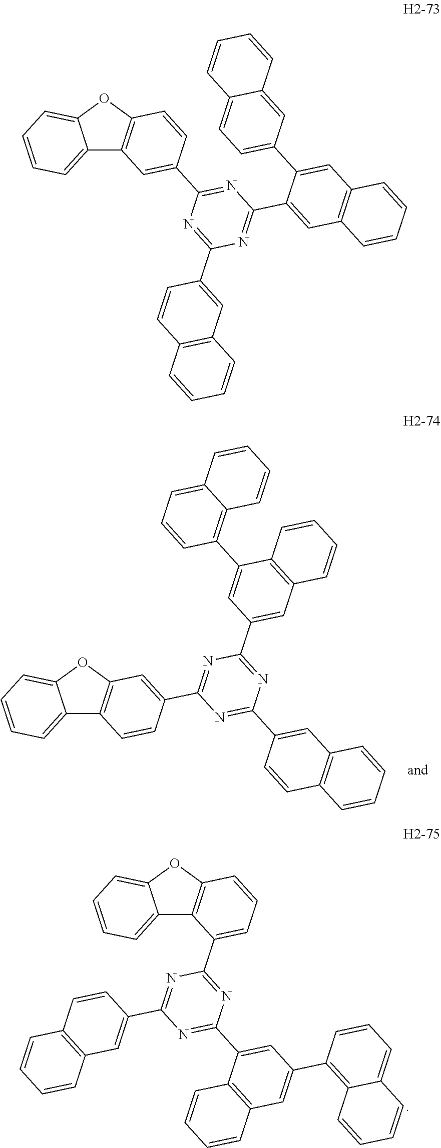 [SMILES: c1ccc2cc(-c3nc(-c4ccc5oc6ccccc6c5c4)nc(-c4cc5ccccc5cc4-c4ccc5ccccc5c4)n3)ccc2c1 ; c1ccc2cc(-c3nc(-c4cc(-c5cccc6ccccc56)c5ccccc5c4)nc(-c4ccc5c(c4)oc4ccccc45)n3)ccc2c1 ; c1ccc2cc(-c3nc(-c4cc(-c5cccc6ccccc56)cc5ccccc45)nc(-c4cccc5oc6ccccc6c45)n3)ccc2c1]

9. An organic electroluminescent device comprising an anode, a cathode, and at least one light-emitting layer between the anode and the cathode, wherein the at least one light-emitting layer comprises the plurality of host materials according to claim 1.

10. An organic electroluminescent compound represented by the following formula 21: 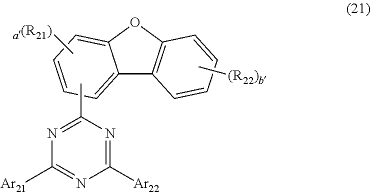
in formula 21,
Ar₂₁ represents a naphthyl unsubstituted or substituted with deuterium, a phenylnaphthyl unsubstituted or substituted with deuterium, a naphthylphenyl unsubstituted or substituted with deuterium, or a terphenyl unsubstituted or substituted with deuterium;
Ar₂₂ represents a binaphthyl unsubstituted or substituted with deuterium;
R₂₁ and R₂₂ each independently represent hydrogen or deuterium; and
a′ represents an integer of 1 to 3, and b′ represents an integer of 1 to 4, where if a′ and b′ represent an integer of 2 or more, each of R₂₁ and each of R₂₂ may be the same as or different from each other.

11. The organic electroluminescent compound according to claim 10, wherein formula 21 is represented by the following formula 21-1: 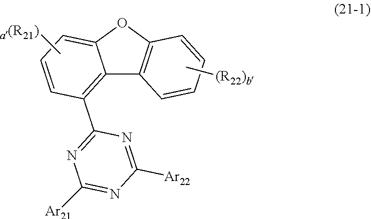
in formula 21-1, Ar₂₁, Ar₂₂, R₂₁, R₂₂, a′, and b′ are as defined in claim 10.

12. The organic electroluminescent compound according to claim 10, wherein Ar₂₂ is represented by one of the following formulas A-1 and A-2: 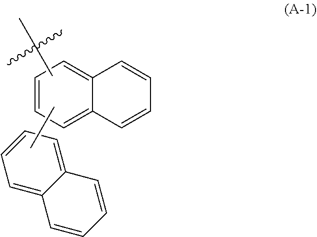 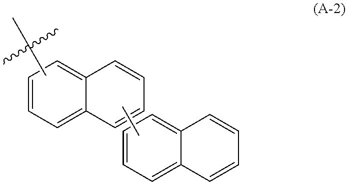
in formulas A-1 and A-2, the hydrogen of the naphthalenes may be substituted with deuterium.

13. The organic electroluminescent compound according to claim 10, wherein the organic electroluminescent compound represented by formula 21 is selected from the following compounds:

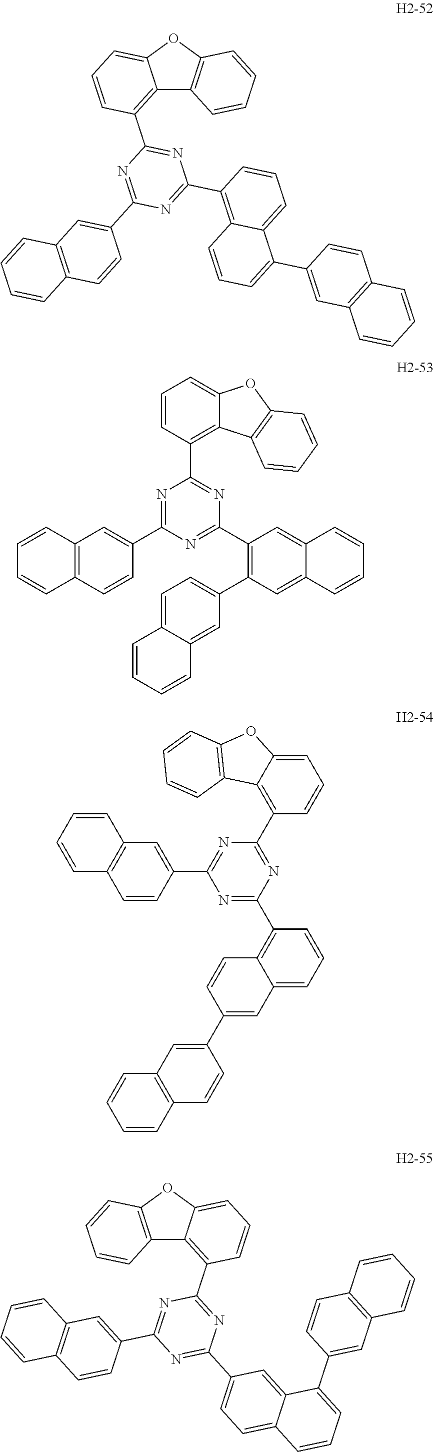 [SMILES: c1ccc2cc(-c3nc(-c4cccc5c(-c6ccc7ccccc7c6)cccc45)nc(-c4cccc5oc6ccccc6c45)n3)ccc2c1 ; c1ccc2cc(-c3nc(-c4cc5ccccc5cc4-c4ccc5ccccc5c4)nc(-c4cccc5oc6ccccc6c45)n3)ccc2c1 ; c1ccc2cc(-c3ccc4c(-c5nc(-c6ccc7ccccc7c6)nc(-c6cccc7oc8ccccc8c67)n5)cccc4c3)ccc2c1 ; c1ccc2cc(-c3nc(-c4ccc5cccc(-c6ccc7ccccc7c6)c5c4)nc(-c4cccc5oc6ccccc6c45)n3)ccc2c1]

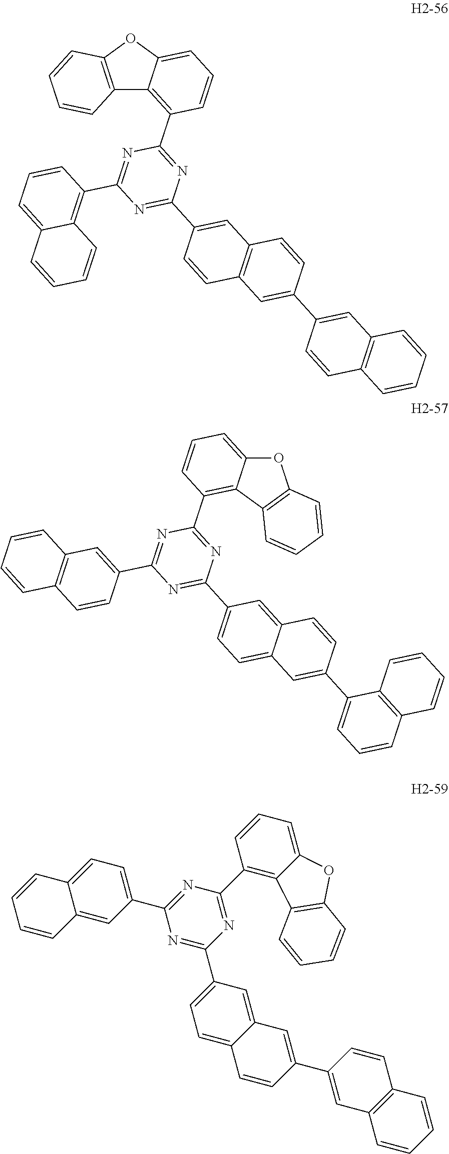 [SMILES: c1ccc2cc(-c3ccc4cc(-c5nc(-c6cccc7ccccc67)nc(-c6cccc7oc8ccccc8c67)n5)ccc4c3)ccc2c1 ; c1ccc2cc(-c3nc(-c4ccc5cc(-c6cccc7ccccc67)ccc5c4)nc(-c4cccc5oc6ccccc6c45)n3)ccc2c1 ; c1ccc2cc(-c3ccc4ccc(-c5nc(-c6ccc7ccccc7c6)nc(-c6cccc7oc8ccccc8c67)n5)cc4c3)ccc2c1]

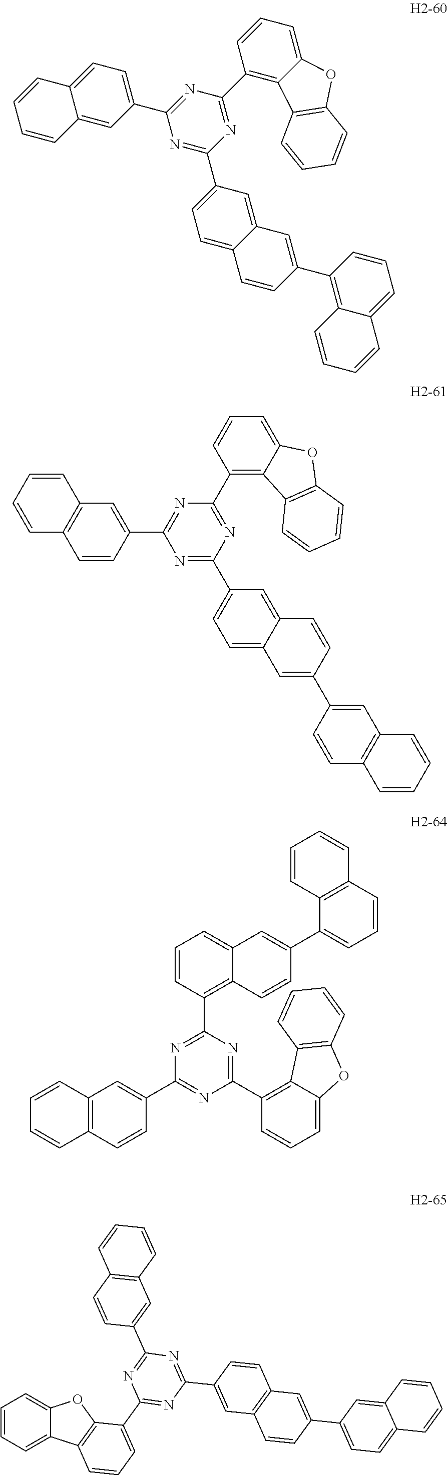 [SMILES: c1ccc2cc(-c3nc(-c4ccc5ccc(-c6cccc7ccccc67)cc5c4)nc(-c4cccc5oc6ccccc6c45)n3)ccc2c1 ; c1ccc2cc(-c3ccc4cc(-c5nc(-c6ccc7ccccc7c6)nc(-c6cccc7oc8ccccc8c67)n5)ccc4c3)ccc2c1 ; c1ccc2cc(-c3nc(-c4cccc5cc(-c6cccc7ccccc67)ccc45)nc(-c4cccc5oc6ccccc6c45)n3)ccc2c1 ; c1ccc2cc(-c3ccc4cc(-c5nc(-c6ccc7ccccc7c6)nc(-c6cccc7c6oc6ccccc67)n5)ccc4c3)ccc2c1]

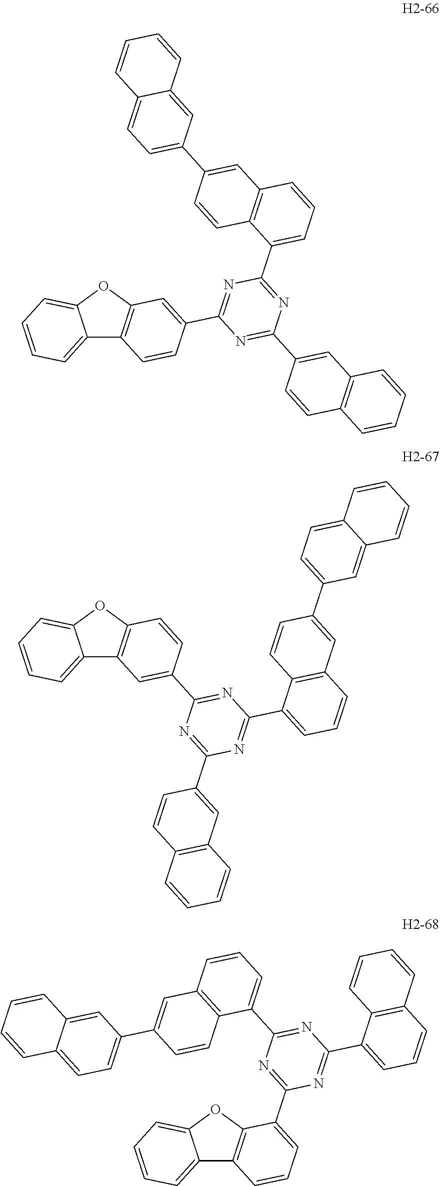 [SMILES: c1ccc2cc(-c3ccc4c(-c5nc(-c6ccc7ccccc7c6)nc(-c6ccc7c(c6)oc6ccccc67)n5)cccc4c3)ccc2c1 ; c1ccc2cc(-c3ccc4c(-c5nc(-c6ccc7ccccc7c6)nc(-c6ccc7oc8ccccc8c7c6)n5)cccc4c3)ccc2c1 ; c1ccc2cc(-c3ccc4c(-c5nc(-c6cccc7ccccc67)nc(-c6cccc7c6oc6ccccc67)n5)cccc4c3)ccc2c1]

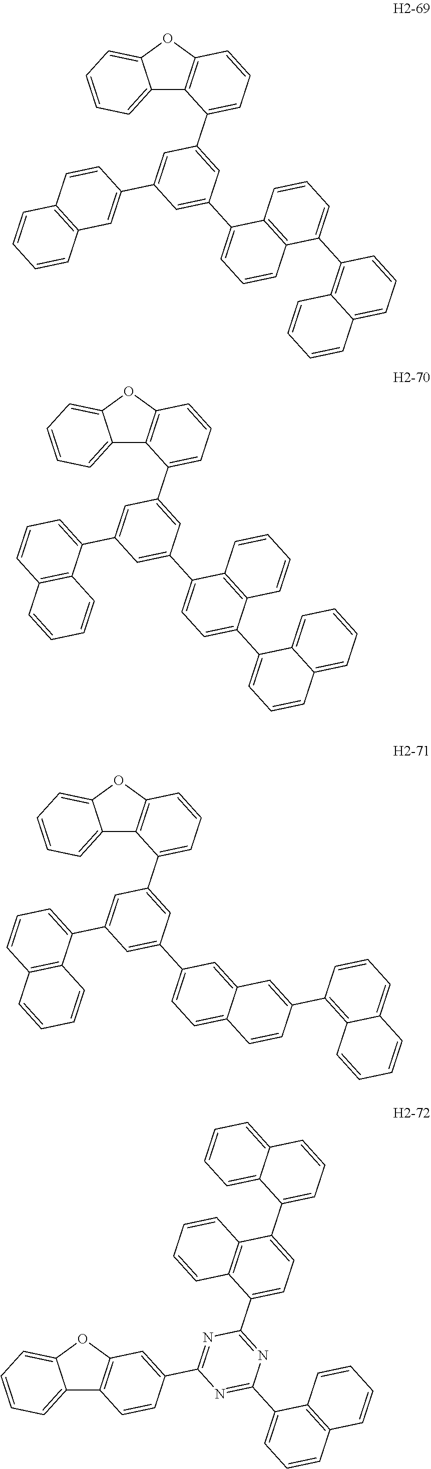 [SMILES: c1ccc2cc(-c3cc(-c4cccc5c(-c6cccc7ccccc67)cccc45)cc(-c4cccc5oc6ccccc6c45)c3)ccc2c1 ; c1ccc2c(-c3cc(-c4ccc(-c5cccc6ccccc56)c5ccccc45)cc(-c4cccc5oc6ccccc6c45)c3)cccc2c1 ; c1ccc2c(-c3cc(-c4ccc5ccc(-c6cccc7ccccc67)cc5c4)cc(-c4cccc5oc6ccccc6c45)c3)cccc2c1 ; c1ccc2c(-c3nc(-c4ccc5c(c4)oc4ccccc45)nc(-c4ccc(-c5cccc6ccccc56)c5ccccc45)n3)cccc2c1]

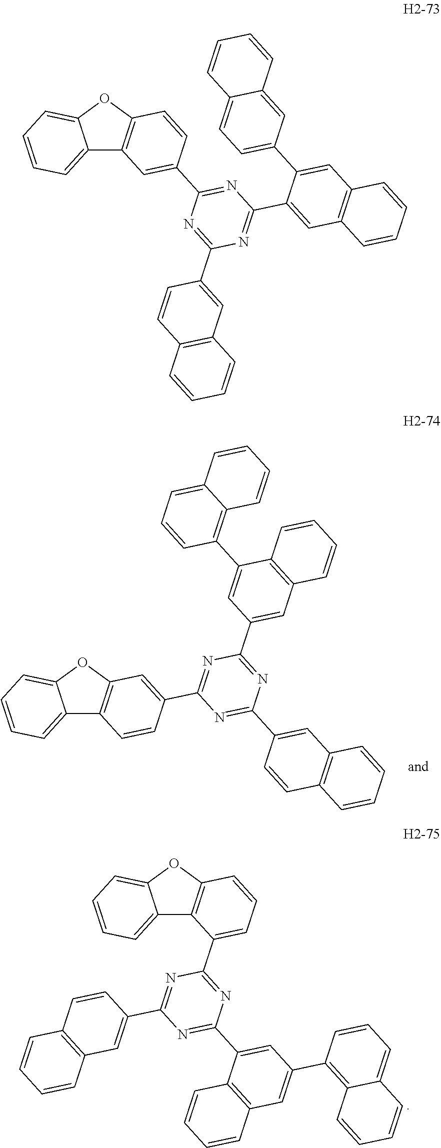 [SMILES: c1ccc2cc(-c3nc(-c4ccc5oc6ccccc6c5c4)nc(-c4cc5ccccc5cc4-c4ccc5ccccc5c4)n3)ccc2c1 ; c1ccc2cc(-c3nc(-c4cc(-c5cccc6ccccc56)c5ccccc5c4)nc(-c4ccc5c(c4)oc4ccccc45)n3)ccc2c1 ; c1ccc2cc(-c3nc(-c4cc(-c5cccc6ccccc56)cc5ccccc45)nc(-c4cccc5oc6ccccc6c45)n3)ccc2c1]

14. An organic electroluminescent device comprising the organic electroluminescent compound according to claim 10.

15. An organic electroluminescent compound selected from the following compounds:

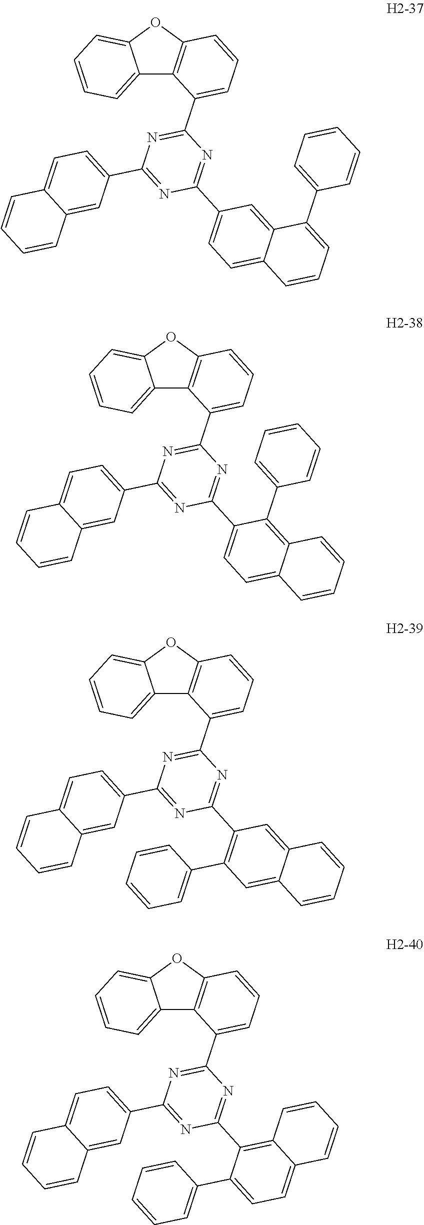 [SMILES: c1ccc(-c2cccc3ccc(-c4nc(-c5ccc6ccccc6c5)nc(-c5cccc6oc7ccccc7c56)n4)cc23)cc1 ; c1ccc(-c2c(-c3nc(-c4ccc5ccccc5c4)nc(-c4cccc5oc6ccccc6c45)n3)ccc3ccccc23)cc1 ; c1ccc(-c2cc3ccccc3cc2-c2nc(-c3ccc4ccccc4c3)nc(-c3cccc4oc5ccccc5c34)n2)cc1 ; c1ccc(-c2ccc3ccccc3c2-c2nc(-c3ccc4ccccc4c3)nc(-c3cccc4oc5ccccc5c34)n2)cc1]

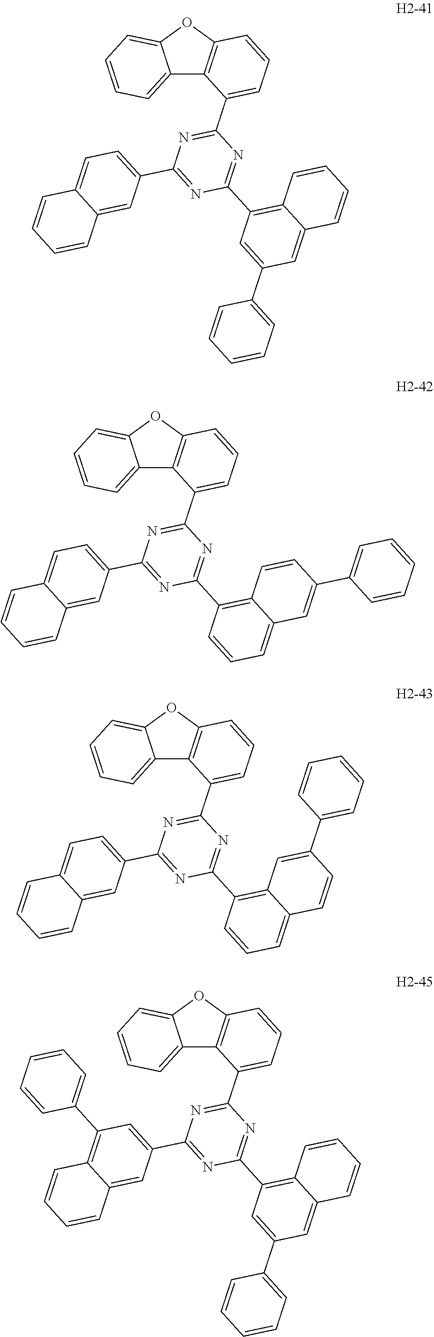 [SMILES: c1ccc(-c2cc(-c3nc(-c4ccc5ccccc5c4)nc(-c4cccc5oc6ccccc6c45)n3)c3ccccc3c2)cc1 ; c1ccc(-c2ccc3c(-c4nc(-c5ccc6ccccc6c5)nc(-c5cccc6oc7ccccc7c56)n4)cccc3c2)cc1 ; c1ccc(-c2ccc3cccc(-c4nc(-c5ccc6ccccc6c5)nc(-c5cccc6oc7ccccc7c56)n4)c3c2)cc1 ; c1ccc(-c2cc(-c3nc(-c4cc(-c5ccccc5)c5ccccc5c4)nc(-c4cccc5oc6ccccc6c45)n3)c3ccccc3c2)cc1]

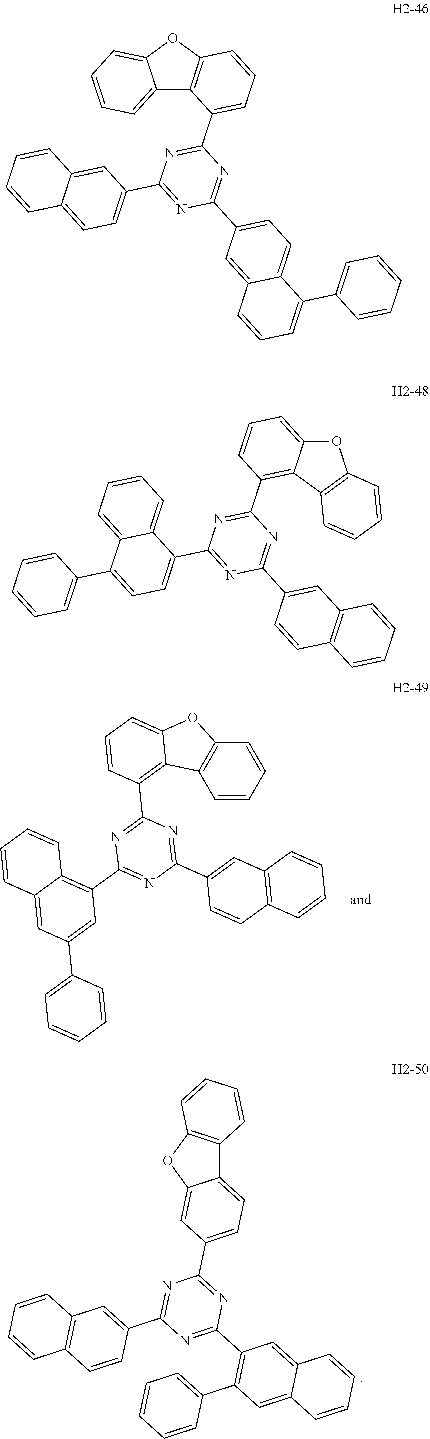 [SMILES: c1ccc(-c2cccc3cc(-c4nc(-c5ccc6ccccc6c5)nc(-c5cccc6oc7ccccc7c56)n4)ccc23)cc1 ; c1ccc(-c2ccc(-c3nc(-c4ccc5ccccc5c4)nc(-c4cccc5oc6ccccc6c45)n3)c3ccccc23)cc1 ; c1ccc(-c2cc(-c3nc(-c4ccc5ccccc5c4)nc(-c4cccc5oc6ccccc6c45)n3)c3ccccc3c2)cc1 ; c1ccc(-c2cc3ccccc3cc2-c2nc(-c3ccc4ccccc4c3)nc(-c3ccc4c(c3)oc3ccccc34)n2)cc1]

16. An organic electroluminescent device comprising the organic electroluminescent compound according to claim 15.
